(19) United States
(12) Patent Application Publication
(10) Pub. No.: US 2026/0271689 A1
(43) Pub. Date: Sep. 10, 2026

(54) SEMICONDUCTOR DEVICE AND METHOD OF FABRICATING THE SAME

(71) Applicant: Samsung Electronics Co., Ltd., Suwon-si (KR)

(72) Inventors: Hanseong Kim, Suwon-si (KR); JoonYong Bae, Suwon-si (KR); Seonwoong Lee, Suwon-si (KR)

(21) Appl. No.: 19/455,390

(22) Filed: Jan. 21, 2026

(30) Foreign Application Priority Data
Mar. 5, 2025 (KR) 10-2025-0028269

(51) Int. Cl. H10W 10/20; H10D 62/10; H10D 84/01; H10D 84/83; H10W 10/00; H10W 10/17

(52) U.S. Cl. CPC H10W 10/20; H10D 84/832; H10W 10/17; H10D 62/121; H10D 84/0153; H10W 10/014; H10W 10/021

(57) ABSTRACT

A semiconductor device includes a first channel pattern and a second channel pattern spaced apart from each other in a first direction on a substrate, a first gate electrode on the first channel pattern and extending in the first direction, a second gate electrode on the second channel pattern and extending the first direction, and a separation insulating pattern between the first gate electrode and the second gate electrode. The first gate electrode and the second gate electrode are aligned with each other in the first direction. The separation insulating pattern includes a lower pattern and an upper pattern stacked in a vertical direction perpendicular to a top surface of the substrate. An interface between the lower pattern and the upper pattern is located at a lower height than an uppermost surface of the first channel pattern and an uppermost surface of the second channel pattern.

### CROSS-REFERENCE TO RELATED APPLICATIONS

This U.S. non-provisional patent application claims priority under 35 U.S.C. § 119 to Korean Patent Application No. 10-2025-0028269 filed on Mar. 5, 2025 in the Korean Intellectual Property Office, the entire contents of which are hereby incorporated by reference.

### BACKGROUND

A semiconductor device includes an integrated circuit composed of metal-oxide-semiconductor field effect transistors (MOSFETs). As a size and a design rule of the semiconductor device are gradually decreasing, scaling down of the MOS field effect transistors is also gradually being accelerated. As the MOS field effect transistors are scaled down, operation characteristics of the semiconductor device may be deteriorated. Accordingly, research on various methods for overcoming limitation caused by high-integration of the semiconductor device and forming the semiconductor device with more excellent performance is being conducted.

### SUMMARY

The present disclosure relates to a semiconductor device and a method of fabricating the same, and in particular, to a semiconductor device including field effect transistors and a method of fabricating the same.

Aspects of the present disclosure provide a semiconductor device capable of minimizing manufacturing defects and a method of fabricating the same.

Aspects of the present disclosure provide a semiconductor device that is easy to manufacture and has excellent reliability, and a method of fabricating the same.

According to some implementations of the present disclosure, a semiconductor device may comprise: a first channel pattern and a second channel pattern spaced apart from each other in a first direction on a substrate; a first gate electrode on the first channel pattern and extending in the first direction; a second gate electrode on the second channel pattern and extending the first direction; and a separation insulating pattern between the first gate electrode and the second gate electrode. The first gate electrode and the second gate electrode may be aligned with each other in the first direction. The separation insulating pattern may include a lower pattern and an upper pattern stacked in a vertical direction perpendicular to a top surface of the substrate. An interface between the lower pattern and the upper pattern may be located at a lower height than an uppermost surface of the first channel pattern and an uppermost surface of the second channel pattern.

According to some implementations of the present disclosure, a semiconductor device may comprise: a first active pattern and a second active pattern that are spaced apart from each other in a first direction and extend in a second direction, on a substrate, the first direction and the second direction being parallel to a top surface of the substrate and intersecting with each other; a device isolation layer between the first active pattern and the second active pattern; a first channel pattern on the first active pattern; a second channel pattern on the second active pattern; a first gate electrode extending in the first direction and crossing the first active pattern and the first channel pattern; a second gate electrode extending in the first direction and crossing the second active pattern and the second channel pattern; and a separation insulating pattern interposed between the first gate electrode and the second gate electrode and disposed on the device isolation layer. The first gate electrode and the second gate electrode may be aligned with each other in the first direction. The separation insulating pattern may include a lower pattern and an upper pattern stacked in a third direction perpendicular to the top surface of the substrate. A top surface of the lower pattern may be located at a lower height than an uppermost surface of the first channel pattern and an uppermost surface of second channel pattern.

According to some implementations of the present disclosure, a semiconductor device may comprise: a first active pattern and a second active pattern that are spaced apart from each other in a first direction and extend in a second direction, on a substrate, the first direction and the second direction being parallel to a top surface of the substrate and intersecting each other; a first channel pattern on the first active pattern; first source/drain patterns that are on the first active pattern and are spaced apart from each other in the second direction with the first channel pattern interposed therebetween; a second channel pattern on the second active pattern; second source/drain patters that are on the second active pattern and are spaced apart from each other in the second direction with the second channel pattern interposed therebetween; a first gate electrode extending in the first direction and crossing the first active pattern and the first channel pattern; a second gate electrode extending in the first direction and crossing the second active pattern and the second channel pattern; and a separation insulating pattern interposed between the first gate electrode and the second gate electrode. The first gate electrode and the second gate electrode may be aligned with each other in the first direction. The separation insulating pattern may include a lower pattern and an upper pattern stacked in a third direction perpendicular to the top surface of the substrate. An interface between the lower pattern and the upper pattern may be located at a lower height than an uppermost surface of the first channel pattern and an uppermost surface of the second channel pattern. The first source/drain patterns may have a different conductivity type than the second source/drain patterns.

### BRIEF DESCRIPTION OF THE DRAWINGS

FIG. 1 is a plan view of a semiconductor device according to some implementations of the present disclosure.

FIGS. 2A, 2B, 2C, and 2D are cross-sectional views taken along lines A-A′, B-B', C-C′ and D-D′ of FIG. 1, respectively.

FIGS. 3A to 20A, FIGS. 3B to 20B, FIGS. 3C to 20C, and FIGS. 3D to 20D are cross-sectional views illustrating a method of fabricating a semiconductor device according to some implementations of the present disclosure.

FIGS. 21 to 31 are cross-sectional views corresponding to the line A-A′ of FIG. 1 and illustrating a semiconductor device according to some implementations of the present disclosure.

### DETAILED DESCRIPTION

Example implementations of the present disclosure will now be described more fully with reference to the accompanying drawings, in which example implementations are shown.

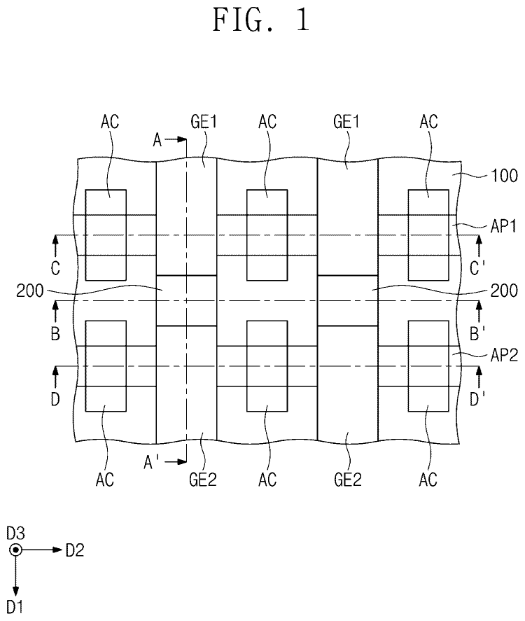

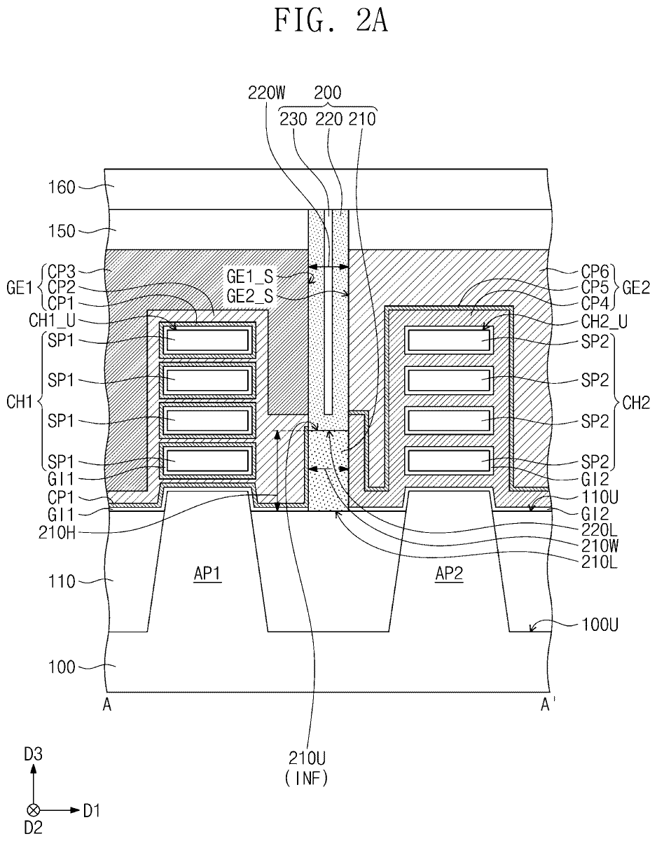

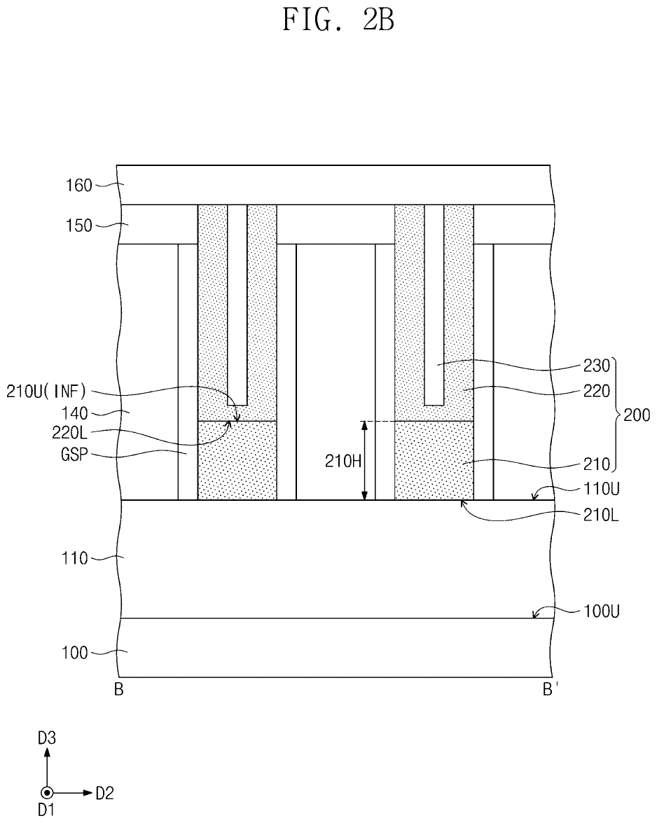

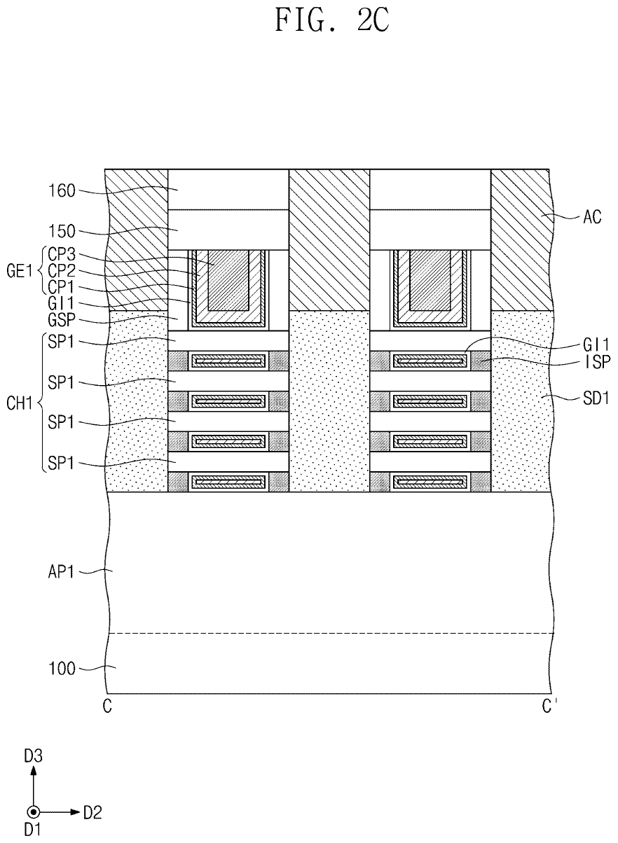

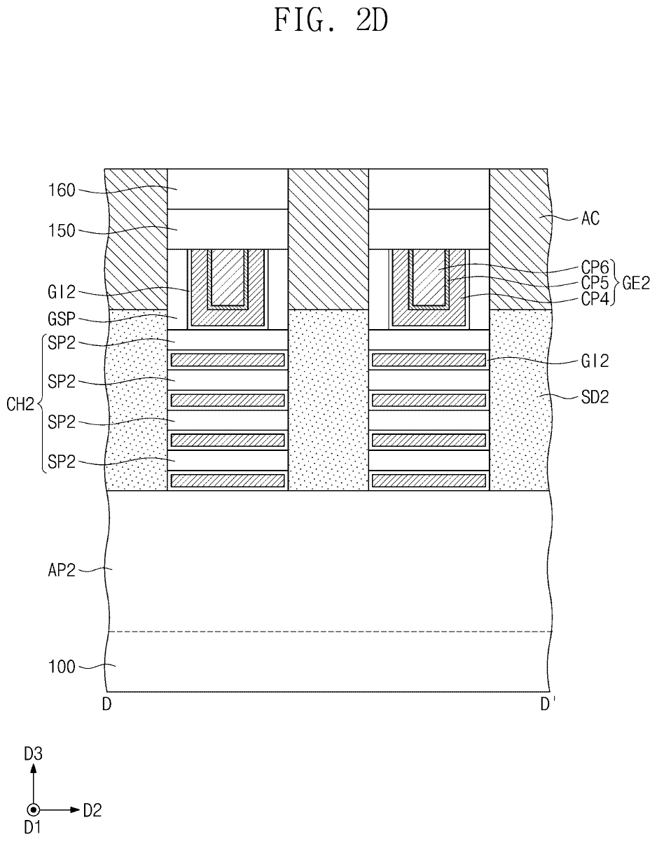

FIG. 1 is a plan view of a semiconductor device according to some implementations of the present disclosure. FIGS. 2A, 2B, 2C, and 2D are cross-sectional views taken along lines A-A′, B-B′, C-C′ and D-D′ of FIG. 1, respectively.

Referring to FIGS. 1 and 2A to 2D, a first active pattern AP1 and a second active pattern AP2 may be disposed on a substrate 100. The substrate 100 may be a semiconductor substrate. As an example, the substrate 100 may be a silicon substrate, a germanium substrate, a silicon-germanium substrate, or a silicon on insulator (SOI) substrate. The first active pattern AP1 and the second active pattern AP2 may be spaced apart from each other in a first direction D1 and may extend in a second direction D2. The first direction D1 and the second direction D2 may be parallel to a top surface 100U of the substrate 100 and intersect with each other. Each of the first active pattern AP1 and the second active pattern AP2 may protrude from the top surface 100U of the substrate 100 along a third direction D3 perpendicular to the top surface 100U of the substrate 100. Each of the first active pattern AP1 and the second active pattern AP2 may be a portion of the substrate 100 that protrudes from the substrate 100.

A device isolation layer 110 may be disposed on the top surface 100U of the substrate 100 and on both sides of each of the first active pattern AP1 and the second active pattern AP2, and may extend in the second direction D2. The device isolation layer 110 may extend in the second direction D2 between the first active pattern AP1 and the second active pattern AP2. The device isolation layer110 may include an oxide, a nitride, and/or an oxynitride.

A first channel pattern CH1 and first source/drain patterns SD1 may be disposed on the first active pattern AP1. The first source/drain patterns SD1 may be spaced apart from each other in the second direction D2, and the first channel pattern CH1 may be interposed between the first source/drain patterns SD1. According to some implementations, the first channel pattern CH1 may include first semiconductor patterns SP1 spaced apart from each other in the third direction D3. A lowermost first semiconductor pattern SP1 of the first semiconductor patterns SP1 may be spaced apart from the first active pattern AP1 along the third direction D3. The first semiconductor patterns SP1 may be interposed between the first source/drain patterns SD1. Each of the first semiconductor patterns SP1 may be connected to the first source/drain patterns SD1 and may be in contact with the first source/drain patterns SD1. Each of the first source/drain patterns SD1 may be connected to (or in contact with) side surfaces of the first semiconductor patterns SP1. Although the number of the first semiconductor patterns SP1 is shown as four, implementations of the present disclosure are not limited thereto. The first semiconductor patterns SP1 may include, for example, at least one of silicon (Si), germanium (Ge), and silicon-germanium (SiGe).

The first source/drain patterns SD1 may be epitaxial patterns formed using the first active pattern AP1 as a seed. The first source/drain patterns SD1 may include at least one of silicon germanium (SiGe), silicon (Si), and silicon carbide (SiC). The first source/drain patterns SD1 may provide tensile strain or compressive strain to the first channel pattern CH1. The first source/drain patterns SD1 may further include an impurity. The impurity may be employed to improve electrical characteristics of a first transistor including the first source/drain patterns SD1. When the first transistor is an NMOSFET, the impurity may be phosphorus (P), for example. When the first transistor is a PMOSFET, the impurity may be boron (B), for example.

A second channel pattern CH2 and second source/drain patterns SD2 may be disposed on the second active pattern AP2. The second source/drain patterns SD2 may be spaced apart from each other in the second direction D2, and the second channel pattern CH2 may be interposed between the second source/drain patterns SD2. According to some implementations, the second channel pattern CH2 may include second semiconductor patterns SP2 spaced apart from each other in the third direction D3. A lowermost second semiconductor pattern SP2 of the second semiconductor patterns SP2 may be spaced apart from the second active pattern AP2 along the third direction D3. The second semiconductor patterns SP2 may be interposed between the second source/drain patterns SD2. Each of the second semiconductor patterns SP2 may be connected to and in contact with the second source/drain patterns SD2. Each of the second source/drain patterns SD2 may be connected to (or in contact with) side surfaces of the second semiconductor patterns SP2. Although the number of the second semiconductor patterns SP2 is shown as four, implementations of the present disclosure are not limited thereto. The second semiconductor patterns SP2 may include, for example, at least one of silicon (Si), germanium (Ge), and silicon-germanium (SiGe).

The second source/drain patterns SD2 may be epitaxial patterns formed using the second active pattern AP2 as a seed. The second source/drain patterns SD2 may include at least one of silicon germanium (SiGe), silicon (Si), and silicon carbide (SiC). The second source/drain patterns SD2 may provide tensile strain or compressive strain to the second channel pattern CH2. The second source/drain patterns SD2 may further include an impurity. The impurity may be employed to improve electrical characteristics of a second transistor including the second source/drain patterns SD2. If the second transistor is an NMOSFET, the impurity may be phosphorus (P), for example. If the second transistor is a PMOSFET, the impurity may be boron (B), for example.

The first channel pattern CH1 and the second channel pattern CH2 may be spaced apart from each other in the first direction D1. The second source/drain patterns SD2 may be spaced apart from the first source/drain patterns SD1 along the first direction D1. According to some implementations, the first source/drain patterns SD1 may have a different conductivity type than the second source/drain patterns SD2. The first source/drain patterns SD1 may have a first conductivity type and the second source/drain patterns SD2 may have a second conductivity type different from the first conductivity type. As an example, the first conductivity type may be N-type, and the second conductivity type may be P-type.

A first gate electrode GE1 may be disposed on the first active pattern AP1 and the first channel pattern CH1. The first gate electrode GE1 may extend in the first direction D1 to cross the first active pattern AP1 and the first channel pattern CH1, and may cover the first channel pattern CH1. The first gate electrode GE1 may extend on a top surface 110U of the device isolation layer 110 along the first direction D1. The first channel pattern CH1 may vertically overlap with the first gate electrode GE1 (e.g., in the third direction D3). The first source/drain patterns SD1 may be disposed on both sides of the first gate electrode GE1. The first gate electrode GE1 may be disposed on an uppermost first semiconductor pattern SP1 of the first semiconductor patterns SP1, and may extend between the first semiconductor patterns SP1, and between the first active pattern AP1 and the lowermost first semiconductor pattern SP1 of the first semiconductor patterns SP1. The first gate electrode GE1 may cover side surfaces of the first channel pattern CH1, which are opposite to each other in the first direction D1 (for example, side surfaces of each of the first semiconductor patterns SP1, which are opposite to each other in the first direction D1).

A first gate insulating pattern GI1 may be interposed between the first active pattern AP1 and the first gate electrode GE1, and between the first channel pattern CH1 and the first gate electrode GE1. The first gate insulating pattern GI1 may be interposed between each of the first semiconductor patterns SP1 and the first gate electrode GE1, and may surround an outer surface of each of the first semiconductive patterns SP1. Each of the first semiconductor patterns SP1 may be spaced apart from the first gate electrode GE1 with the first gate insulating pattern GI1 interposed therebetween. The first gate insulating pattern GI1 may extend between each of the first source/drain patterns SD1 and the first gate electrode GE1. The first gate insulating pattern GI1 may extend along a bottom surface of the first gate electrode GE1, and may be interposed between the first gate electrode GE1 and the device isolation layer 110.

Gate spacers GSP may be disposed on side surfaces of the first gate electrode GE1. The gate spacers GSP may be disposed on the uppermost first semiconductor pattern SP1, and may extend along the side surfaces of the first gate electrode GE1. The first gate insulating pattern GI1 may extend on the side surfaces of the first gate electrode GE1 and may be interposed between the first gate electrode GE1 and the gate spacers GSP.

Spacer patterns ISP may be interposed between the first semiconductor patterns SP1 of the first channel pattern CH1, and between the lowermost first semiconductor pattern SP1 and the first active pattern AP1. The spacer patterns ISP may be spaced apart from each other in the second direction D2 with the first gate electrode GE1 interposed therebetween. Each of the spacer patterns ISP may be interposed between a corresponding one of the first source/drain patterns SD1 and the first gate electrode GE1. Each of the first source/drain patterns SD1 may be in contact with the first semiconductor patterns SP1, and may be spaced apart from the first gate electrode GE1 with the spacer patterns ISP interposed therebetween. Each of the first source/drain patterns SD1 may be in contact with corresponding ones of the spacer patterns ISP. The first gate insulating pattern GI1 may be interposed between the first gate electrode GE1 and each of the first semiconductor patterns SP1, and may extend between the first gate electrode GE1 and each of the spacer patterns ISP. Each of the spacer patterns ISP may be in contact with the first gate insulating pattern GI1.

The first gate electrode GE1 may include a doped semiconductor, a conductive metal nitride and/or a metal. According to some implementations, the first gate electrode GE1 may include a first conductive pattern CP1 on the first active pattern AP1 and the first channel pattern CH1, a second conductive pattern CP2 on the first conductive pattern CP1, and a third conductive pattern CP3 on the second conductive pattern CP2. The first conductive pattern CP1 may be on the uppermost first semiconductor pattern SP1, and may be interposed between the first semiconductor patterns SP1, and between the lowermost first semiconductor pattern SP1 and the first active pattern AP1. The first conductive pattern CP1 may surround the outer surface of each of the first semiconductor patterns SP1. The first conductive pattern CP1 may extend on the top surface 110U of the device isolation layer 110 along the first direction D1. The second conductive pattern CP2 may be on the uppermost first semiconductor pattern SP1, and may fill a space between the first semiconductor patterns SP1, and between the lowermost first semiconductor pattern SP1 and the first active pattern AP1. The second conductive pattern CP2 may extend on the top surface 110U of the device isolation layer 110 along the first direction D1. The third conductive pattern CP3 may be on the uppermost first semiconductor pattern SP1, and may extend on the top surface 110U of the device isolation layer 110 along the first direction D1. The second conductive pattern CP2 may extend between the third conductive pattern CP3 and the gate spacers GSP, and the first conductive pattern CP1 may extend between the second conductive pattern CP1 and the gate spacers GSP. The first gate insulating pattern GI1 may extend between the first conductive pattern CP1 and the gate spacers GSP. In an example, the first conductive pattern CP1 and the third conductive pattern CP3 may include conductive metal nitride (e.g., TiN), and the second conductive pattern CP2 may include metal carbide (e.g., TiAlC).

The first gate insulating pattern GI1 may include at least one of a silicon oxide layer, a silicon nitride layer, a silicon oxynitride layer, or a high dielectric layer. The high dielectric layer may include a material having a dielectric constant greater than that of a silicon oxide layer, such as a hafnium oxide layer (HfO), an aluminum oxide layer (AlO), or a tantalum oxide layer (TaO). The gate spacers GSP may include at least one of a silicon oxide layer, a silicon nitride layer, and a silicon oxynitride layer. The spacer patterns ISP may include a low dielectric layer (e.g. silicon nitride). As an example, the spacer patterns ISP may include at least one of SiN, SiCN, SiOCN, SiBCN, and SiBN.

The first gate electrode GE1, the first channel pattern CH1, and the first source/drain patterns SD1 may constitute a Gate-All-Around type field effect transistor, or a Multi-Bridge Channel Field Effect Transistor (MBCFET).

A second gate electrode GE2 may be disposed on the second active pattern AP2 and the second channel pattern CH2. The second gate electrode GE2 may extend in the first direction D1 to cross the second active pattern AP2 and the second channel pattern CH2, and may cover the second channel pattern CH2. The second gate electrode GE2 may extend on the top surface 110U of the device isolation layer 110 along the first direction D1. The second channel pattern CH2 may vertically overlap with the second gate electrode GE2 (e.g., in the third direction D3). The second source/drain patterns SD2 may be disposed on both sides of the second gate electrode GE2. The second gate electrode GE2 may be disposed on an uppermost second semiconductor pattern SP2 of the second semiconductor patterns SP2, and may extend between the second semiconductor patterns SP2 and between the second active pattern AP2 and the lowermost second semiconductor pattern SP2 of the second semiconductor patterns SP2. The second gate electrode GE2 may cover side surfaces of the second channel pattern CH2, which are opposite to each other in the first direction D1 (for example, side surfaces of each of the second semiconductor patterns SP2, which are opposite to each other in the first direction D1).

A second gate insulating pattern GI2 may be interposed between the second active pattern AP2 and the second gate electrode GE2, and between the second channel pattern CH2 and the second gate electrode GE2. The second gate insulating pattern GI2 may be interposed between each of the second semiconductor patterns SP2 and the second gate electrode GE2, and may surround an outer surface of each of the second semiconductor patterns SP2. Each of the second semiconductor patterns SP2 may be spaced apart from the second gate electrode GE2 with the second gate insulating pattern GI2 interposed therebetween. The second gate insulating pattern GI2 may extend between each of the second source/drain patterns SD2 and the second gate electrode GE2. The second gate insulating pattern GI2 may extend along a bottom surface of the second gate electrode GE2, and may be interposed between the second gate electrode GE2 and the device isolation layer 110.

The gate spacers GSP may be disposed on side surfaces of the second gate electrode GE2. The gate spacers GSP may be disposed on the uppermost second semiconductor pattern SP2, and may extend along the side surfaces of the second gate electrode GE2. The second gate insulating pattern GI2 may extend on the side surfaces of the second gate electrode GE2 and may be interposed between the second gate electrode GE2 and the gate spacers GSP. The second gate insulating pattern GI2 may be interposed between the second gate electrode GE2 and each of the second semiconductor patterns SP2, and may extend between the second gate electrode GE2 and each of the second source/drain patterns SD2. Each of the second source/drain patterns SD2 may be in contact with the second semiconductor patterns SP2, and may be spaced apart from the second gate electrode GE2 with the second gate insulating pattern GI2 interposed therebetween. Each of the second source/drain patterns SD2 may be in contact with the second gate insulating pattern GI2.

The second gate electrode GE2 may include a doped semiconductor, a conductive metal nitride and/or a metal. The second gate electrode GE2 may include a material different from that of the first gate electrode GE1. According to some implementations, the second gate electrode GE2 may include a fourth conductive pattern CP4 on the second active pattern AP2 and the second channel pattern CH2, a fifth conductive pattern CP5 on the fourth conductive pattern CP4, and a sixth conductive pattern CP6 on the fifth conductive pattern CP5. The fourth conductive pattern CP4 may be on the uppermost second semiconductor pattern SP2, and may fill a space between the second semiconductor patterns SP2, and between the lowermost second semiconductor pattern SP2 and the second active pattern AP2. The fourth conductive pattern CP4 may surround the outer surface of each of the second semiconductor patterns SP2. The fourth conductive pattern CP4 may extend on the top surface 110U of the device isolation layer 110 along the first direction D1. The fifth conductive pattern CP5 may be on the uppermost second semiconductor pattern SP2, and may extend on the top surface 110U of the device isolation layer 110 along the first direction D1. The sixth conductive pattern CP6 may be on the uppermost second semiconductor pattern SP2, and may extend on the top surface 110U of the device isolation layer 110 along the first direction D1. The fifth conductive pattern CP5 may extend between the sixth conductive pattern CP6 and the gate spacers GSP, and the fourth conductive pattern CP4 may extend between the fifth conductive pattern CP5 and the gate spacers GSP. The second gate insulating pattern GI2 may extend between the fourth conductive pattern CP4 and the gate spacers GSP. As an example, the fourth conductive pattern CP4 and the fifth conductive pattern CP5 may include different conductive metal nitrides. As an example, the fourth conductive pattern CP4 may include TiAlN, and the fifth conductive pattern CP5 may include TiN. The sixth conductive pattern CP6 may include metal carbide (e.g. TiAlC).

The second gate insulating pattern GI2 may include at least one of a silicon oxide layer, a silicon nitride layer, a silicon oxynitride layer, or a high dielectric layer. The high dielectric layer may include a material having a dielectric constant greater than that of a silicon oxide layer, such as a hafnium oxide layer (HfO), an aluminum oxide layer (AlO), or a tantalum oxide layer (TaO).

The second gate electrode GE2, the second channel pattern CH2, and the second source/drain patterns SD2 may constitute a Gate-All-Around type field effect transistor, or a Multi-Bridge Channel Field Effect Transistor (MBCFET).

A separation insulating pattern 200 may be disposed between the first gate electrode GE1 and the second gate electrode GE2, and may be disposed on the device isolation layer 110 between the first active pattern AP1 and the second active pattern AP2. The separation insulating pattern 200 may extend between the first gate insulating pattern GI1 and the second gate insulating pattern GI2 to be in contact with the top surface 110U of the device isolation layer 110, and may extend in the third direction D3 to separate the first gate electrode GE1 and the second gate electrode GE2 from each other. The first gate electrode GE1 and the second gate electrode GE2 may be spaced apart from each other in the first direction D1 with the separation insulating pattern 200 interposed therebetween, and may be aligned with each other in the first direction D1.

The separation insulating pattern 200 may include a lower pattern 210 and an upper pattern 220 stacked along the third direction D3. The lower pattern 210 may be interposed between the first gate electrode GE1 and the second gate electrode GE2, and may extend between the first gate insulating pattern GI1 and the second gate insulating pattern GI2 to be in contact with the top surface 110U of the device isolation layer 110. A bottom surface 210L of the lower pattern 210 may be in contact with the top surface 110U of the device isolation layer 110. According to some implementations, the top surface 110U of the device isolation layer 110 may be substantially flat, and thus the bottom surface 210L of the lower pattern 210 may also be substantially flat. The lower pattern 210 may have a pillar shape extending in the third direction D3. A top surface 210U of the lower pattern 210 may be located at a lower height than an uppermost surface CH1_U of the first channel pattern CH1 and an uppermost surface CH2_U of the second channel pattern CH2. Herein, a height may be measured in the third direction D3 from the top surface 100U of the substrate 100. The uppermost surface CH1_U of the first channel pattern CH1 may be a top surface of the uppermost first semiconductor pattern SP1 of the first semiconductor patterns SP1, and the uppermost surface CH2_U of the second channel pattern CH2 may be a top surface of the uppermost second semiconductor pattern SP2 of the second semiconductor patterns SP2.

The upper pattern 220 may be interposed between the first gate electrode GE1 and the second gate electrode GE2, and may be disposed on the lower pattern 210. A bottom surface 220L of the upper pattern 220 may be in contact with the top surface 210U of the lower pattern 210. An interface INF between the lower pattern 210 and the upper pattern 220 may be located at a lower height than the uppermost surface CH1_U of the first channel pattern CH1 and the uppermost surface CH2_U of the second channel pattern CH2. According to some implementations, the upper pattern 220 may extend in the third direction D3 and may include an empty region 230 therein. The empty region 230 may be referred to as a void or a seam, as an example. The upper pattern 220 may cover a first side surface GE1_S of the first gate electrode GE1 and a second side surface GE2_S of the second gate electrode GE2, which are opposite to each other in the first direction D1, and may cover the top surface 210U of the lower pattern 210.

According to some implementations, the gate spacers GSP may extend in the first direction D1 to cover side surfaces of the first gate electrode GE1, which are opposite to each other in the second direction D2, side surfaces of the separation insulating pattern 200, which are opposite to each other in a second direction D2, and side surfaces of the second gate electrode GE2, which are opposite to each other in second direction D2. The gate spacers GSP may cover side surfaces of the lower pattern 210, which are opposite to each other in the second direction D2, and may cover side surface of the upper pattern 220, which are opposite to each other in the second direction D2. The separation insulating pattern 200 may be interposed between the gate spacers GSP.

According to some implementations, the first conductive pattern CP1 and the second conductive pattern CP2 of the first gate electrode GE1 may cover one of side surfaces of the lower pattern 210, which are opposite to each other in the first direction D1. The first conductive pattern CP1 may be interposed between the second conductive pattern CP2 and the one of the side surfaces of the lower pattern 210, which are opposite to each other in the first direction D1. The third conductive pattern CP3 of the first gate electrode GE1 may cover one of side surfaces of the upper pattern 220, which are opposite to each other in the first direction D1. The fourth to sixth conductive patterns CP4, CP5, CP6 of the second gate electrode GE2 may cover the other of the side surfaces of the lower pattern 210, which are opposite to each other in the first direction D1. The sixth conductive pattern CP6 of the second gate electrode GE2 may cover the other of the side surfaces of the upper pattern 220, which are opposite to each other in the first direction D1.

The lower pattern 210 and the upper pattern 220 may include an insulating material. According to some implementations, the lower pattern 210 may include silicon nitride, e.g., at least one of SiN and SiCN. The upper pattern 220 may include silicon nitride (e.g., SiN, SiCN), silicon oxide, and/or silicon oxynitride. The lower pattern 210 and the upper pattern 220 may include the same insulating material as each other, or may include different insulating materials from each other.

Each of the lower pattern 210 and the upper pattern 220 may have a width along the first direction D1. A width 210W of the lower pattern 210 may range, for example, from 10 nm to 20 nm. According to some implementations, the width 210W of the top surface 210U of the lower pattern 210 may be the same as a width 220W of the bottom surface 220L of the upper pattern 220. A vertical length 210H of the lower pattern 210 along the third direction D3 may be, for example, greater than 0 nm and less than or equal to 35 nm.

A first interlayer insulating layer 140 may be disposed on the substrate 100 and may cover the first and second gate electrodes GE1, GE2, the gate spacers GSP, the first and second source/drain patterns SD1, SD2, and the separation insulating pattern 200. The gate spacers GSP may be interposed between the first gate electrode GE1 and the first interlayer insulating layer 140, between the separation insulating pattern 200 and the first interlayer insulating layer 140, and between the second gate electrode GE2 and the first interlayer insulating layer 140. The first interlayer insulating layer 140 may include at least one of a silicon oxide layer, a silicon nitride layer, a silicon oxynitride layer, or low dielectric layers.

An upper layer 150 may be disposed on the first interlayer insulating layer 140 and may cover uppermost surfaces of the first and second gate electrodes GE1, GE2 and the gate spacers GSP. The separation insulating pattern 200 may extend in the third direction D3 and penetrate through the upper layer 150. The upper layer 150 may include, for example, silicon nitride. According to some implementations, the upper layer 150 may be provided locally on uppermost surfaces of the first and second gate electrodes GE1, GE2. In this case, the first interlayer insulating layer 140 and the gate spacers GSP may extend on side surfaces of the upper layer 150, and the upper layer 150 may include silicon nitride or metal.

A second interlayer insulating layer 160 may be disposed on the upper layer 150 and may cover an uppermost surface of the separation insulating pattern 200. The second interlayer insulating layer 160 may include at least one of a silicon oxide layer, a silicon nitride layer, a silicon oxynitride layer, or low dielectric layers.

Active contacts AC may be disposed on both sides of each of the first gate electrode GE1 and the second gate electrode GE2, and may be connected to the first and second source/drain patterns SD1, SD2. Each of the active contacts AC may penetrate through the second interlayer insulating layer 160, the upper layer 150 and the first interlayer insulating layer 140 and be connected to a corresponding one of the first and second source/drain patterns SD1, SD2. The active contacts AC may include a conductive material.

According to the present disclosure, the separation insulating pattern 200 may include the lower pattern 210 and the upper pattern 220 stacked along the third direction D3. The lower pattern 210 may be formed prior to formation of the first and second gate electrodes GE1 and GE2, and the upper pattern 220 may be formed to penetrate through the first and second gate electrodes GE1 and GE2 after the formation of the first and second gate electrodes GE1 and GE2. In this case, as the lower pattern 210 is provided between the device isolation layer 110 and the upper pattern 220, loss of the device isolation layer 110 during formation of the upper pattern 220 may be minimized. Further, as the upper pattern 220 is formed on the lower pattern 210, a vertical length (e.g., a length along the third direction D3) of the upper pattern 220 may be reduced, thereby facilitating formation of the upper pattern 220.

In addition, the interface INF between the lower pattern 210 and the upper pattern 220 may be located at a lower height than the uppermost surface CH1_U of the first channel pattern CH1 and the uppermost surface CH2_U of the second channel pattern CH2. That is, the top surface 210U of the lower pattern 210 may be positioned at a lower height than the uppermost surface CH1_U of the first channel pattern CH1 and the uppermost surface CH2_U of the second channel pattern CH2, and thus, layers formed between the first channel pattern CH1 and the lower pattern 210 and between the second channel pattern CH2 and the lower pattern 210 may be easily removed during a manufacturing process of a semiconductor device.

Accordingly, a semiconductor device that can minimize manufacturing defects, is easy to manufacture, and has excellent reliability and a method of fabricating the same may be provided.

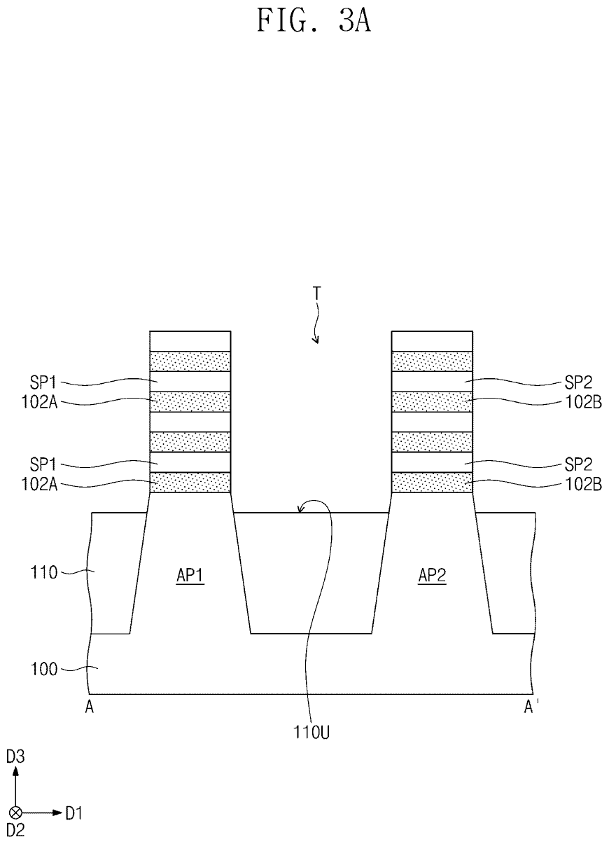

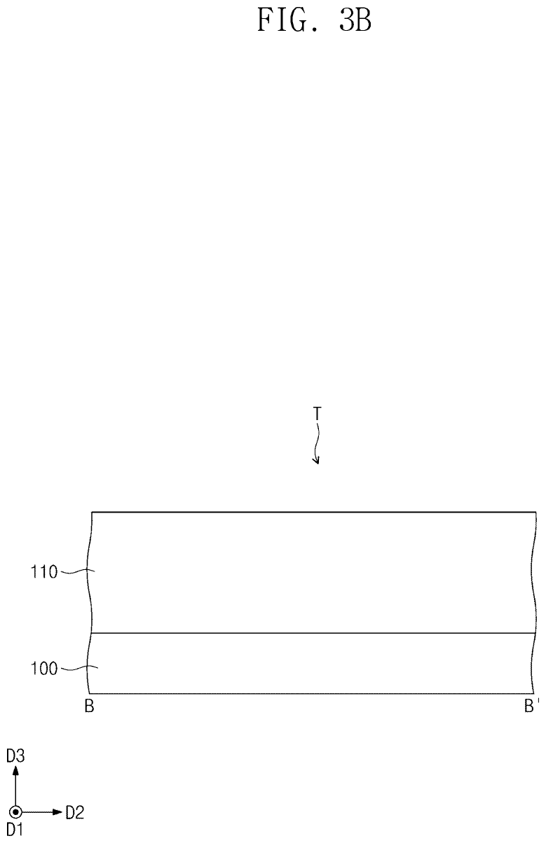

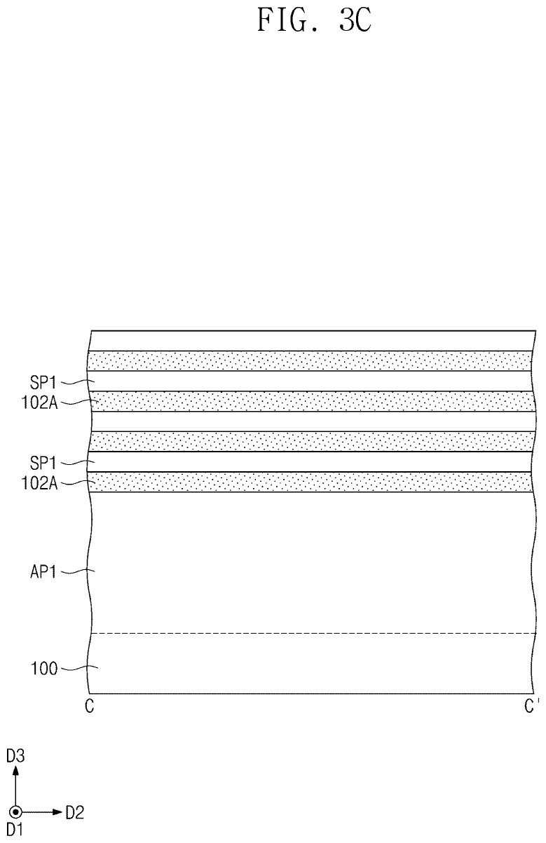

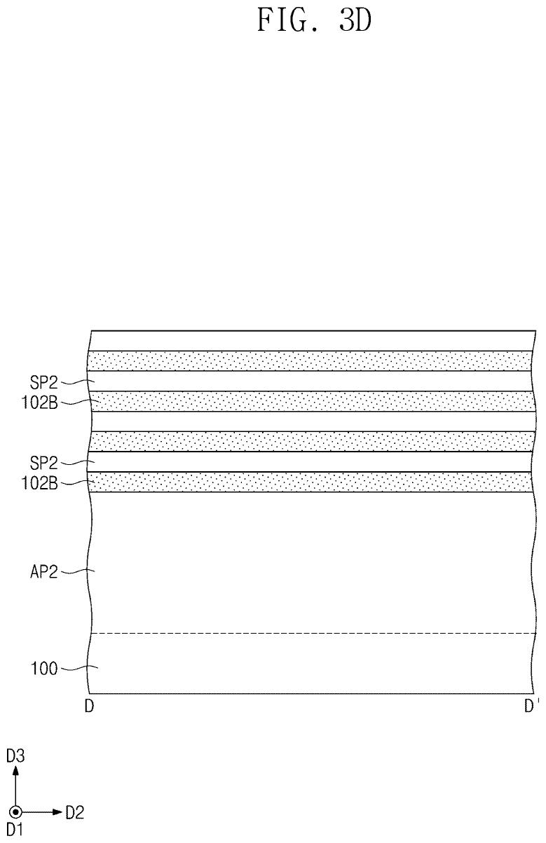

FIGS. 3A to 20A, FIGS. 3B to 20B, FIGS. 3C to 20C, and FIGS. 3D to 20D are cross-sectional views illustrating a method of fabricating a semiconductor device according to some implementations of the present disclosure. FIGS. 3A to 20A are cross-sectional views corresponding to the line A-A′ of FIG. 1, FIGS. 3B to 20B are cross-sectional views corresponding to the line B-B′ of FIG. 1, FIGS. 3C to 20C are cross-sectional views corresponding to the line C-C′ of FIG. 1, and FIGS. 3D to 20D are cross-sectional views corresponding to the line D-D′ of FIG. 1. For simplicity of description, duplicate description for that of the semiconductor device described with reference to FIGS. 1 and 2A to 2D will be omitted.

Referring to FIGS. 1 and 3A to 3D, a first active pattern AP1 and a second active pattern AP2 may be formed on a substrate 100. The first active pattern AP1 and the second active pattern AP2 may be spaced apart from each other in the first direction D1 and may extend in the second direction D2. First semiconductor patterns SP1 may be formed on the first active pattern AP1 and may be spaced apart from each other along the third direction D3. A lowermost first semiconductor pattern SP1 of the first semiconductor patterns SP1 may be spaced apart from the first active pattern AP1 along the third direction D3. Second semiconductor patterns SP2 may be formed on the second active pattern AP2 and may be spaced apart from each other along the third direction D3. A lowermost second semiconductor pattern SP2 of the second semiconductor patterns SP2 may be spaced apart from the second active pattern AP2 along the third direction D3.

First sacrificial patterns 102A may be formed between the first active pattern AP1 and the lowermost first semiconductor pattern SP1, and between the first semiconductor patterns SP1. Second sacrificial patterns 102B may be formed between the second active pattern AP2 and the lowermost second semiconductor pattern SP2, and between the second semiconductor patterns SP2. The first semiconductor patterns SP1 and the first sacrificial patterns 102A may extend in the second direction D2 on the first active pattern AP1, and the second semiconductor patterns SP2 and the second sacrificial pattern 102B may extend in the second direction D2 on the second active pattern AP2. The first and second sacrificial patterns 102A and 102B may include a material having etch selectivity with respect to the first and second semiconductor patterns SP1 and SP2. In one example, the first and second sacrificial patterns 102A and 102B may include silicon-germanium (SiGe) and the first and second semiconductor patterns SP1 and SP2 may include silicon (Si).

Forming the first and second semiconductor patterns SP1 and SP2, the first and second sacrificial patterns 102A and 102B, and the first and second active patterns AP1 and AP2 may include, for example, alternately and repeatedly stacking sacrificial layers and semiconductor layers on the substrate 100, and patterning the sacrificial layers, the semiconductor layers, and an upper portion of the substrate 100 to form trenches T defining the first and second semiconductive patterns SP1 and SP2, the first and second sacrificial patterns 102A and 102B, and the first and second active patterns AP1 and AP2. The trenches T may have a line shape extending in the second direction D2 and may be spaced apart from each other in the first direction D1.

A device isolation layer 110 may be formed to fill a lower portion of each of the trenches T. Forming the device isolation layer 110 may include, for example, forming an insulating layer filling the trenches T on the substrate 100, and recessing the insulating layer so that side surfaces of the first and second semiconductor patterns SP1 and SP2 and the first and second sacrificial patterns 102A and 102B are exposed. The device isolation layer 110 may extend in the second direction D2 between the first active pattern AP1 and the second active pattern AP2.

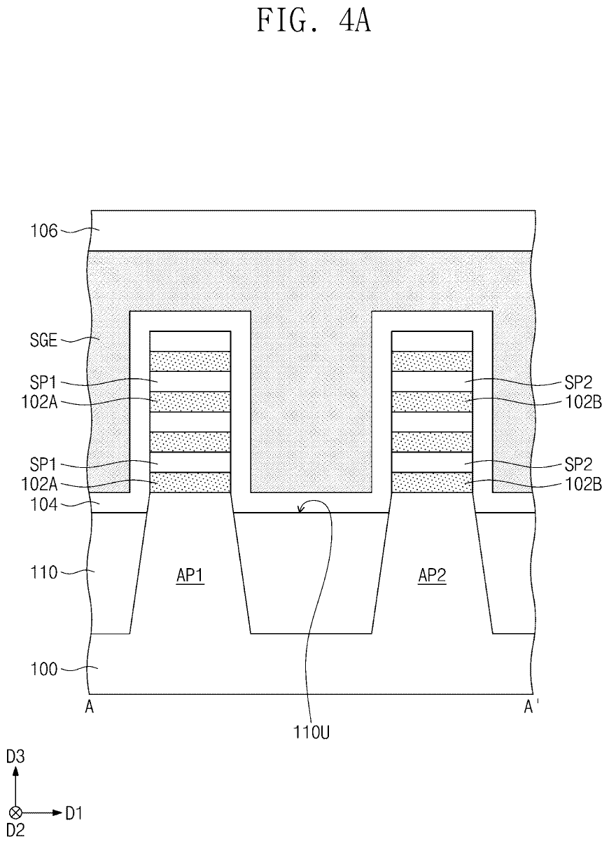

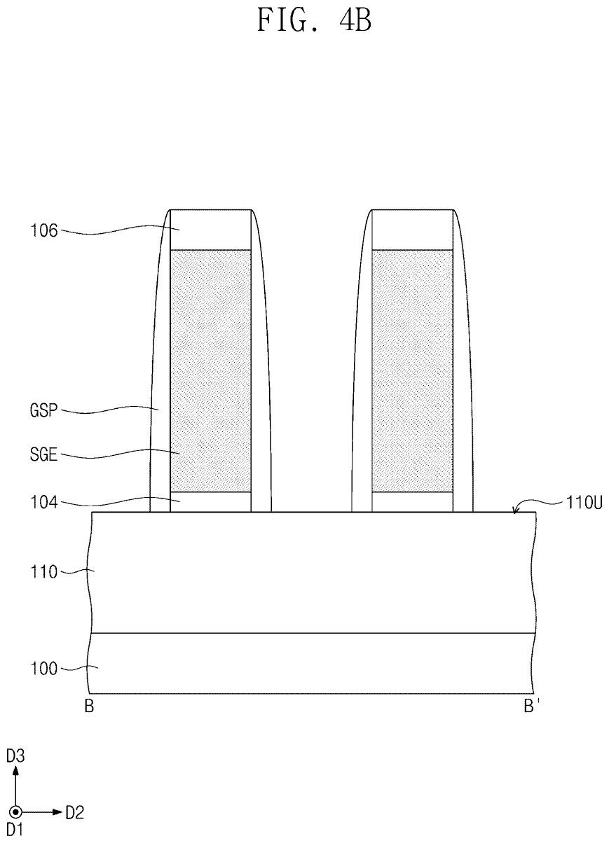

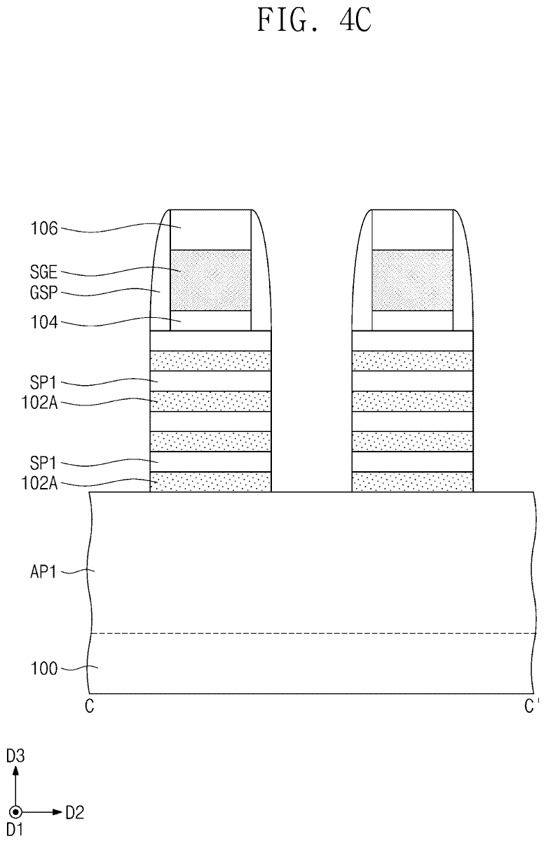

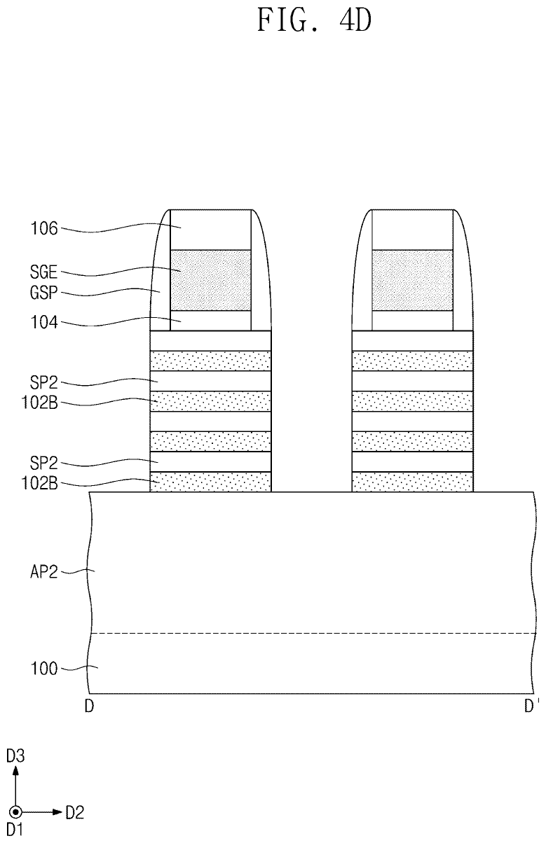

Referring to FIGS. 1 and 4A to 4D, a sacrificial gate pattern SGE may be formed to cross the first and second active patterns AP1 and AP2, the first and second semiconductor patterns SP1 and SP2, and the first and second sacrificial patterns 102A and 102B. The sacrificial gate pattern SGE may extend in the first direction D1 to cross the first and second active patterns AP1 and AP2, the first and second semiconductor patterns SP1 and SP2, the first and the second sacrificial patterns 102A and 102B, and the device isolation layer 110. The sacrificial gate pattern SGE may cover side surfaces of each of the first and second semiconductor patterns SP1 and SP2 and the first and second sacrificial patterns 102A and 102B, which are opposite to each other in the first direction D1, and may cover a top surface 110U of the device isolation layer 110.

An etch stop pattern 104 may extend in the first direction D1 along a bottom surface of the sacrificial gate pattern SGE. The etch stop pattern 104 may be interposed between the side surfaces of each of the first and second semiconductor patterns SP1 and SP2 and the first and second sacrificial patterns 102A and 102B, which are opposite to each other in the first direction D1, and the sacrificial gate pattern SGE, and may extend between the sacrificial gate pattern SGE and the device isolation layer 110. A mask pattern 106 may extend in the first direction D1 along a top surface of the sacrificial gate pattern SGE.

Forming the sacrificial gate pattern SGE and the etch stop pattern 104 may include, for example, sequentially forming an etch stop layer and a sacrificial gate layer covering the first and second semiconductor patterns SP1 and SP2, the first and second sacrificial patterns 102A and 102B, and the device isolation layer 110 on the substrate 100, forming the mask pattern 106 defining a region where the sacrificial gate pattern SGE will be formed, on the sacrificial gate layer, and sequentially patterning the sacrificial gate layer and the etch stop layer using the mask pattern 106 as an etch mask. The etch stop pattern 104 may include, for example, a silicon oxide layer. The sacrificial gate pattern SGE may include a material having an etch selectivity with respect to the etch stop pattern 104. The sacrificial gate pattern SGE may include, for example, polysilicon.

Gate spacers GSP may be formed on side surfaces of the sacrificial gate pattern SGE. Forming the gate spacers GSP may include, for example, forming a gate spacer layer covering the mask pattern 106, the sacrificial gate pattern SGE, and the etch stop pattern 104 on the substrate 100, and anisotropically etching the gate spacer layer. The mask pattern 106 and the gate spacers GSP may include, for example, silicon nitride.

Portions of the first and second semiconductor patterns SP1 and SP2 and portions of the first and second sacrificial patterns 102A and 102B, at both side of the sacrificial gate pattern SGE, may be removed. Removing the portions of the first and second semiconductor patterns SP1 and SP2 and the portions of the first and second sacrificial patterns 102A and 102B may include, for example, etching the portions of the first and second semiconductor patterns SP1 and SP2 and the portions of the first and second sacrificial patterns 102A and 102B by performing an etching process using the mask pattern 106 and the gate spacers GSP as an etch mask. The etching process may be performed until top surfaces of the first and second active patterns AP1, AP2 at both side of the sacrificial gate pattern SGE are exposed.

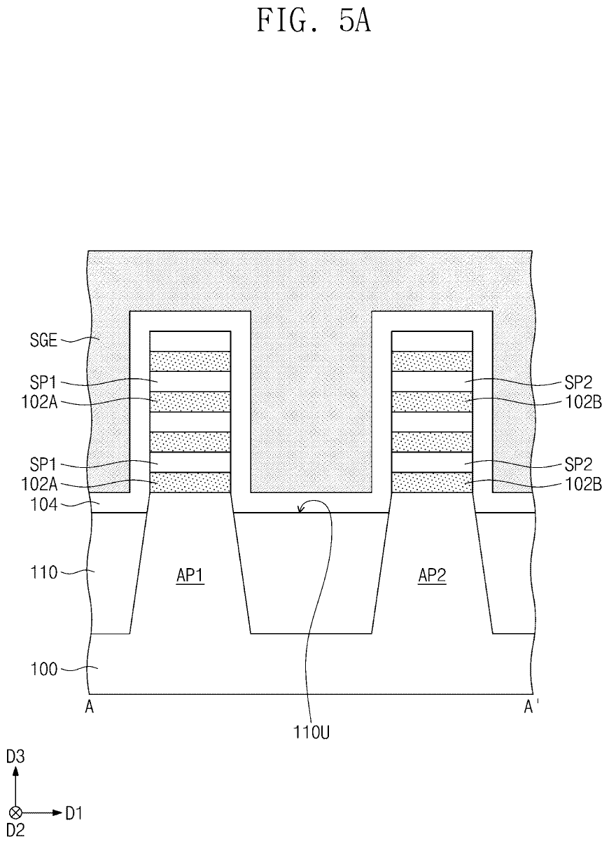

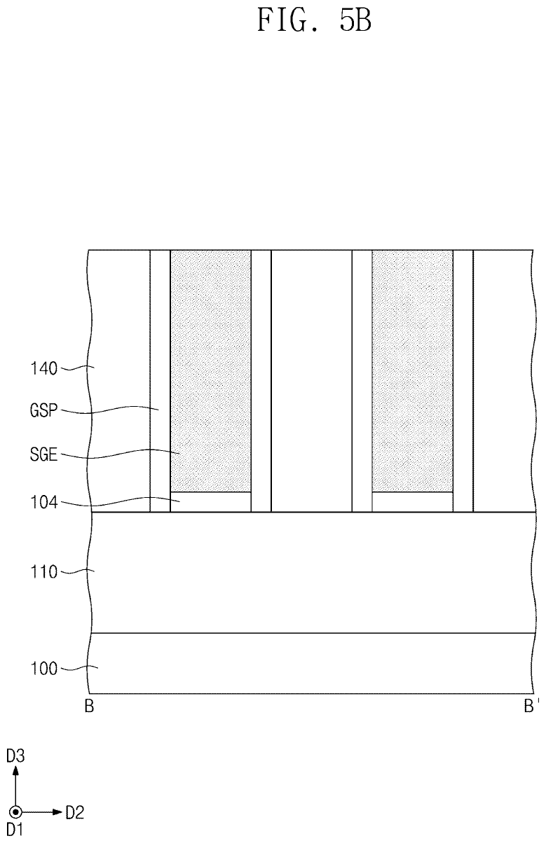

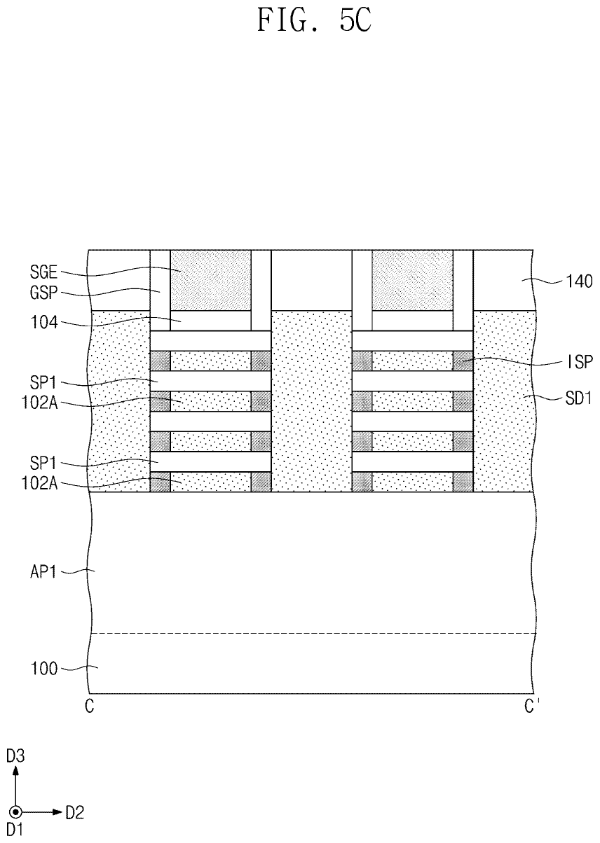

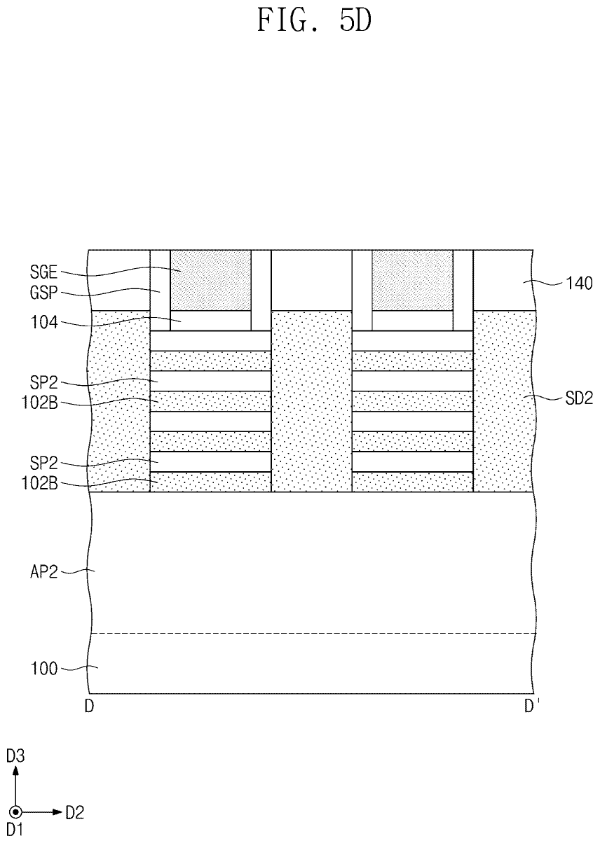

Referring to FIGS. 1 and 5A to 5D, according to some implementations, spacer patterns ISP may be formed between the first active pattern AP1 and the lowermost first semiconductor pattern SP1, and between the first semiconductor patterns SP1. Forming the spacer patterns ISP may include, for example, forming recess regions between the first active pattern AP1 and the lowermost first semiconductor pattern SP1 and between the first semiconductor patterns SP1 by horizontally recessing side surfaces of the first sacrificial patterns 102A, forming a spacer layer filling the recess regions, and anisotropically etching the spacer layer so that the spacer patterns ISP are locally formed in the recess regions, respectively.

First source/drain patterns SD1 may be formed at both sides of the sacrificial gate pattern SGE and on the first active pattern AP1. The first source/drain patterns SD1 may be formed by performing a selective epitaxial growth process using the first semiconductor patterns SP1 and the first active pattern AP1 as seeds. Each of the first source/drain patterns SD1 may be in contact with side surfaces of the first semiconductor patterns SP1. The first source/drain patterns SD1 may be spaced apart from the first sacrificial patterns 102A with the spacer patterns ISP interposed therebetween. The first source/drain patterns SD1 may be in contact with the spacer patterns ISP. Forming the first source/drain patterns SD1 may further include implanting an impurity (e.g., phosphorus (P) or boron (B)) into the first source/drain patterns SD1 at the same time as or after the selective epitaxial growth process.

Second source/drain patterns SD2 may be formed at both side of the sacrificial gate pattern SGE and on the second active pattern AP2. The second source/drain patterns SD2 may be formed by performing a selective epitaxial growth process using the second semiconductor patterns SP2 and the second active pattern AP2 as seeds. Each of the second source/drain patterns SD2 may be in contact with side surfaces of the second semiconductor patterns SP2. According to some implementations, the second source/drain patterns SD2 may be in contact with side surfaces of the second sacrificial patterns 102B. Forming the second source/drain patterns SD2 may further include implanting an impurity (e.g., phosphorus (P) or boron (B)) into the second source/drain patterns SD2 at the same time as or after the selective epitaxial growth process.

A first interlayer insulating layer 140 may be formed on the substrate 100, and may cover the sacrificial gate pattern SGE, the gate spacers GSP, the device isolation layer 110, and the first and second source/drain patterns SD1 and SD2. Forming the first interlayer insulating layer 140 may include, for example, forming an insulating layer covering the mask pattern 106, the sacrificial gate pattern SGE, the gate spacers GSP, the device isolation layer 110 and the first and second source/drain patterns SD1 and SD2 on the substrate 100, and planarizing the insulating layer until a top surface of the sacrificial gate pattern SGE is exposed. The mask pattern 106 may be removed by the planarization process.

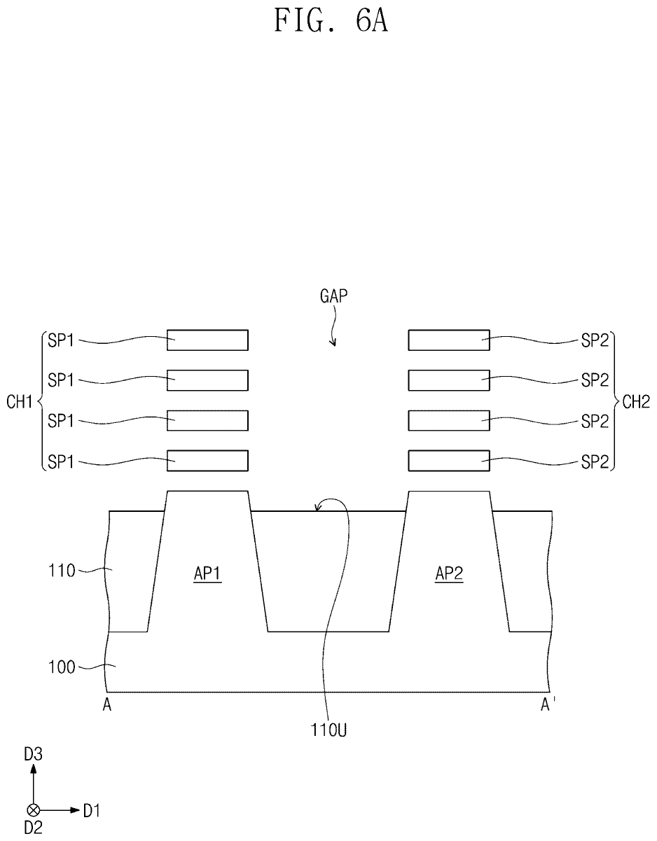

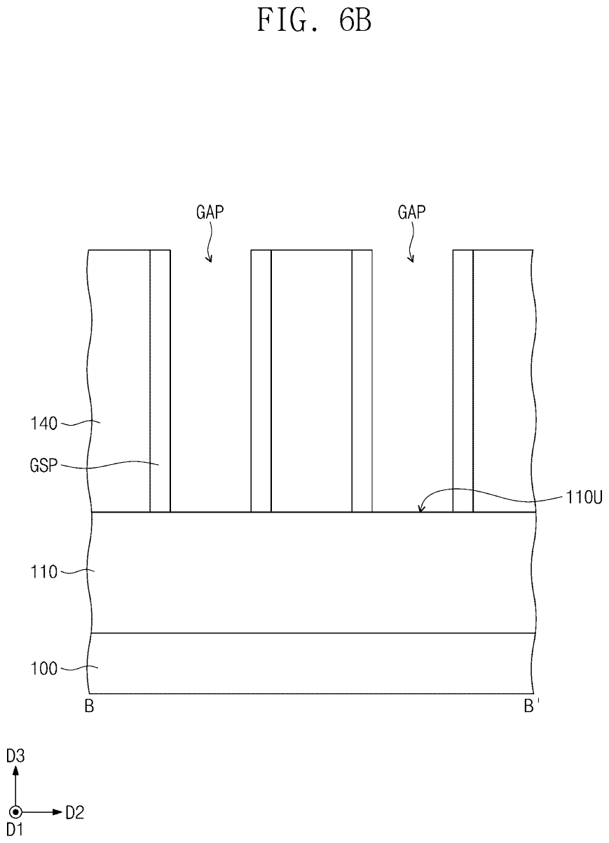

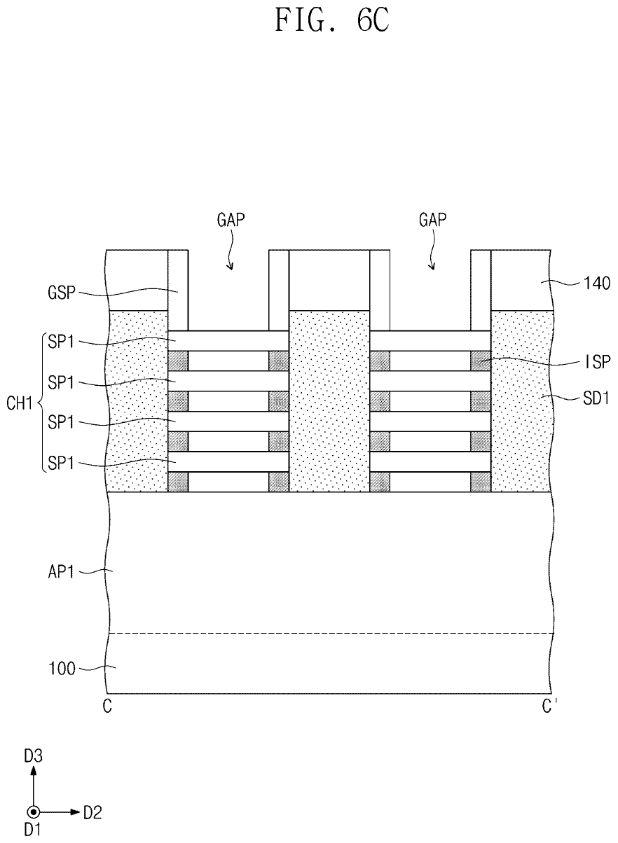

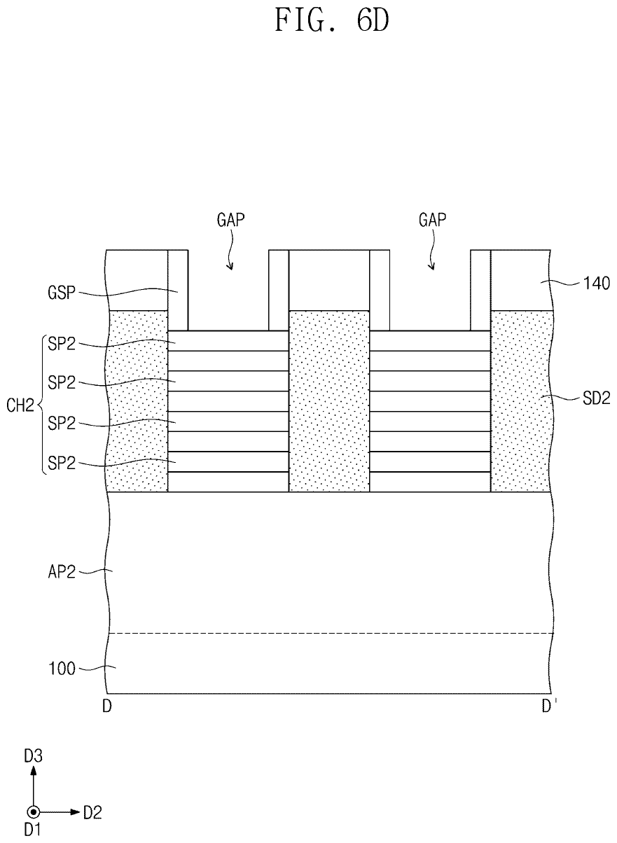

Referring to FIGS. 1 and 6A to 6D, the sacrificial gate pattern SGE and the etch stop pattern 104 may be removed, and thus a gap region GAP may be formed in the first interlayer insulating layer 140. The gap region GAP may be formed between the gate spacers GSP and may extend in the first direction D1. The gap region GAP may expose the top surface 110U of the device isolation layer 110 and may expose side surfaces of the first sacrificial patterns 102A and the second sacrificial pattern 102B. Forming the gap region GAP may further include removing the first sacrificial patterns 102A and the second sacrificial pattern 102B. Accordingly, the gap region GAP may extend between the first active pattern AP1 and the lowermost first semiconductor pattern SP1, between the first semiconductor patterns SP1, between the second active pattern AP2 and the lowermost second semiconductor pattern SP2 and between the second semiconductor patterns SP2. The first semiconductor patterns SP1 may be referred to as a first channel pattern CH1, and the second semiconductor patterns SP2 may be referred to as a second channel pattern CH2.

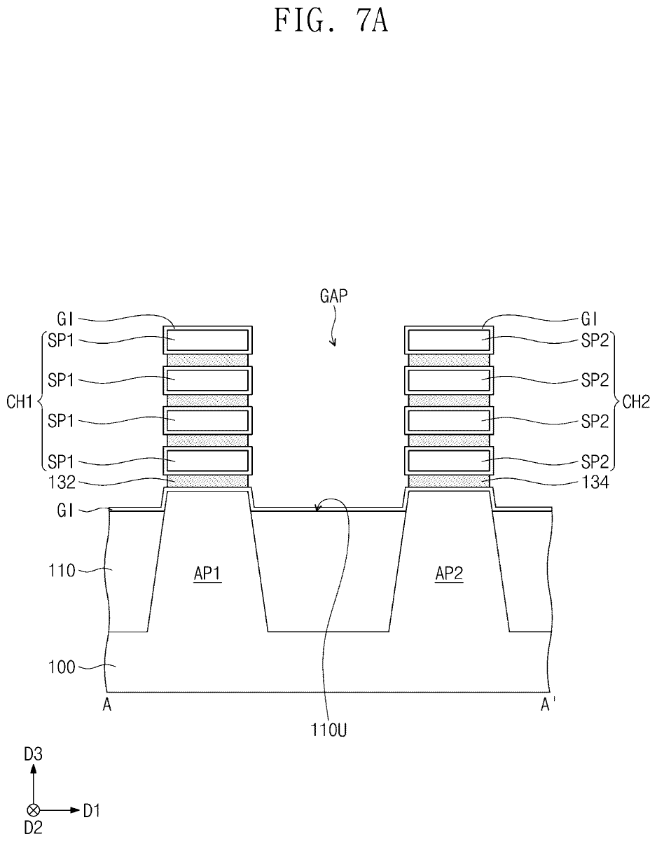

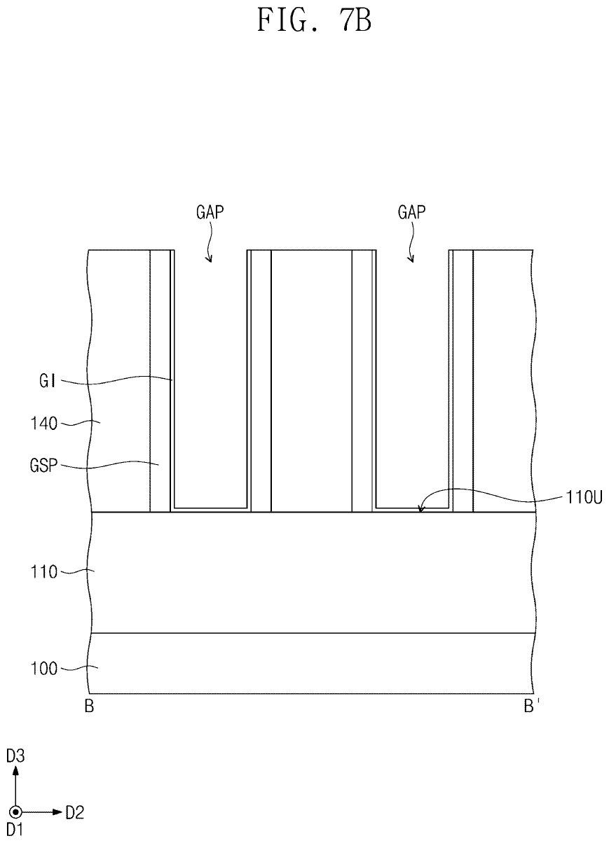

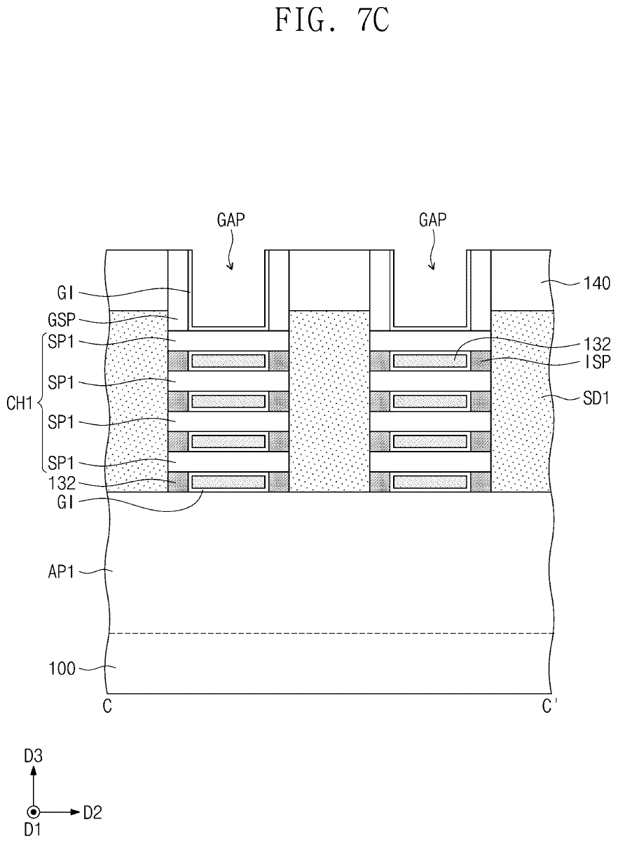

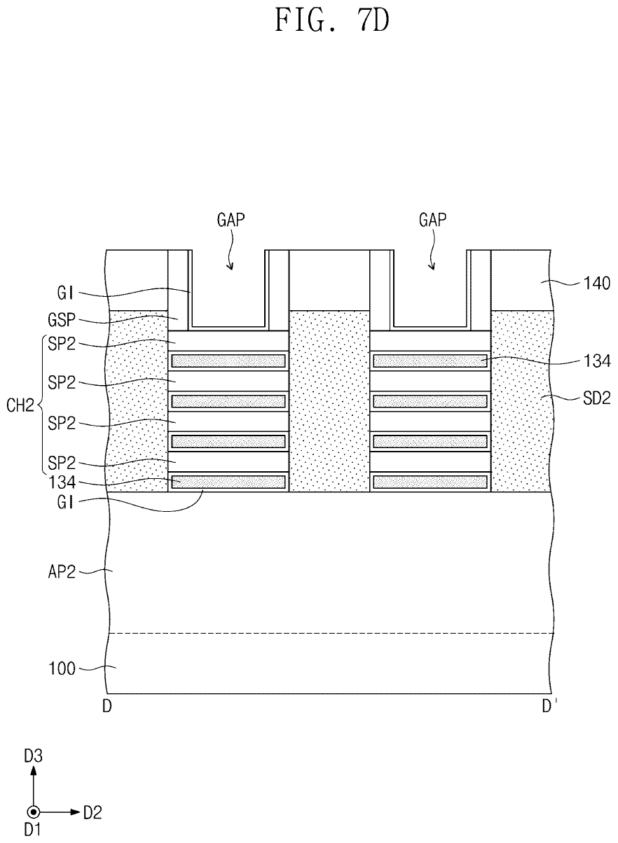

Referring to FIGS. 1 and 7A to 7D, a gate insulating layer GI may be formed to conformally cover an inner surface of the gap region GAP. The gate insulating layer GI may cover top surfaces of the first and second active patterns AP1 and AP2 and the top surface 110U of the device isolation layer 110, in the gap region GAP, and may surround an outer surface of each of the first and the second semiconductor patterns SP1 and SP2. The gate insulating layer GI may conformally cover the gate spacers GSP, the spacer patterns ISP, and the second source/drain patterns SD2, in the gap region GAP.

Third sacrificial patterns 132 may be formed to fill a space between the first active pattern AP1 and the lowermost first semiconductor pattern SP1 and between the first semiconductor patterns SP1. Fourth sacrificial patterns 134 may be formed to fill a space between the second active pattern AP2 and the lowermost second semiconductor pattern SP2 and between the second semiconductor patterns SP2. Forming the third and fourth sacrificial patterns 132 and 134 may include, for example, forming a sacrificial layer covering the first and second active patterns AP1 and AP2, the first and second semiconductor patterns SP1 and SP2, and the device isolation layer 110 in the gap region GAP, and removing a portion of the sacrificial layer so that the sacrificial layer remains locally between the first active pattern AP1 and the lowermost first semiconductor pattern SP1, between the first semiconductor patterns SP1, between the second active pattern AP2 and the lowermost second semiconductor pattern SP2, and between the second semiconductor patterns SP2. The third and fourth sacrificial patterns 132 and 134 may include a metal oxide (e.g., aluminum oxide).

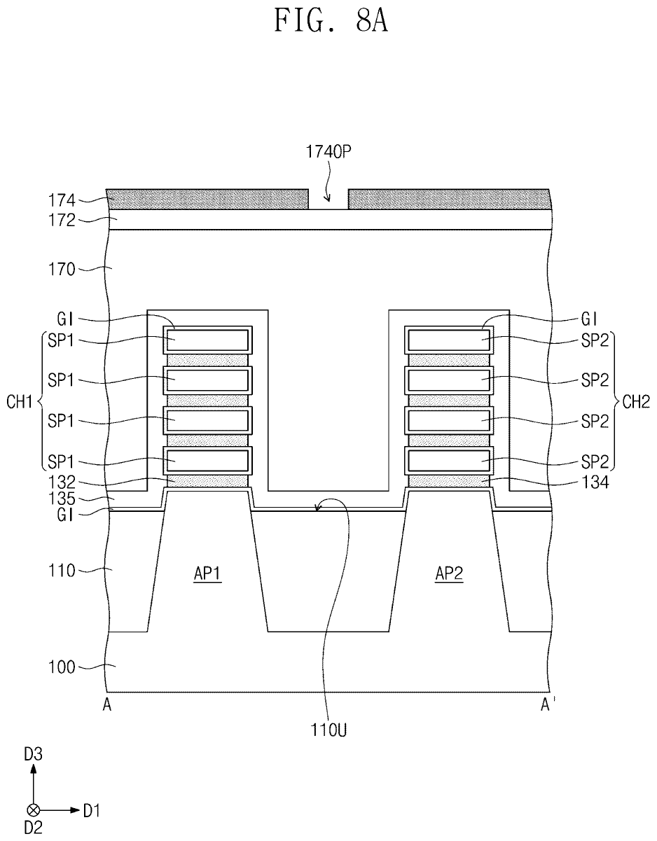

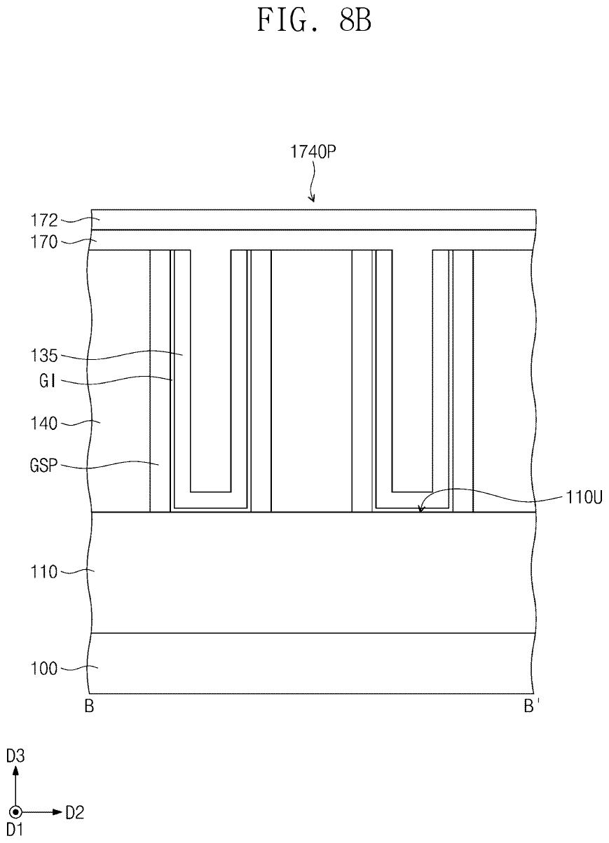

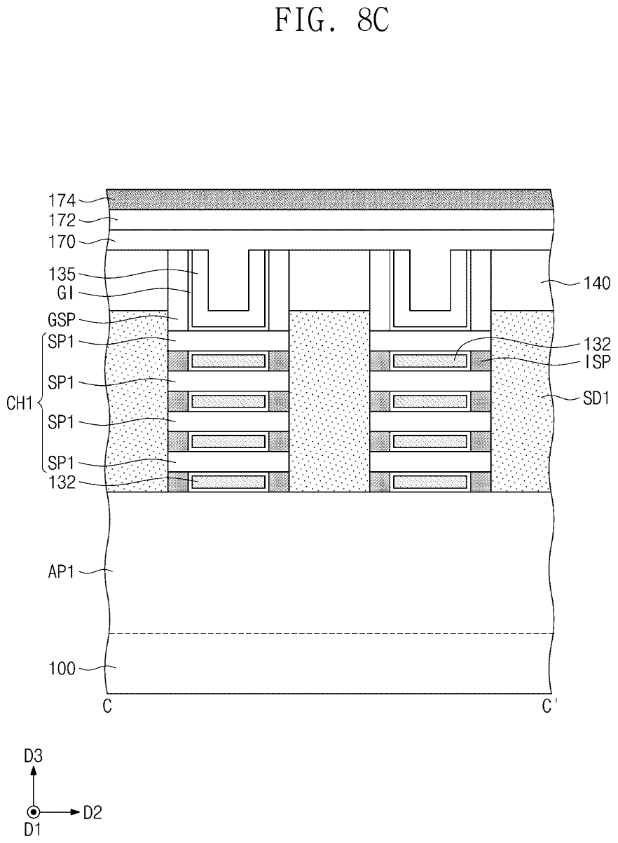

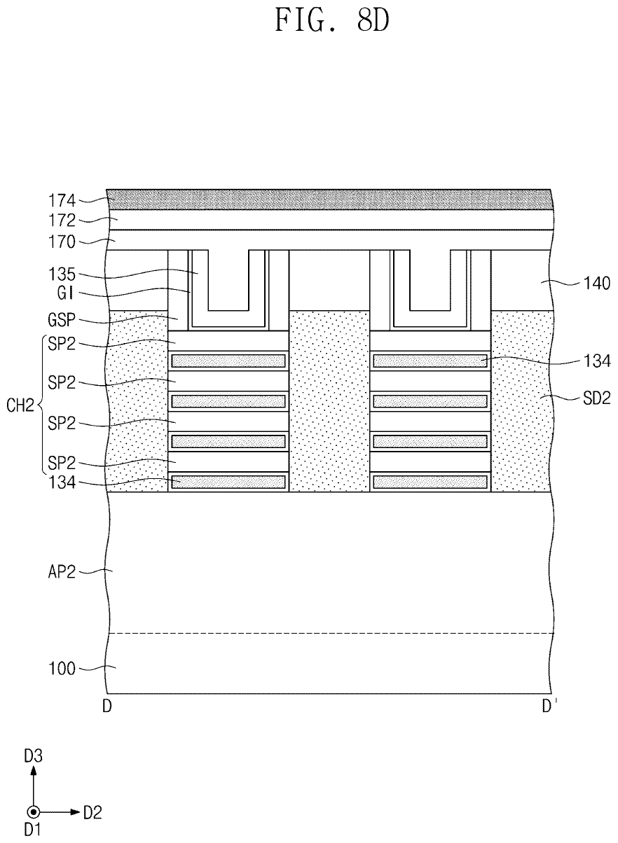

Referring to FIGS. 1 and 8A to 8D, a first protective layer 135 may be formed to fill a portion of the gap region GAP. The first protective layer 135 may conformally cover the first channel pattern CH1, the third sacrificial patterns 132, the second channel pattern CH2, and the fourth sacrificial patterns 134, and may extend on the top surface 110U of the device isolation layer 110. The first protective layer 135 may extend on the gate spacers GSP. The first protective layer 135 may include a metal nitride (e.g., TiN).

A first lower mask layer 170 may be formed to fill the remainder of the gap region GAP. The first lower mask layer 170 may cover a top surface of the first interlayer insulating layer 140. A first upper mask layer 172 may be formed on the first lower mask layer 170. The first lower mask layer 170 may include an anti-reflective material (e.g., a bottom anti-reflective coating (BARC) material), and the first upper mask layer 172 may include a metal oxide (e.g., TiO₂).

A first photoresist pattern 174 may be formed on the first upper mask layer 172. The first photoresist pattern 174 may have a first opening 174OP that vertically overlaps with the device isolation layer 110 between the first channel pattern CH1 and the second channel pattern CH2 (in the third direction D3, for example). The first opening 174OP may have a line shape extending in the second direction D2.

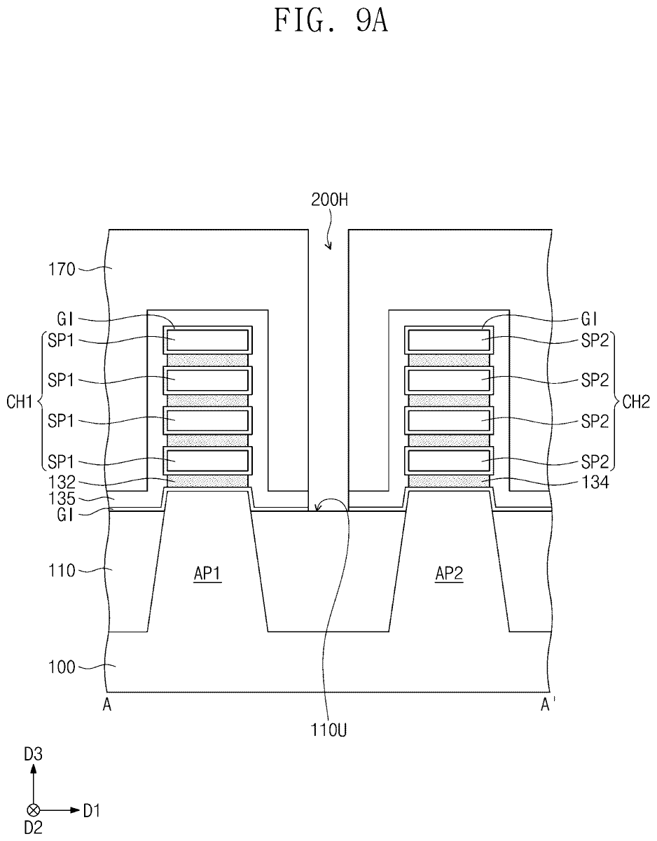

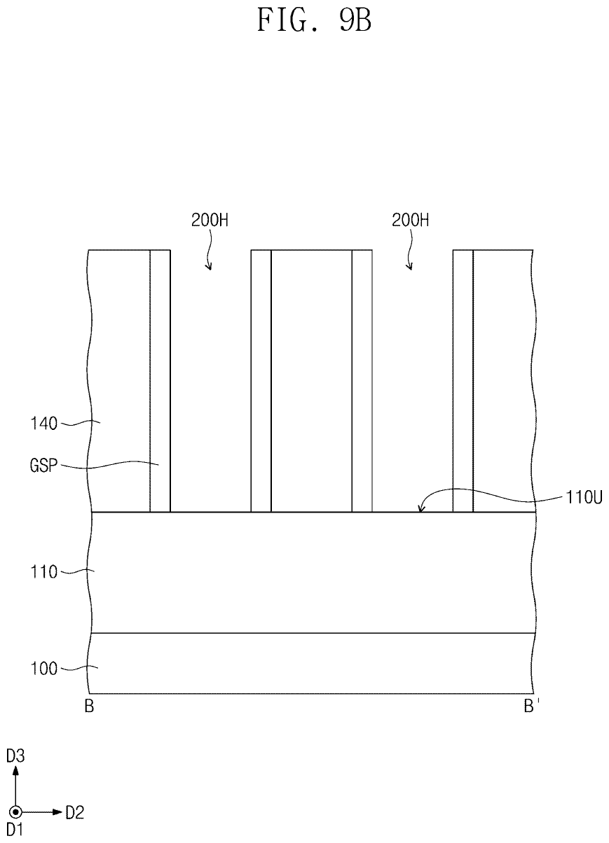

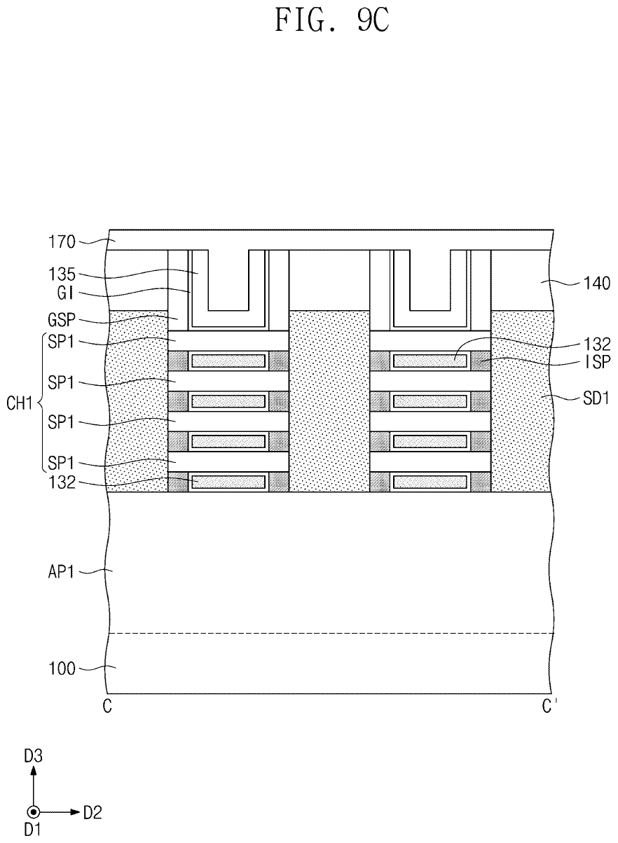

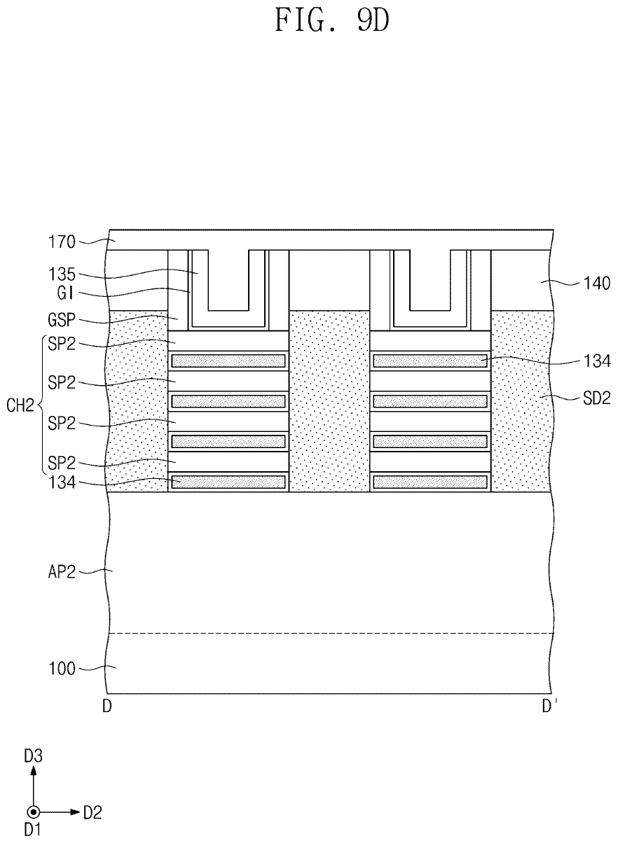

Referring to FIGS. 1 and 9A to 9D, an etching process of etching portions of the first upper mask layer 172, the first lower mask layer 170, the first protective layer 135, and the gate insulating layer GI, which are exposed by the first opening 174OP, may be performed. During the etching process, the first interlayer insulating layer 140 and the gate spacers GSP may not be etched. Thus, a first separation hole 200H may be formed on the device isolation layer 110 between the first channel pattern CH1 and the second channel pattern CH2, and between the gate spacers GSP. The first separation hole 200H may extend in the third direction D3 between the gate spacers GSP, and may penetrate through the first upper mask layer 172, the first lower mask layer 170, the first protective layer 135, and the gate insulating layer GI. The first separation hole 200H may expose the top surface 110U of the device isolation layer 110 between the first channel pattern CH1 and the second channel pattern CH2. After the first separation hole 200H is formed, the first photoresist pattern 174 and the first upper mask layer 172 may be removed.

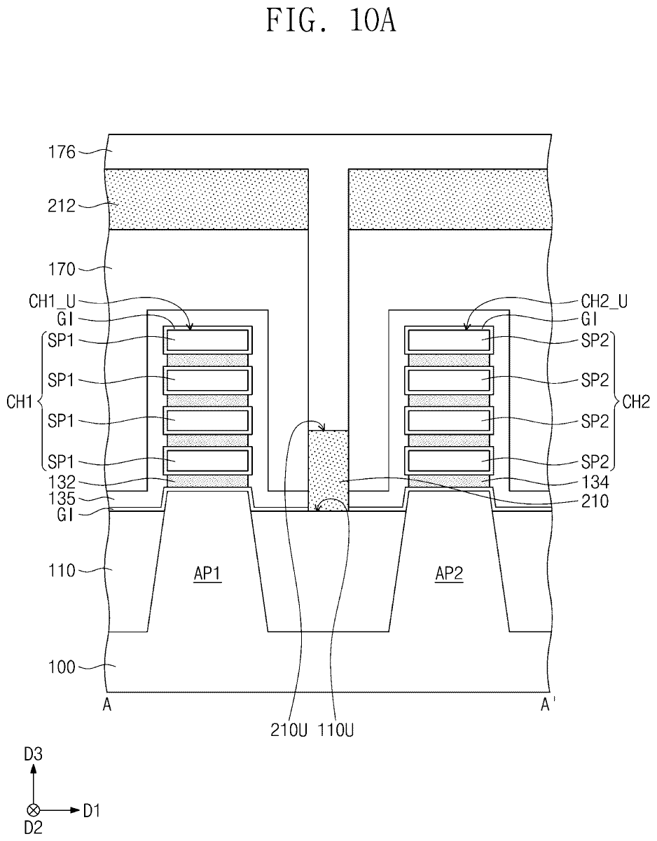

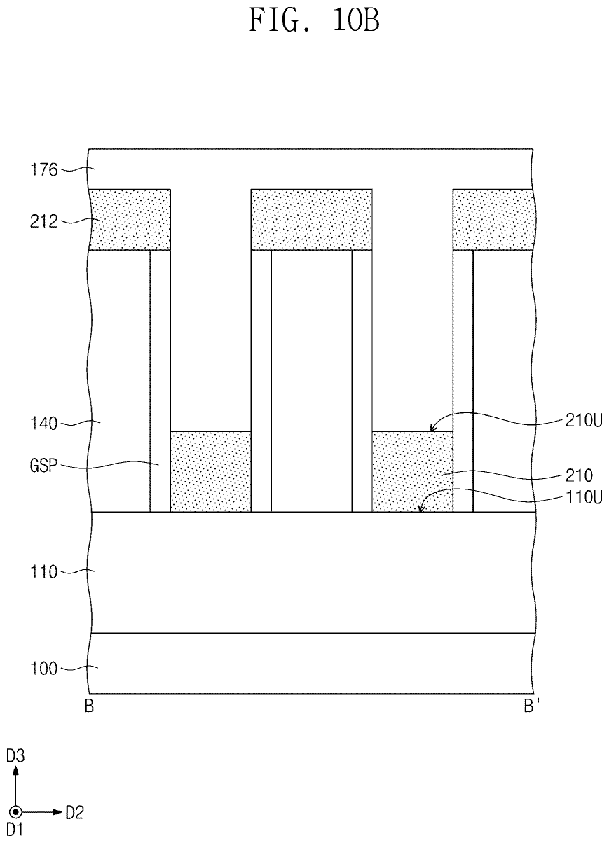

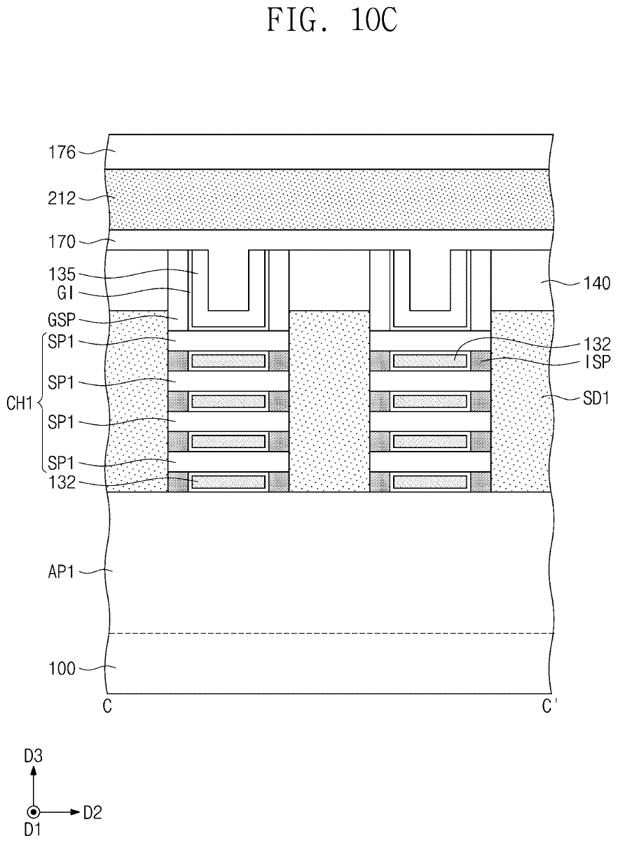

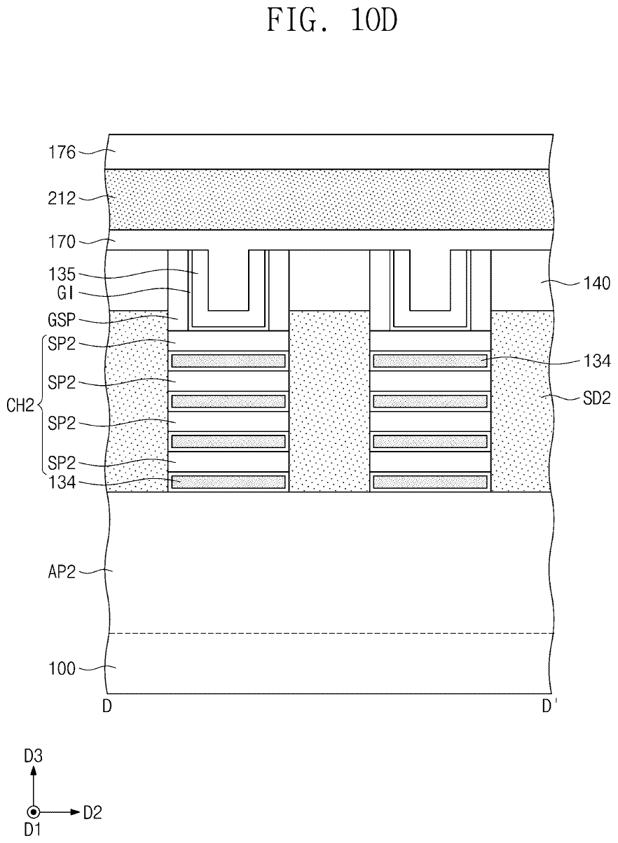

Referring to FIGS. 1 and 10A to 10D, a lower pattern 210 may be formed to fill a lower portion of the first separation hole 200H. The lower pattern 210 may be formed using a bottom-up filling process. The lower pattern 210 may be in contact with the top surface 110U of the device isolation layer 110 and may have a pillar shape extending in the third direction D3. A top surface 210U of the lower pattern 210 may be located at a lower height than an uppermost surface CH1_U of the first channel pattern CH1 and an uppermost surface CH2_U of the second channel pattern CH2. The uppermost surface CH1_U of the first channel pattern CH1 may be a top surface of an uppermost first semiconductor pattern SP1 of the first semiconductor patterns SP1, and the uppermost surface CH2_U of the second channel pattern CH2 may be a top surface of an uppermost second semiconductor pattern SP2 of the second semiconductor patterns SP2.

During the bottom-up filling process, a lower layer 212 may be formed on the first lower mask layer 170 and the first interlayer insulating layer 140, and may be formed so as to cover uppermost surfaces of the gate spacers GSP. The lower layer 212 may include the same material as the lower pattern 210. A second protective layer 176 may be formed on the lower layer 212 and may fill the remainder of the first separation hole 200H. The second protective layer 176 may include, for example, silicon oxide.

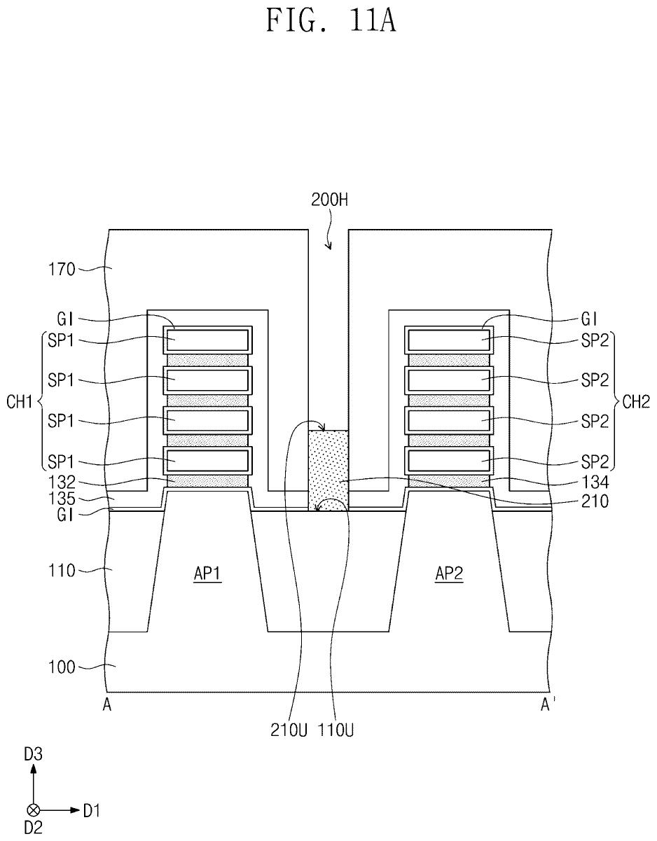

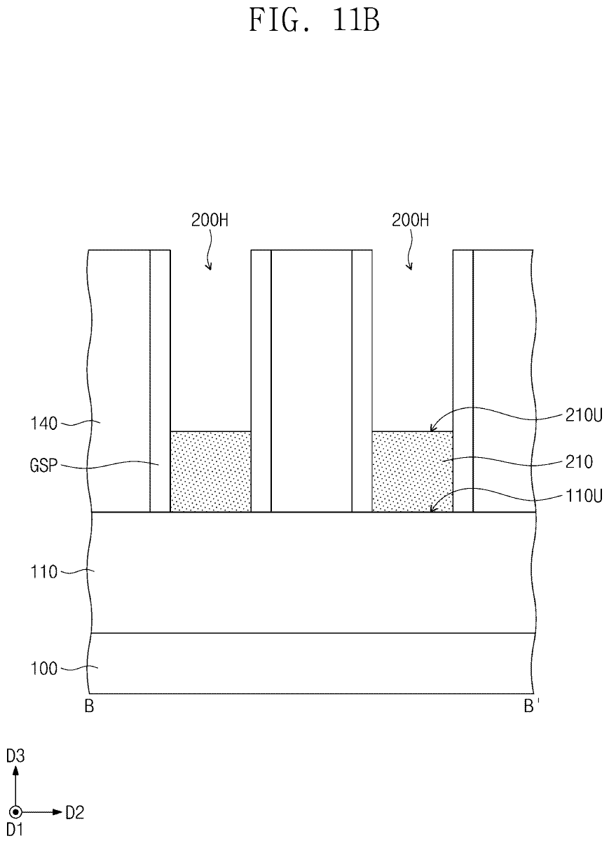

Referring to FIGS. 1 and 11A to 11D, the second protective layer 176, the lower layer 212, and the first lower mask layer 170 may be planarized until the top surface of the first interlayer insulating layer 140 and the uppermost surfaces of the gate spacers GSP are exposed. By the planarization process, the remainder of the second protective layer 176 may remain in the first separation hole 200H, and the lower layer 212 may be removed. By the planarization process, the remainder of the first lower mask layer 170 may remain between the gate spacers GSP. After the planarization process, the remainder of the second protective layer 176 may be removed in the first separation hole 200H, and thus, the top surface 210U of the lower pattern 210 may be exposed. Removing the remainder of the second protective layer 176 may be performed using, for example, a dry or wet etching process.

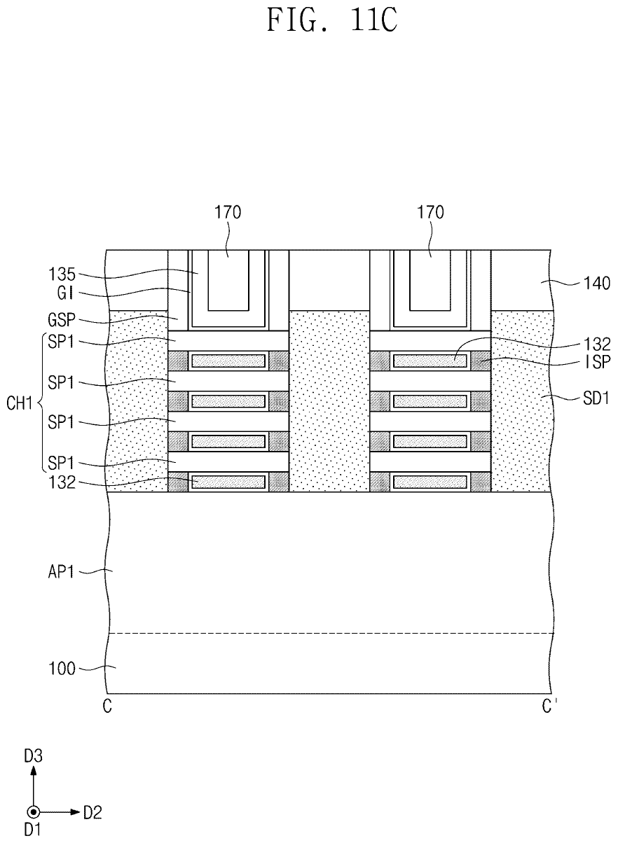

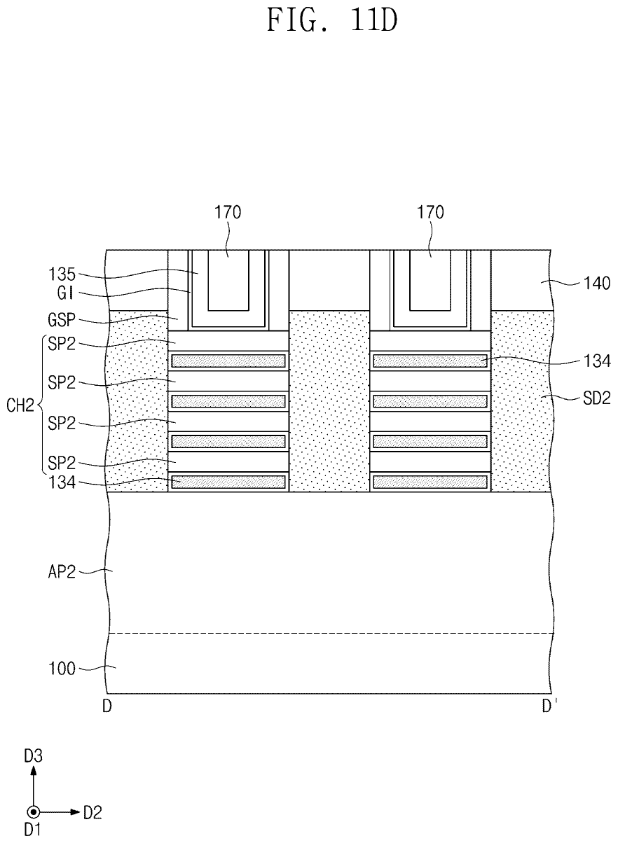

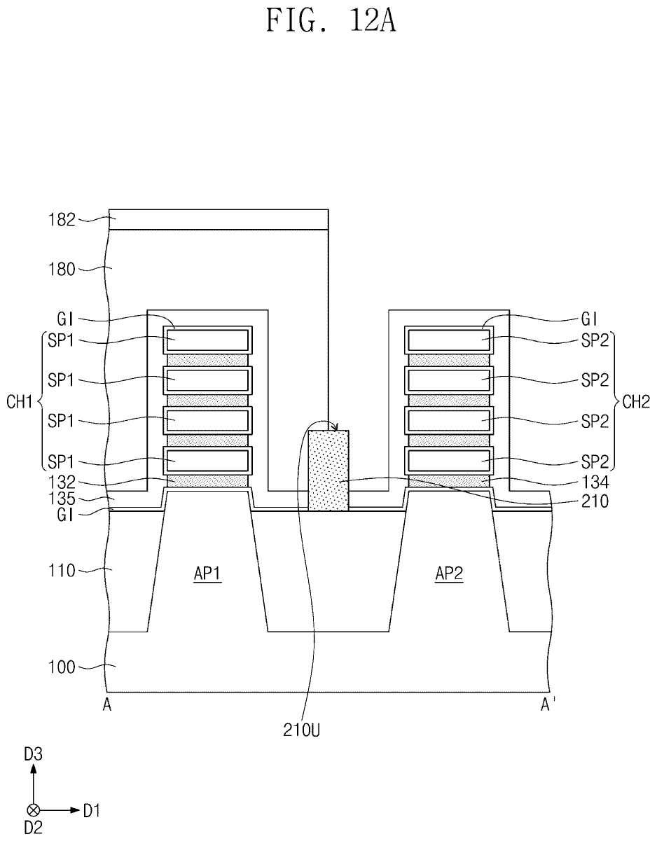

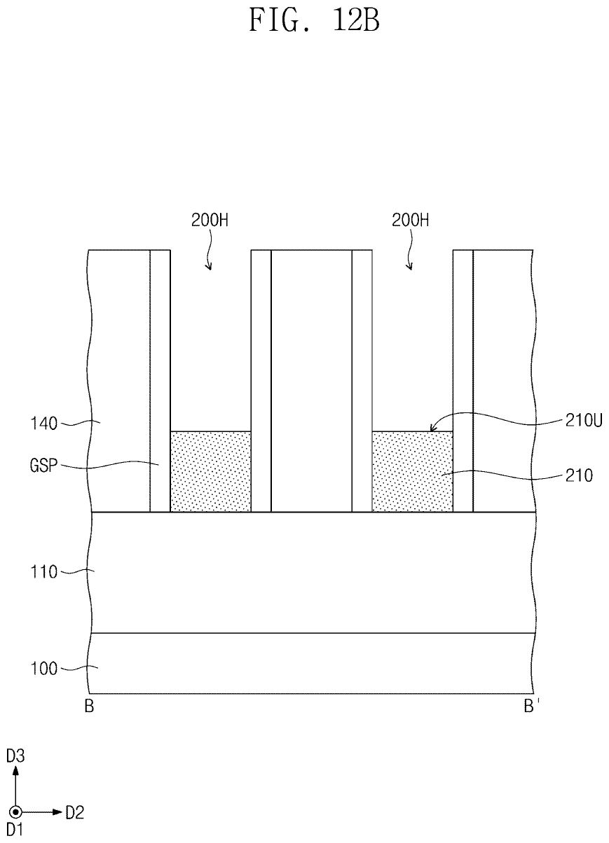

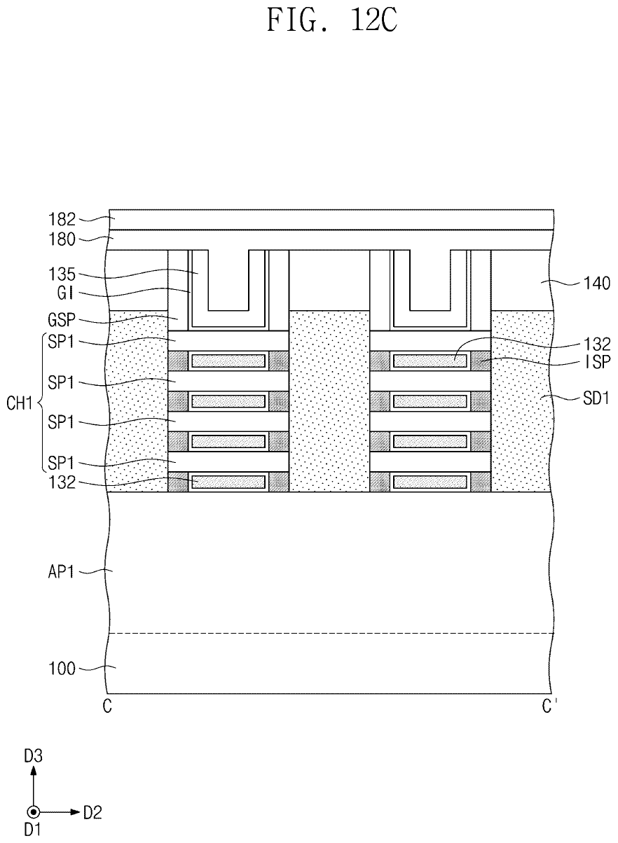

Referring to FIGS. 1 and 12A to 12D, the remainder of the first lower mask layer 170 may be removed. Removing the remainder of the first lower mask layer 170 may be performed using, for example, an ashing and/or strip process.

A second lower mask layer 180 may be formed on the first interlayer insulating layer 140, and may extend between the gate spacers GSP to cover the first channel pattern CH1 and the third sacrificial patterns 132. The second lower mask layer 180 may cover the first protective layer 135 on the first channel pattern CH1 and the third sacrificial patterns 132, and may cover a portion of the lower pattern 210. A second upper mask layer 182 may be formed on the second lower mask layer 180. The second lower mask layer 180 and the second upper mask layer 182 may expose the first protective layer 135 on the second channel pattern CH2 and the fourth sacrificial patterns 134, and may expose the remainder of the lower pattern 210. The second lower mask layer 180 may include an anti-reflective material (e.g., a bottom anti-reflective coating (BARC) material), and the second upper mask layer 182 may include a metal oxide (e.g., TiO₂).

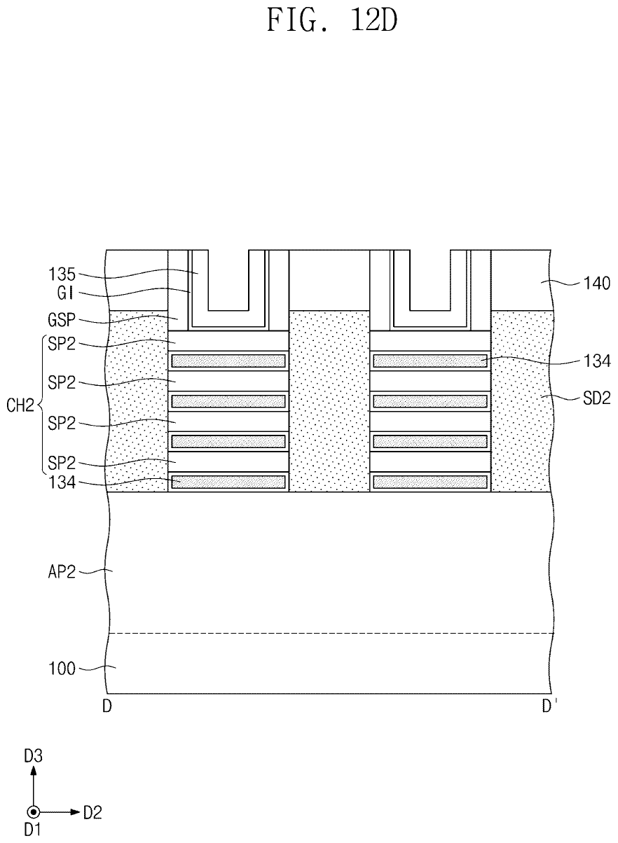

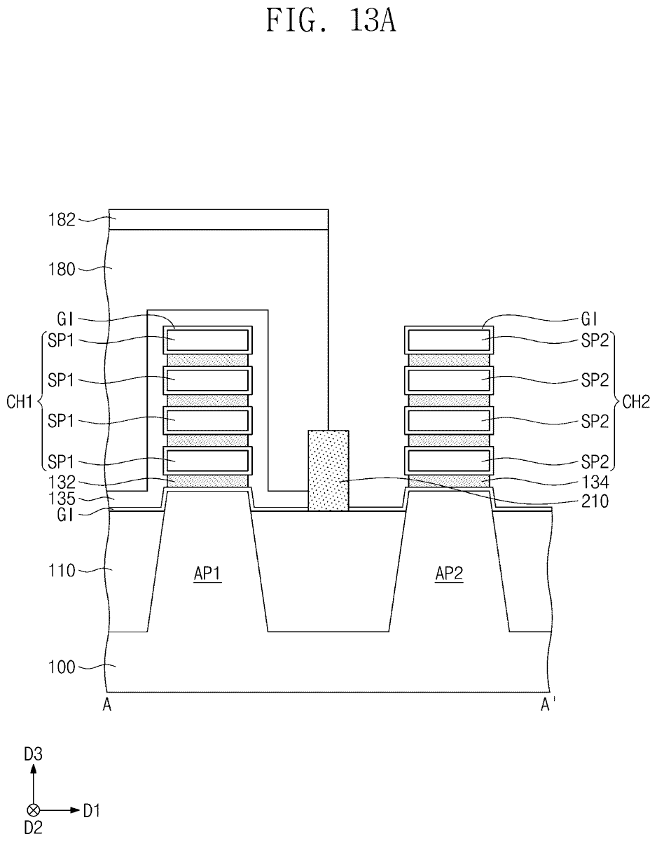

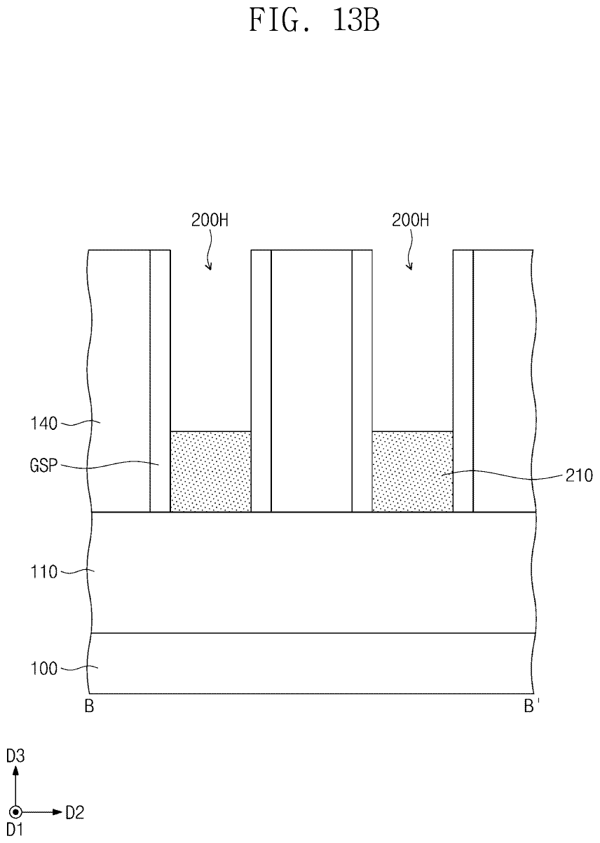

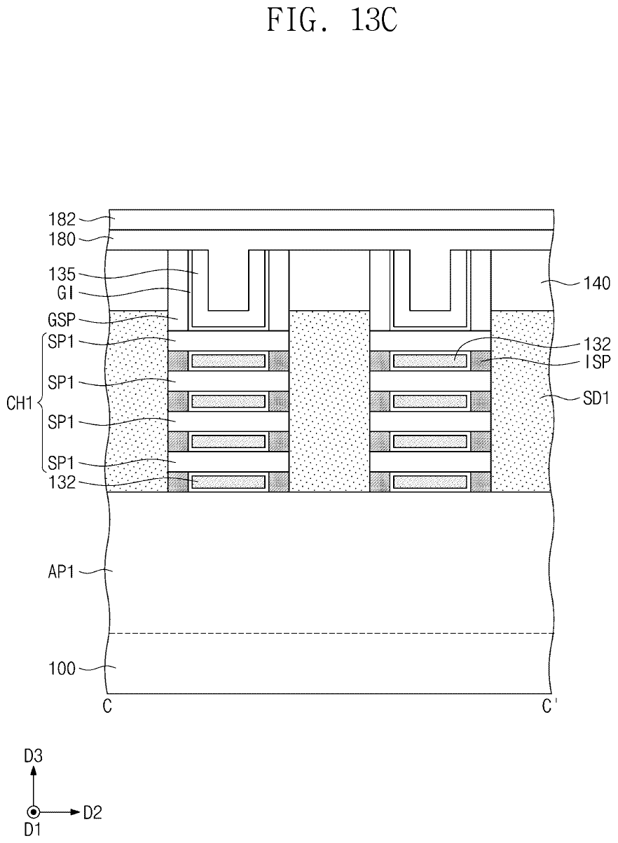

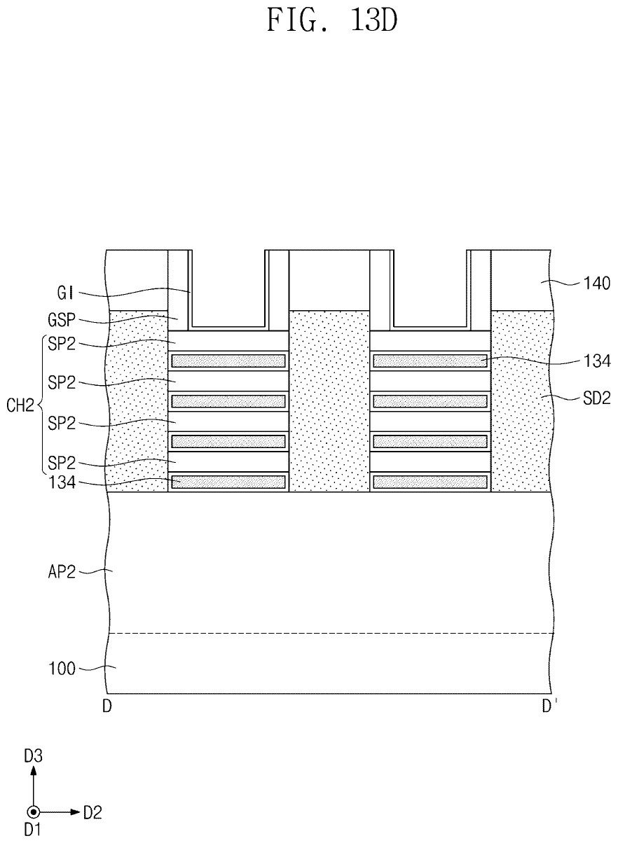

Referring to FIGS. 1 and 13A to 13D, the first protective layer 135 on the second channel pattern CH2 and the fourth sacrificial patterns 134 may be removed. Accordingly, the gate insulating layer GI on the second channel pattern CH2 may be exposed, and side surfaces of the fourth sacrificial patterns 134 may be exposed.

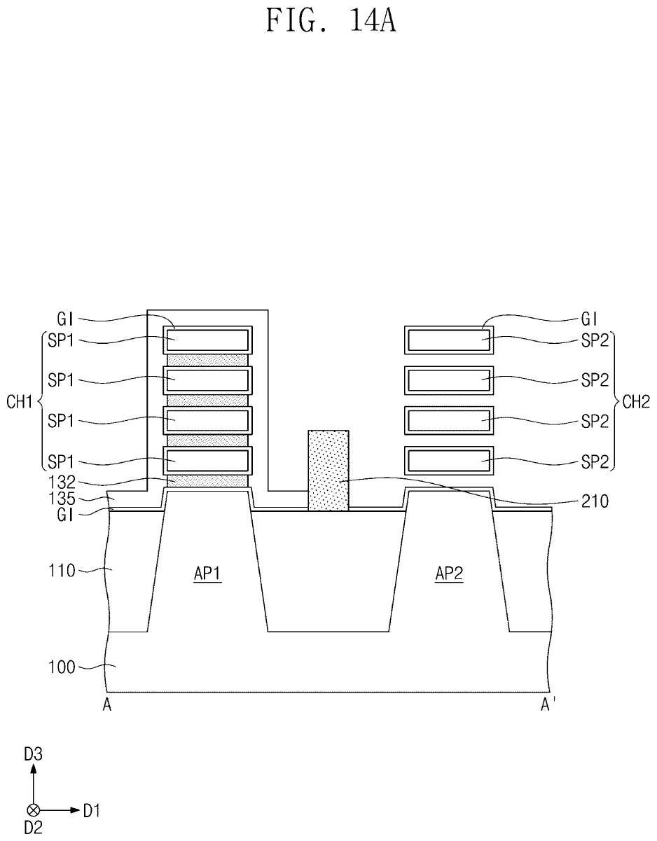

Referring to FIGS. 1 and 14A to 14D, the second lower mask layer 180 and the second upper mask layer 182 may be removed. Accordingly, the first protective layer 135 on the first channel pattern CH1 and the third sacrificial patterns 132 may be exposed. Removing the second lower mask layer 180 and the second upper mask layer 182 may be performed using an ashing and/or strip process, for example. Thereafter, the fourth sacrificial patterns 134 may be removed. Accordingly, the gate insulating layer GI between the second semiconductor patterns SP2 of the second channel pattern CH2 and between the second active pattern AP2 and the lowermost second semiconductor pattern SP2 of the second semiconductor patterns SP2 may be exposed.

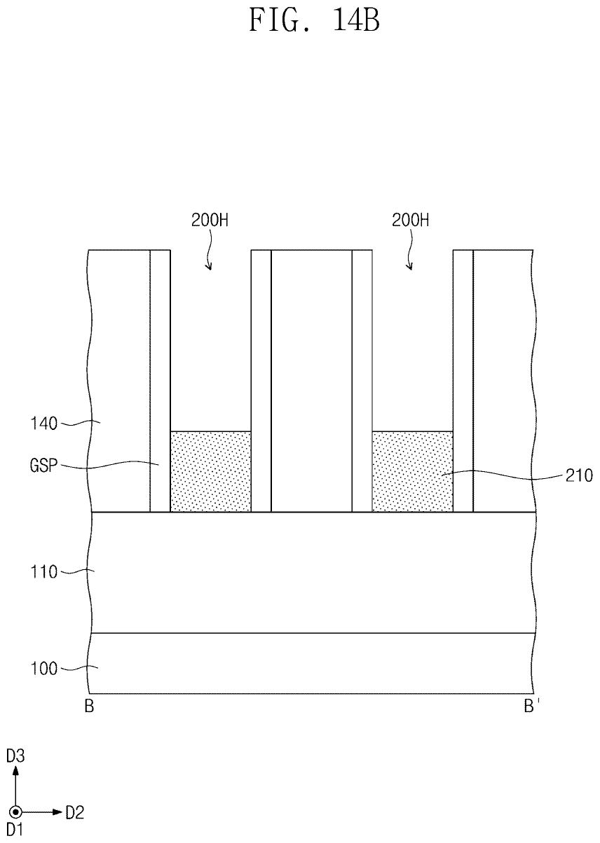

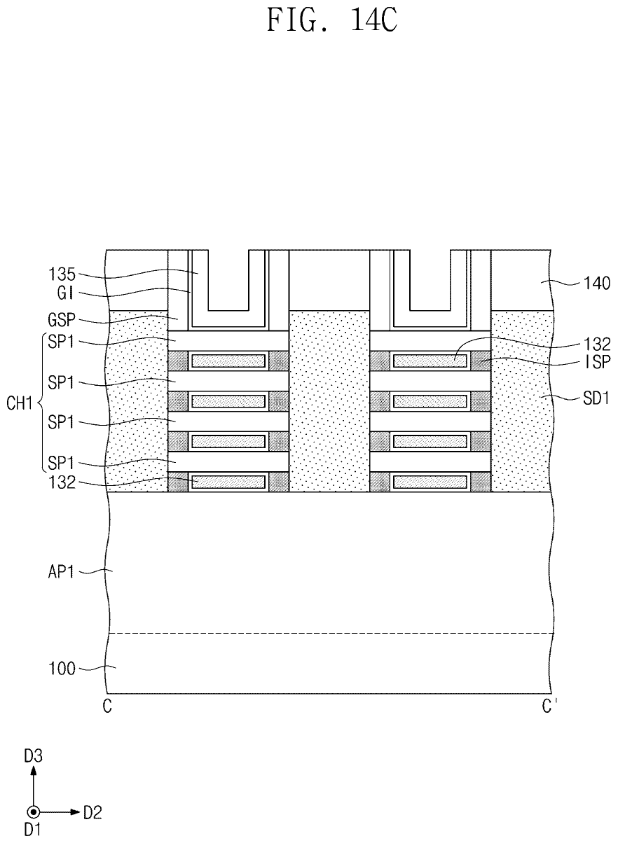

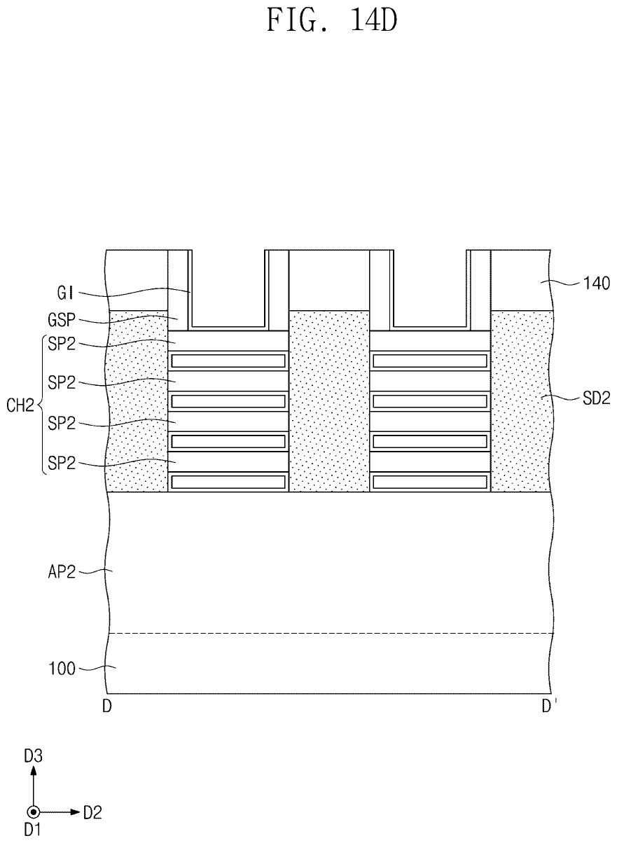

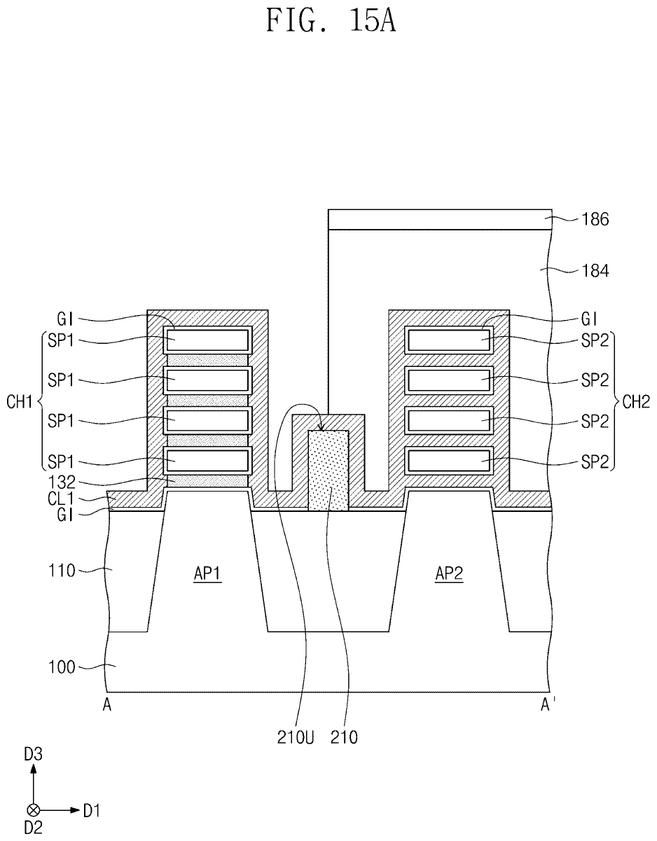

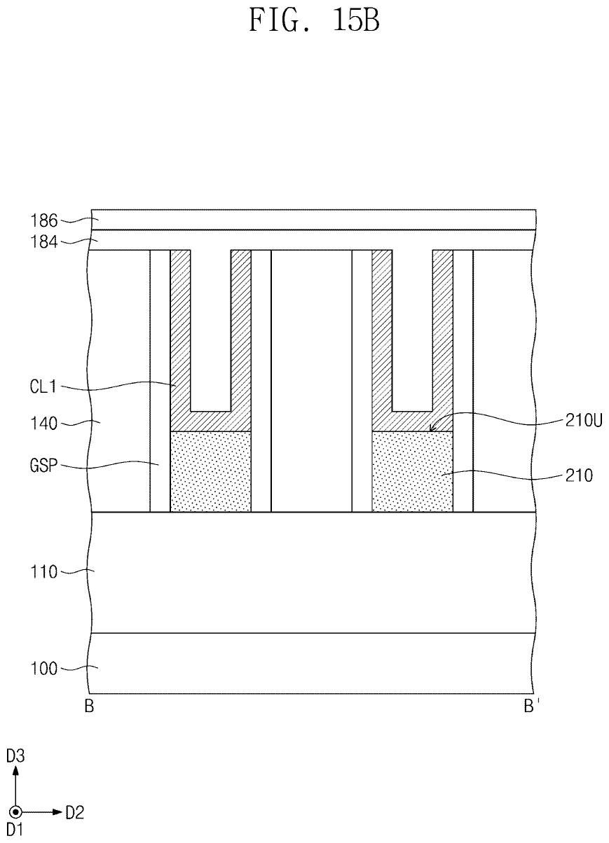

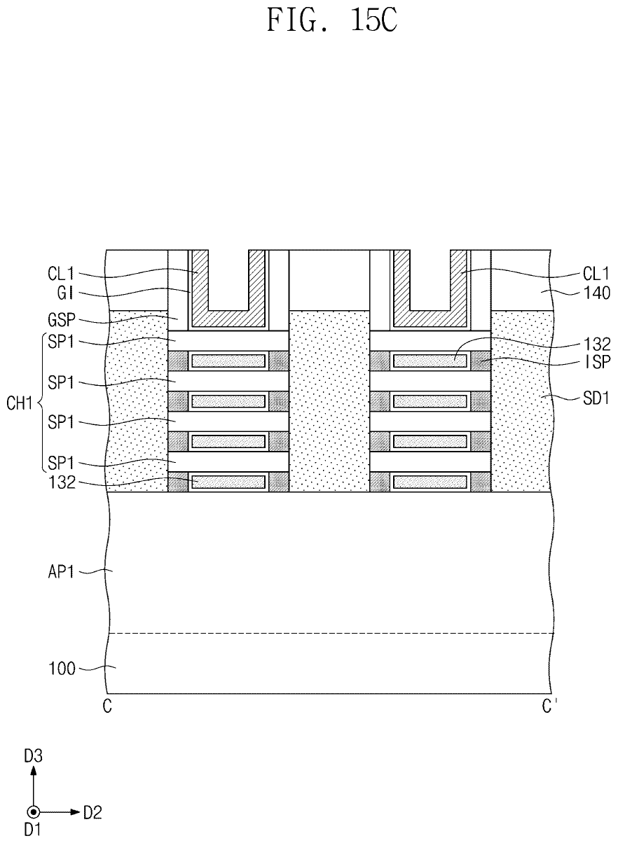

Referring to FIGS. 1 and 15A to 15D, the first protective layer 135 on the first channel pattern CH1 and the third sacrificial patterns 132 may be removed. Accordingly, the gate insulating layer GI on the first channel pattern CH1 may be exposed, and side surfaces of the third sacrificial patterns 132 may be exposed.

A first conductive layer CL1 may be formed to cover the first channel pattern CH1, the third sacrificial patterns 132, the lower pattern 210, and the second channel pattern CH2. The first conductive layer CL1 may fill a space between the second semiconductor patterns SP2 of the second channel pattern CH2, and fill a space between the lowermost second semiconductor pattern SP2 of the second semiconductor patterns PS2 and the second active pattern AP2. The first conductive layer CL1 may cover the top surface 210U of the lower pattern 210 and may extend on side surfaces of the gate spacers GSP. The first conductive layer CL1 may include a conductive metal nitride, and for example, may include TiAlN.

A third lower mask layer 184 may be formed on the first interlayer insulating layer 140, and may extend between the gate spacers GSP to cover the first conductive layer CL1 on the second channel pattern CH2. The third lower mask layer 184 may cover a portion of the first conductive layer CL1 on the lower pattern 210. A third upper mask layer 186 may be formed on the third lower mask layer 184. The third lower mask layer 184 and the third upper mask layer 186 may expose the first conductive layer CL1 on the first channel pattern CH1 and the third sacrificial patterns 132, and may expose a portion of the first conductive layer CL1 on the lower pattern 210. The third lower mask layer 184 may include an anti-reflective material (e.g., a bottom anti-reflective coating (BARC) material), and the third upper mask layer 186 may include a metal oxide (e.g., TiO₂).

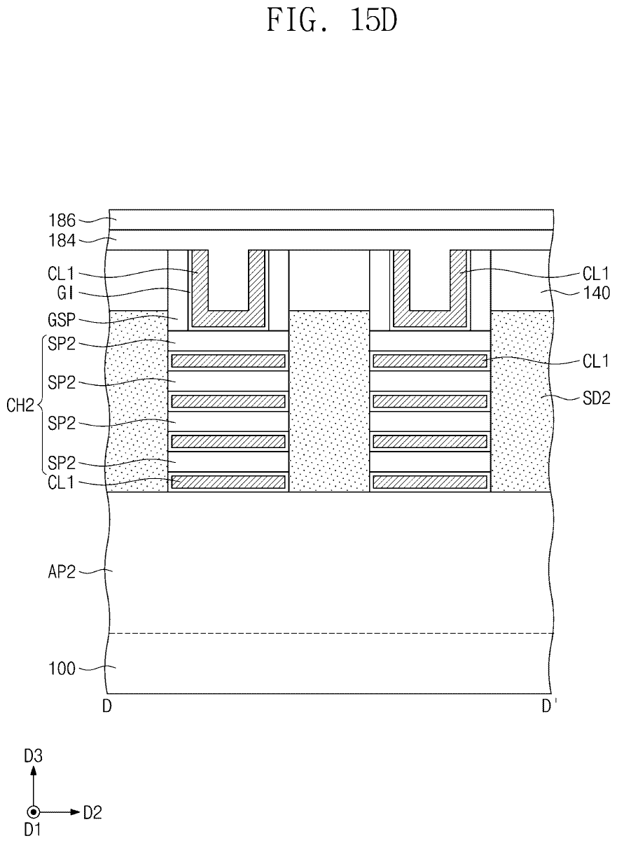

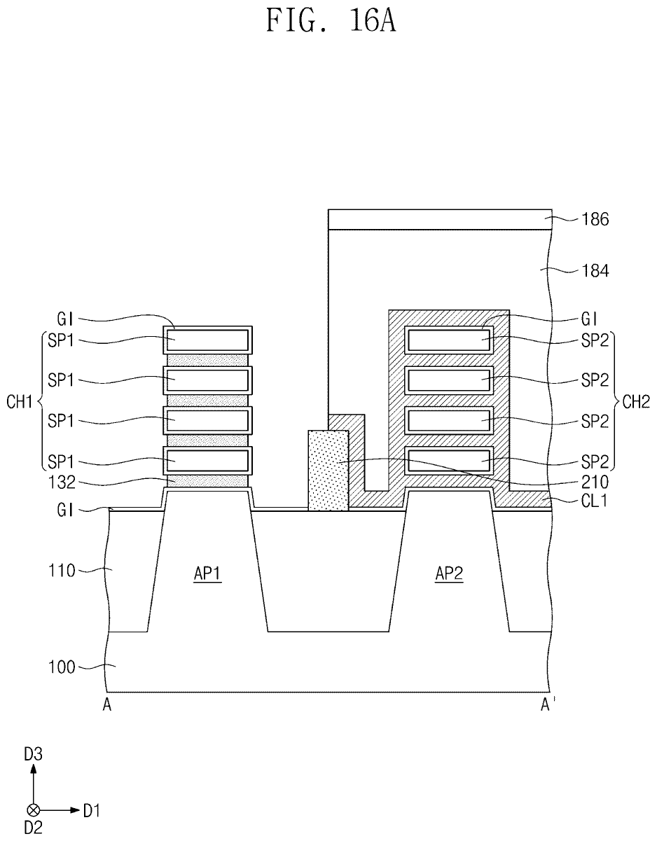

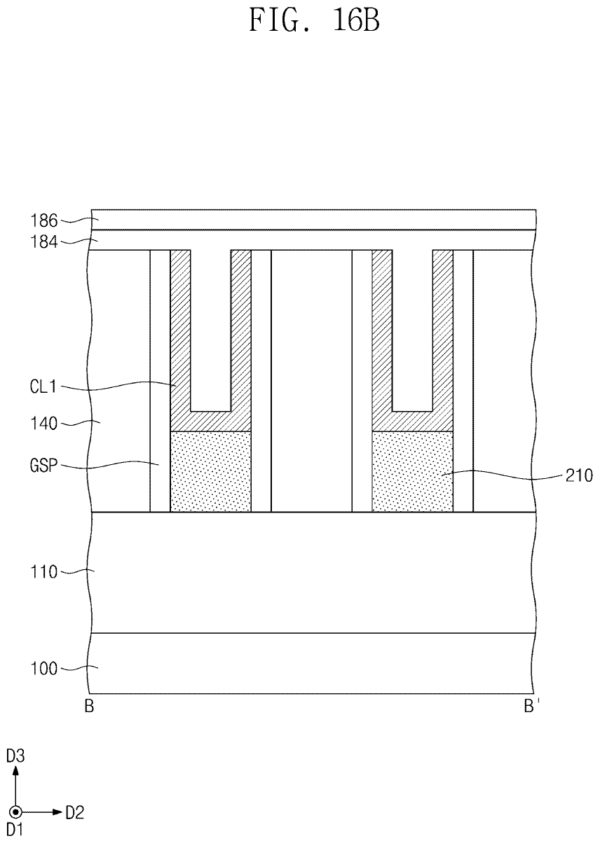

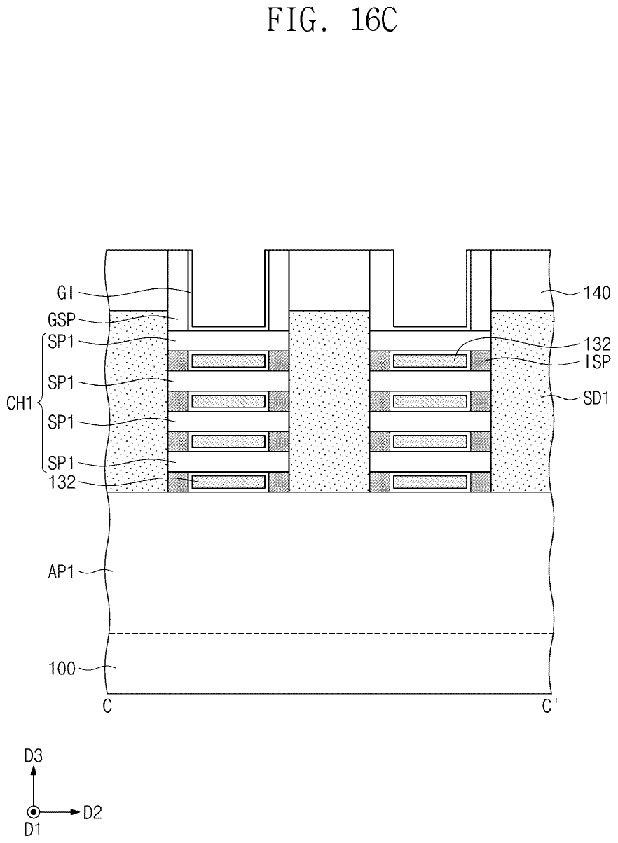

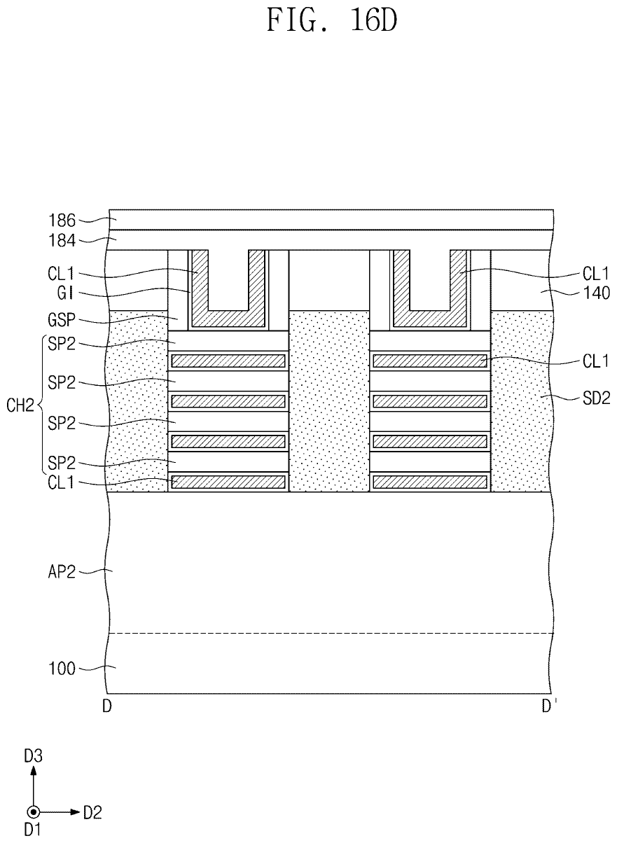

Referring to FIGS. 1 and 16A to 16D, the first conductive layer CL1 on the first channel pattern CH1 and the third sacrificial patterns 132 may be removed, and the portion of the first conductive layer CL1 on the lower pattern 210 may be removed. Accordingly, the gate insulating layer GI on the first channel pattern CH1 may be exposed, and side surfaces of the third sacrificial patterns 132 may be exposed.

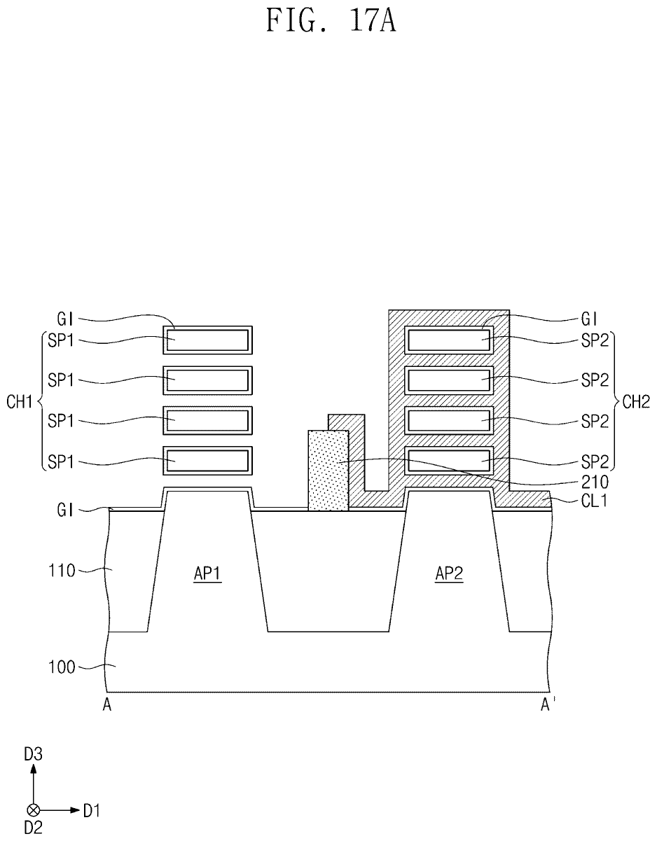

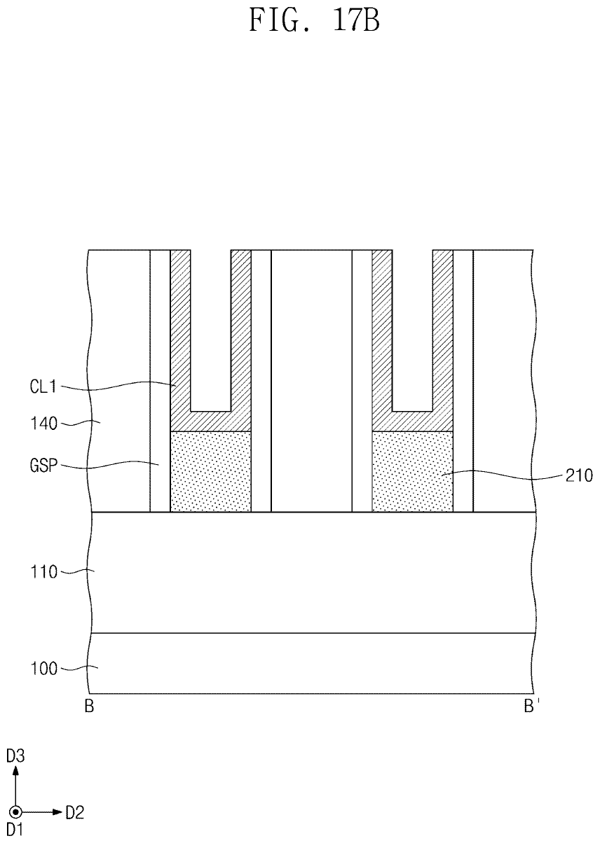

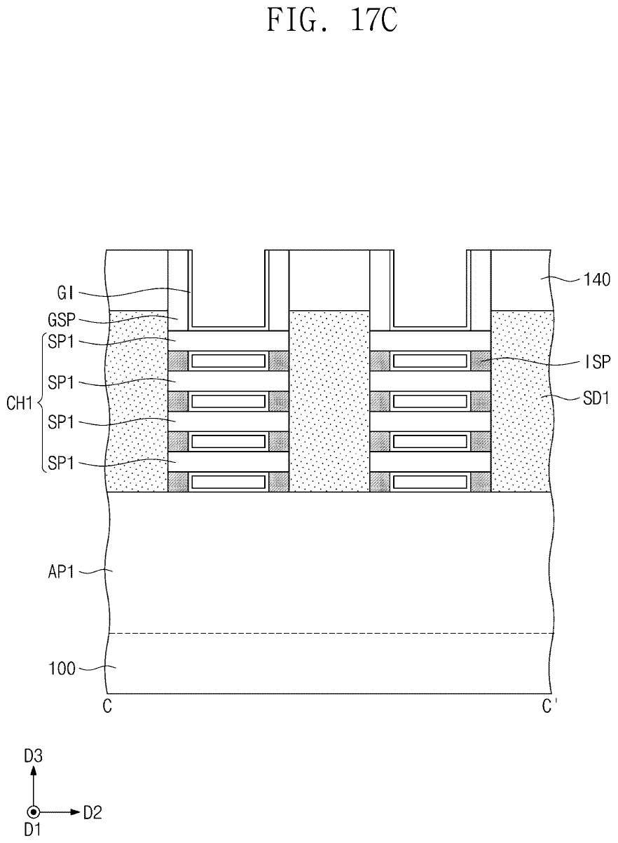

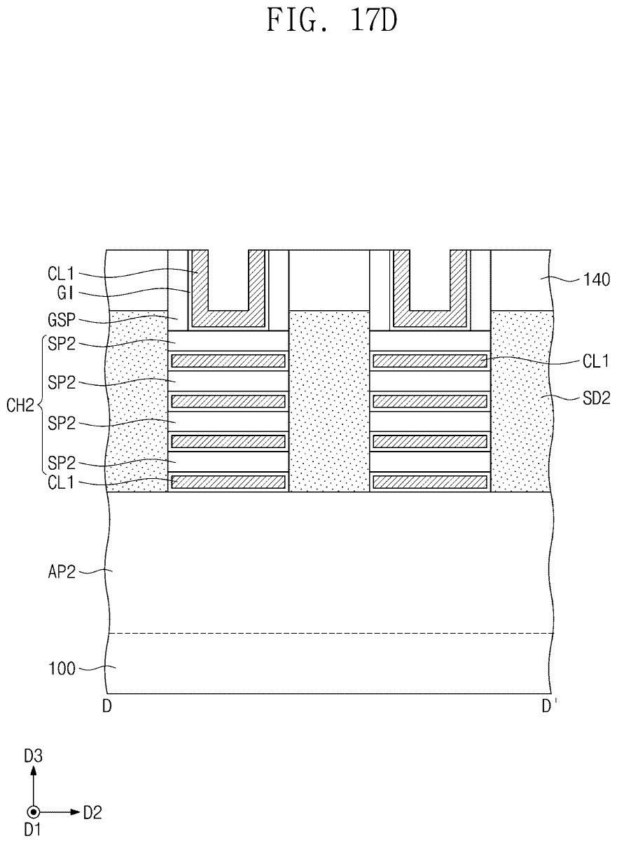

Referring to FIGS. 1 and 17A to 17D, the third lower mask layer 184 and the third upper mask layer 186 may be removed. Accordingly, the first conductive layer CL1, on the second active pattern AP2, the second channel pattern CH2, and the lower pattern 210, may be exposed. Removing the third lower mask layer 184 and the third upper mask layer 186 may be performed using an ashing and/or strip process, for example. Thereafter, the third sacrificial patterns 132 may be removed. Accordingly, the gate insulating layer GI between the first semiconductor patterns SP1 of the first channel pattern CH1 and between the first active pattern AP1 and the lowermost first semiconductor pattern SP1 of the first semiconductor patterns SP1 may be exposed.

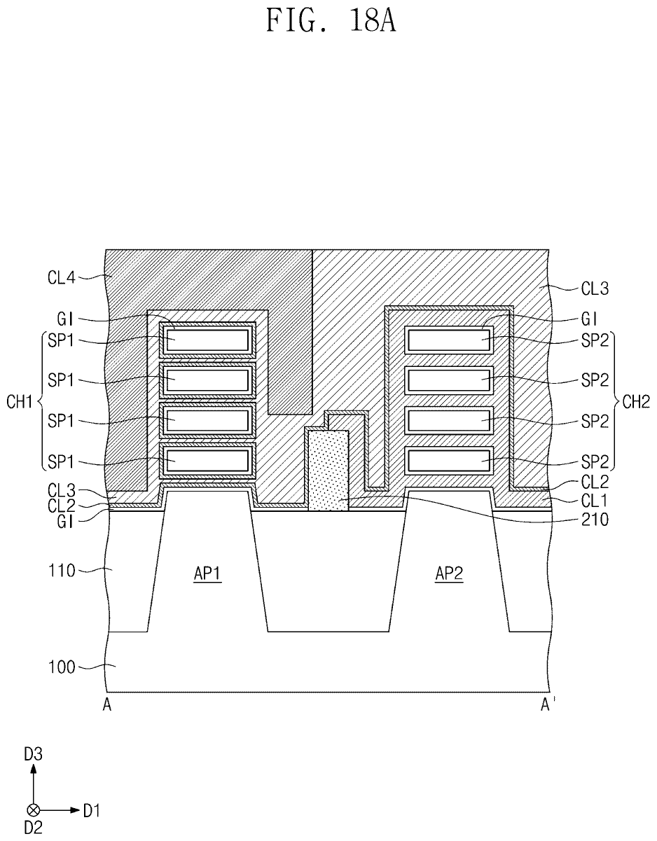

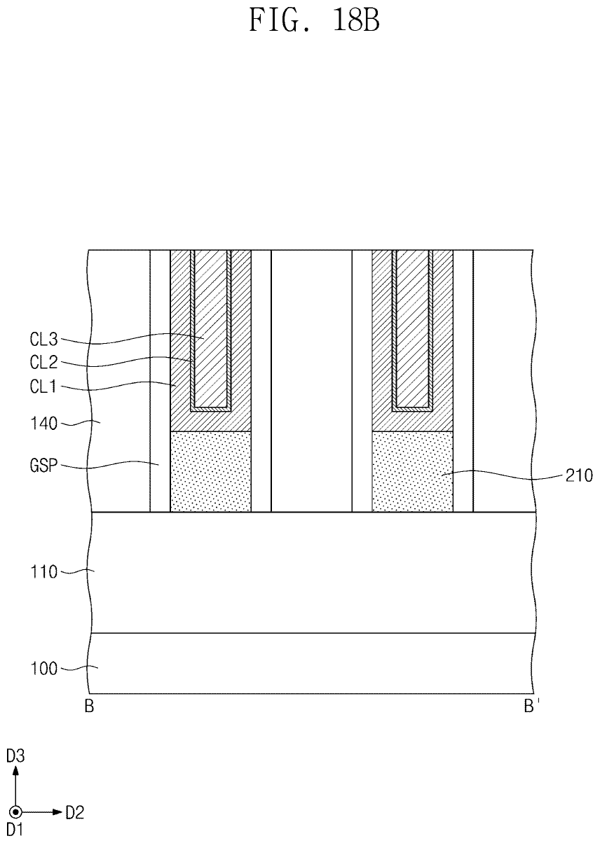

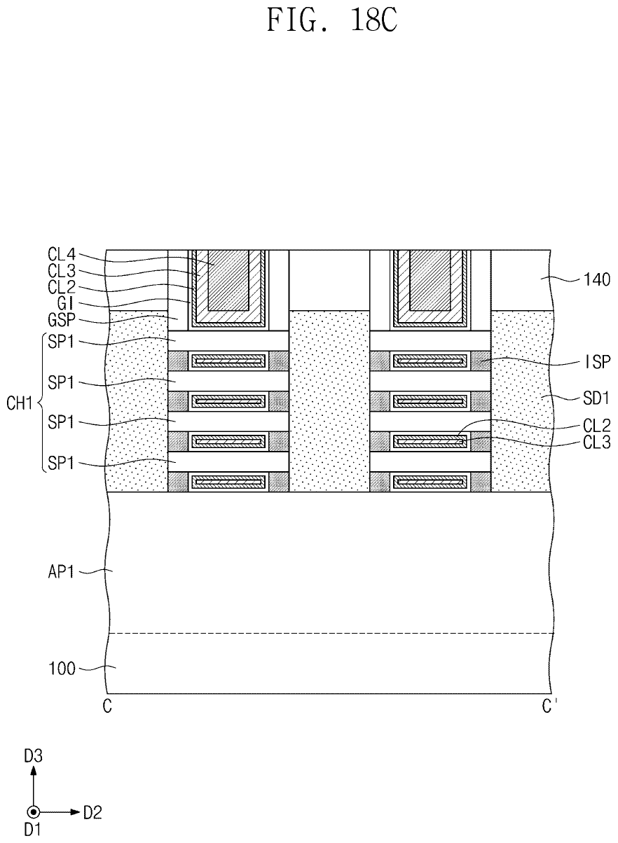

Referring to FIGS. 1 and 18A to 18D, a second conductive layer CL2 may be formed to cover the first channel pattern CH1, the lower pattern 210, and the second channel pattern CH2. The second conductive layer CL2 may surround an outer surface of each of the first semiconductor patterns SP1 of the first channel pattern CH1, and may cover a top surface of the first active pattern AP1 and a top surface of the device isolation layer 110. The second conductive layer CL2 may cover the lower pattern 210, and may cover the first conductive layer CL1 on the lower pattern 210 and on the second channel pattern CH2. The second conductive layer CL2 may include a conductive metal nitride and may include a material different from that of the first conductive layer CL1. The second conductive layer CL2 may include TiN, for example.

A third conductive layer CL3 may be formed to cover the first channel pattern CH1, the lower pattern 210, and the second channel pattern CH2. The third conductive layer CL3 may cover the second conductive layer CL2 on the first channel pattern CH1. The third conductive layer CL3 may fill a space between the first semiconductor patterns SP1 and fill a space between the lowermost first semiconductor pattern SP1 of the first semiconductor patterns SP1 and the first active pattern AP1. The third conductive layer CL3 may cover the second conductive layer CL2 on the lower pattern 210, and may cover the first conductive layer CL1 and the second conductive layer CL2, on the second channel pattern CH2. The third conductive layer CL3 may include metal carbide (e.g., TiAlC).

A fourth conductive layer CL4 may be formed to cover the first channel pattern CH1. The fourth conductive layer CL4 may cover the second conductive layer CL2 and the third conductive layer CL3, on the first channel pattern CH1. The fourth conductive layer CL4 may include a conductive metal nitride (e.g., TiN).

The first to fourth conductive layers CL1, CL2, CL3, and CL4 may be locally formed in the first interlayer insulating layer 140 and between the gate spacers GSP.

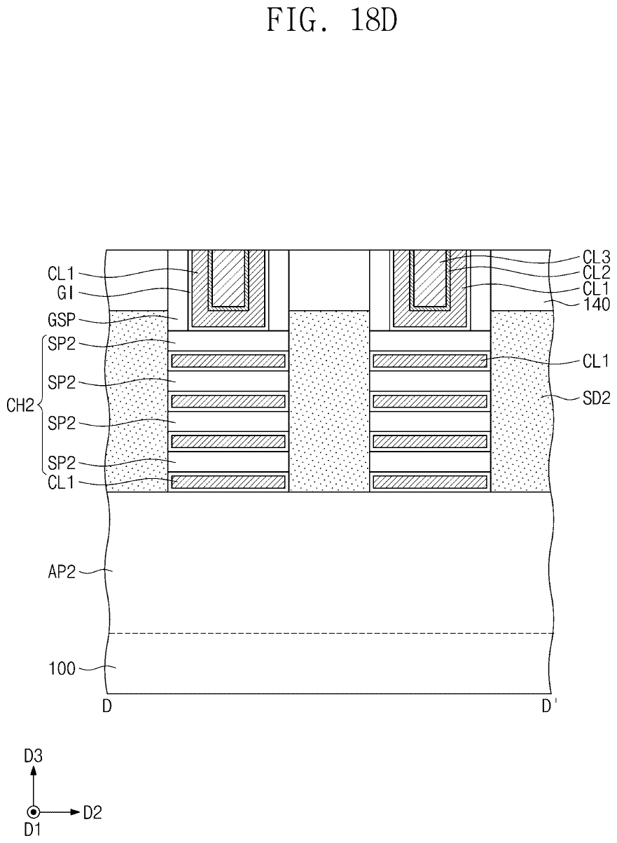

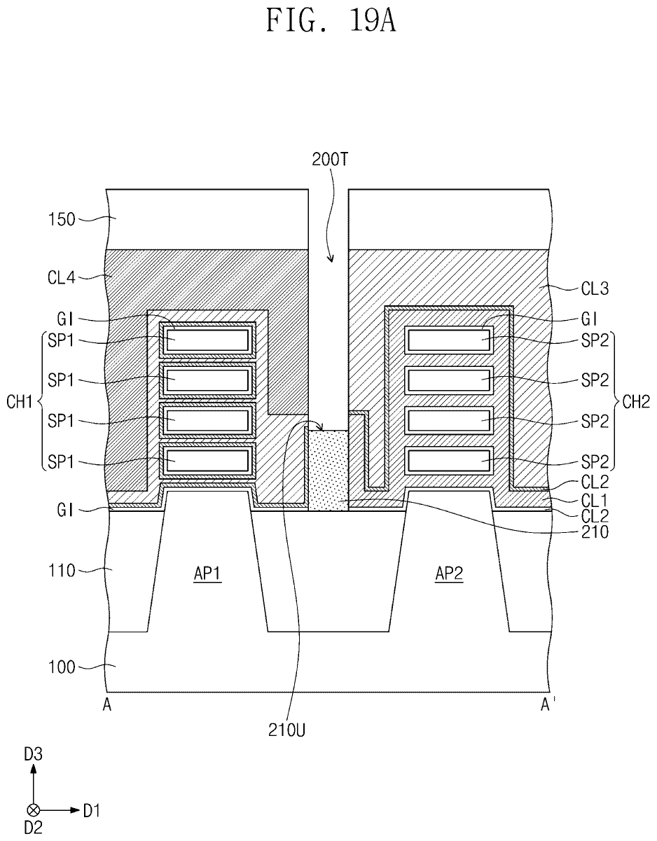

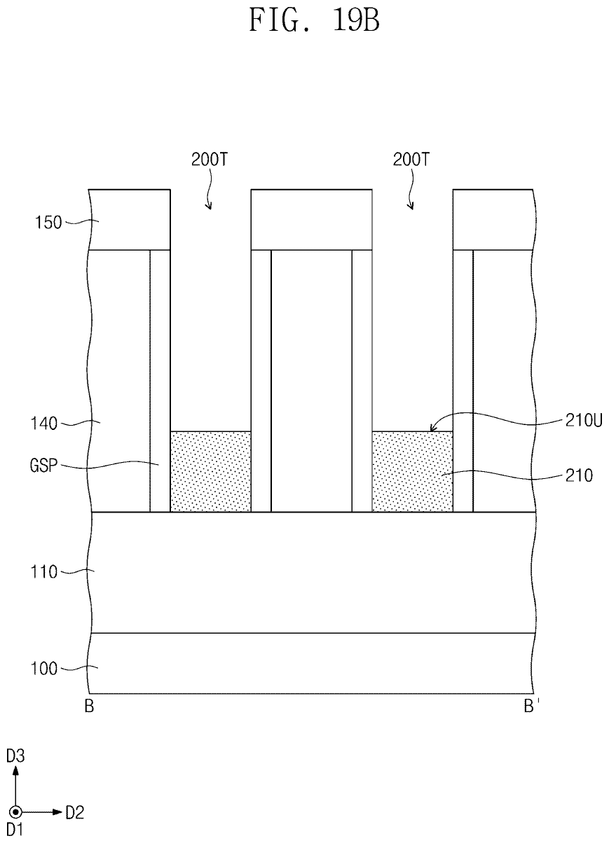

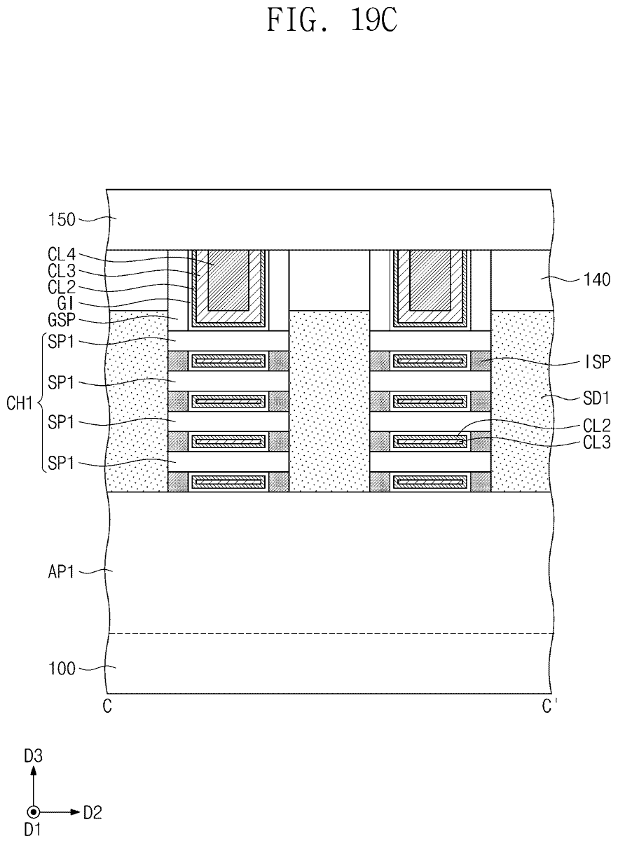

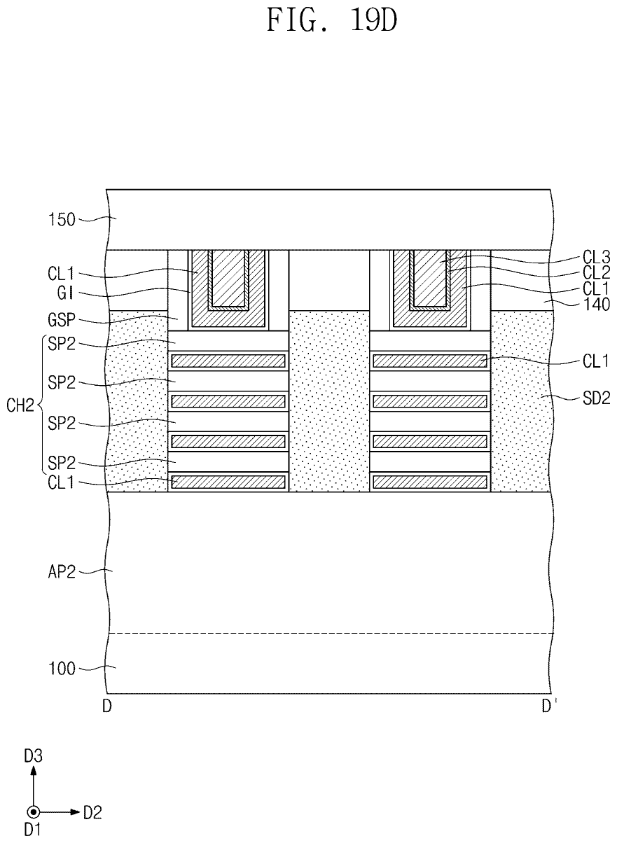

Referring to FIGS. 1 and 19A to 19D, an upper layer 150 may be formed on the first interlayer insulating layer 140, and may cover uppermost surfaces of the gate spacers GSP and the first to fourth conductive layers CL1, CL2, CL3, and CL4.

A second separation hole 200T may be formed to penetrate through the upper layer 150 and the first to fourth conductive layers CL1, CL2, CL3, and CL4. The second separation hole 200T may extend in the third direction D3 between the gate spacers GSP and may expose the top surface 210U of the lower pattern 210. Forming the second separation hole 200T may include patterning the upper layer 150 and the first to fourth conductive layers CL1, CL2, CL3 and CL4 using a dry etching process.

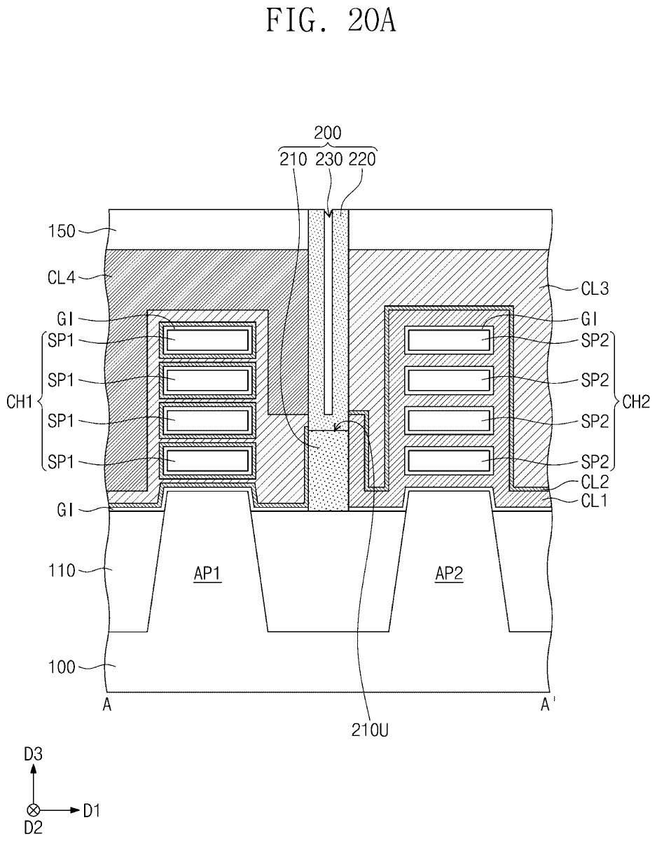

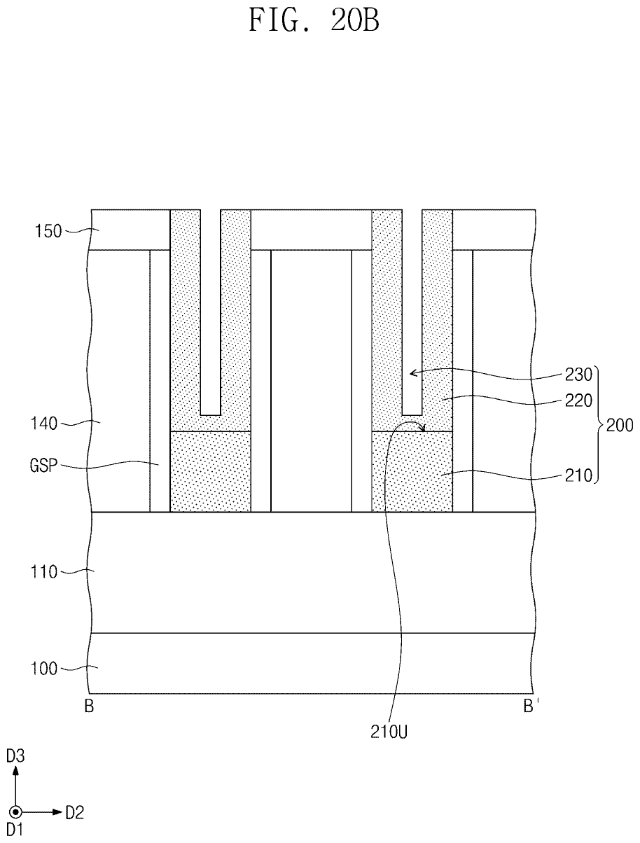

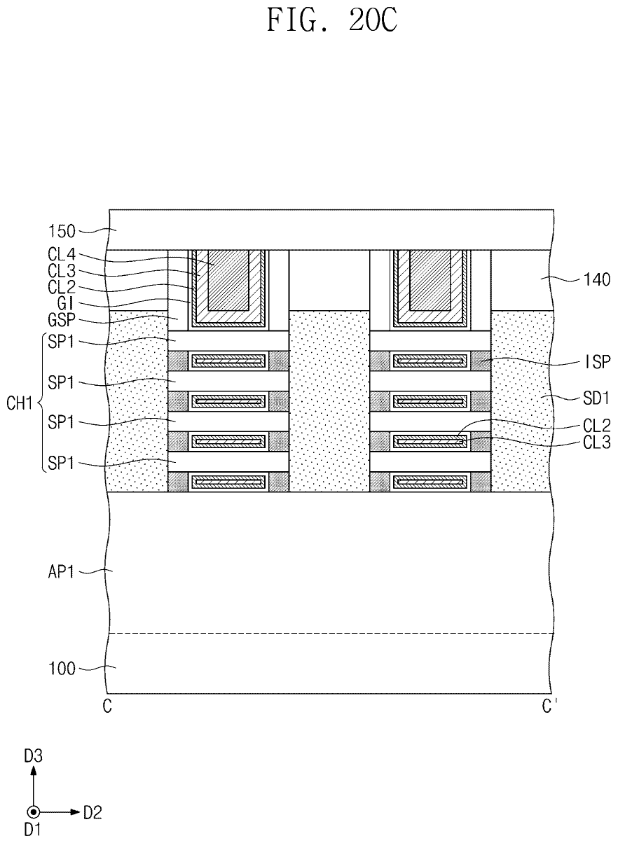

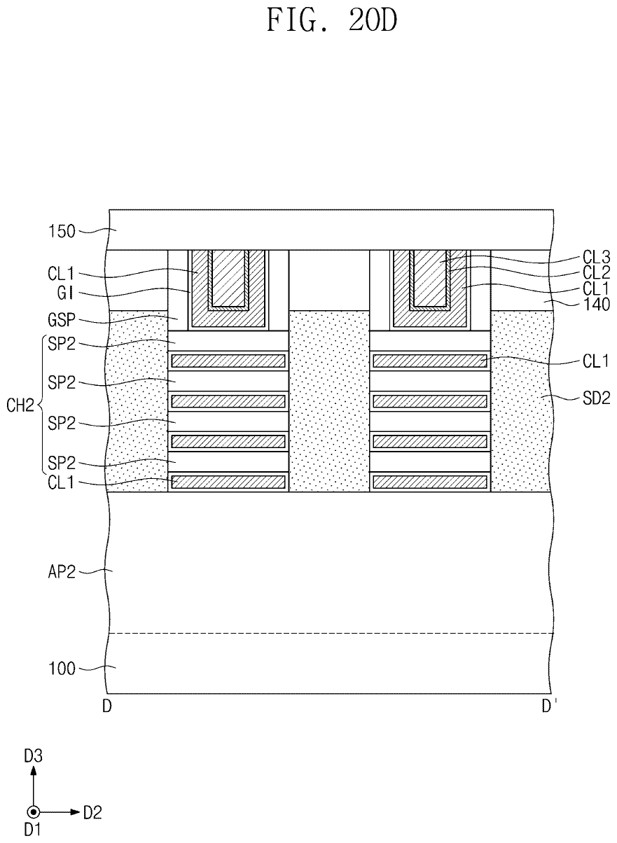

Referring to FIGS. 1 and 20A to 20D, an upper pattern 220 may be formed in the second separation hole 200T. According to some implementations, forming the upper pattern 220 may include forming an upper insulating layer conformally covering an inner surface of the second separation hole 200T on the upper layer 150 by using atomic layer deposition, physical vapor deposition, and/or chemical vapor deposition, and planarizing the upper insulating layer until a top surface of the upper layer 150 is exposed. The upper pattern 220 may be in contact with the top surface 210U of the lower pattern 210. According to some implementations, the upper pattern 220 may extend in the third direction D3 and may include an empty region 230 therein. The empty region 230 may be referred to as a void or a seam, for example. The lower pattern 210 and the upper pattern 220 may be referred to as a separation insulating pattern 200.

Referring again to FIGS. 1 and 2A to 2D, the lower pattern 210 may penetrate through the gate insulating layer GI and be in contact with the top surface 110U of the device isolation layer 110. The gate insulating layer GI may be separated into a first gate insulating pattern GI1 on the first active pattern AP1 and the first channel pattern CH1, and a second gate insulating pattern GI2 on the second active pattern AP2 and the second channel pattern CH2, by the lower pattern 210. The second conductive layer CL2, the third conductive layer CL3 and the fourth conductive layer CL4, which are on the first active pattern AP1 and the first channel pattern CH1, may be referred to as a first conductive pattern CP1, a second conductive pattern CP2 and a third conductive pattern CP3, respectively. The first to third conductive patterns CP1, CP2, CP3 may be referred to as a first gate electrode GE1. The first conductive layer CL1, the second conductive layer CL2 and the third conductive layer CL3, which are on the second active pattern AP2 and the second channel pattern CH2, may be respectively referred to as a fourth conductive pattern CP4, a fifth conductive pattern CP5 and a sixth conductive pattern CP6. The fourth to sixth conductive patterns CP4, CP5 and CP6 may be referred to as a second gate electrode GE2. The first gate electrode GE1 and the second gate electrode GE2 may be spaced apart from each other in the first direction D1 with the separation insulating pattern 200 interposed therebetween, and may be aligned with each other in the first direction D1.

A second interlayer insulating layer 160 may be formed on the upper layer 150 and may cover an uppermost surface of the separation insulating pattern 200. Active contacts AC may be formed on both sides of each of the first gate electrode GE1 and the second gate electrode GE2. Each of the active contacts AC may penetrate through the second interlayer insulating layer 160, the upper layer 150 and the first interlayer insulating layer 140 and be connected to a corresponding one of the first and second source/drain patterns SD1 and SD2.

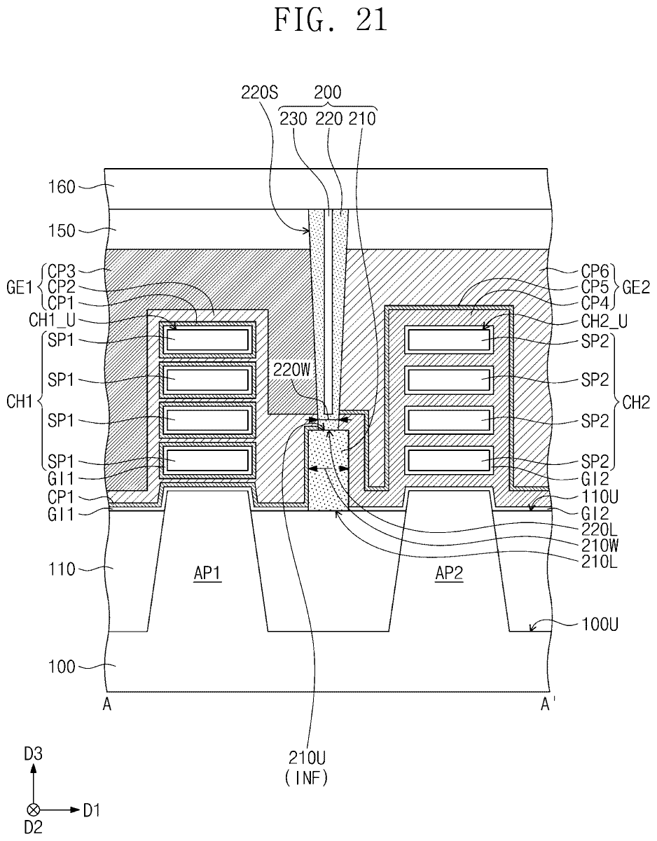

FIG. 21 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 21, the upper pattern 220 of the separation insulating pattern 200 may be disposed on the lower pattern 210, and a bottom surface 220L of the upper pattern 220 may be in contact with the top surface 210U of the lower pattern 210. According to some implementations, the upper pattern 220 may extend in the third direction D3 and may include an empty region 230 therein. The empty region 230 may be referred to as a void or a seam, for example. A side surface 220S of the upper pattern 220 may be inclined with respect to the bottom surface 220L of the upper pattern220.

Each of the lower pattern 210 and the upper pattern 220 may have a width along the first direction D1. According to some implementations, a width 210W of the top surface 210U of the lower pattern 210 may be greater than a width 220W of the bottom surface 220L of the upper pattern 220. The width 220W of the upper pattern 220 in the first direction D1 may increase from its bottom to its top.

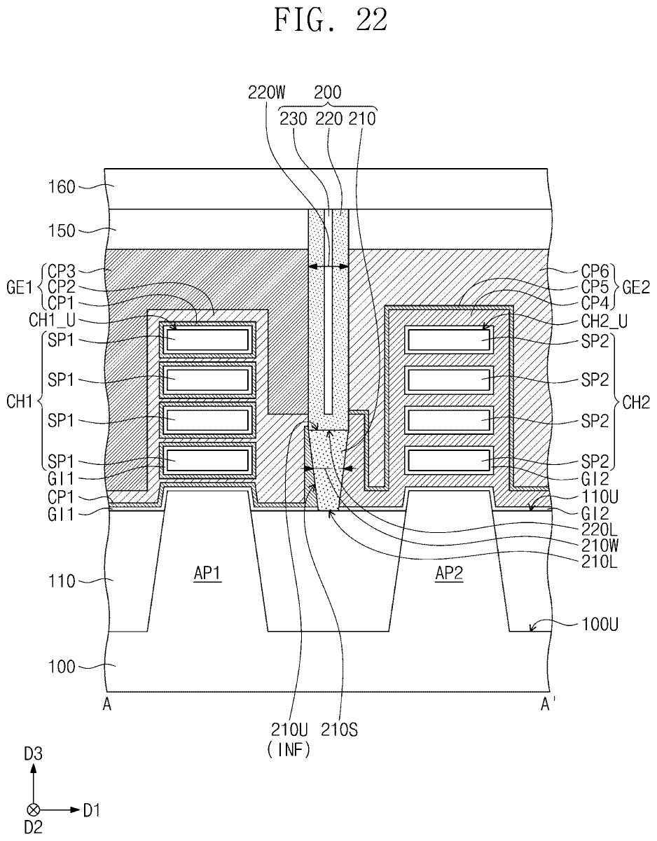

FIG. 22 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 22, the lower pattern 210 of the separation insulating pattern 200 may have a pillar shape extending in the third direction D3. The bottom surface 210L of the lower pattern 210 may be in contact with the top surface 110U of the device isolation layer 110, and the top surface 210U of the lower pattern 210 may be in contact with the bottom surface 220L of the upper pattern 220. A side surface 210S of the lower pattern 210 may be inclined with respect to the bottom surface 210L of the lower pattern 210.

Each of the lower pattern 210 and the upper pattern 220 may have a width along the first direction D1. According to some implementations, a width 210W of the top surface 210U of the lower pattern 210 may be the same as a width 220W of the bottom surface 220L of the upper pattern 220. The width 210W of the lower pattern 210 along the first direction D1 may decrease from its top to its bottom.

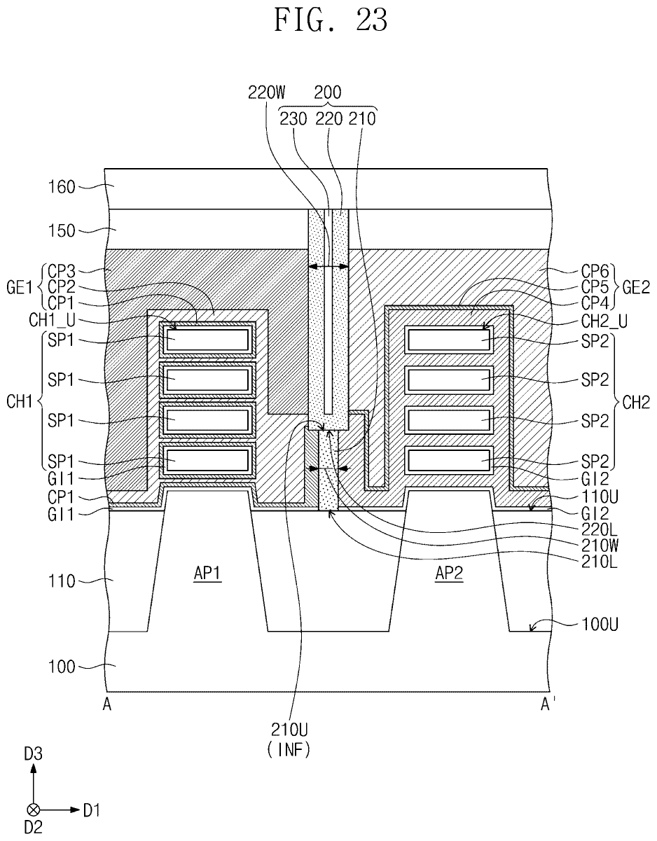

FIG. 23 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 23, the lower pattern 210 of the separation insulating pattern 200 may have a pillar shape extending in the third direction D3. The bottom surface 210L of the lower pattern 210 may be in contact with the top surface 110U of the device isolation layer 110, and the top surface 210U of the lower pattern 210 may be in contact with the bottom surface 220L of the upper pattern 220. Each of the lower pattern 210 and the upper pattern 220 may have a width along the first direction D1. According to some implementations, a width 210W of the top surface 210U of the lower pattern 210 and a width 210W of the bottom surface 210L of the lower pattern 210 may be less than a width 220W of the bottom surface 220L of the upper pattern 220.

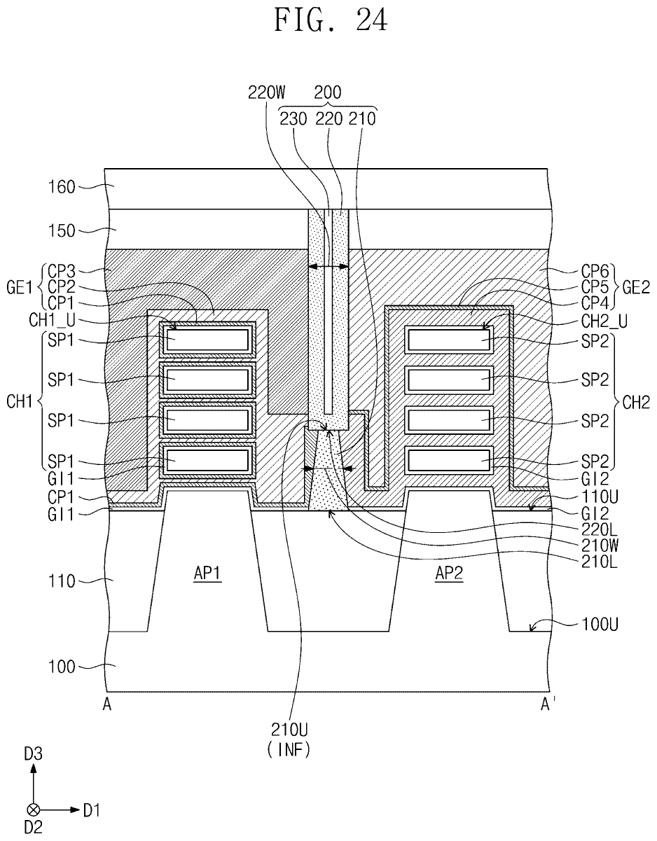

FIG. 24 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 24, the lower pattern 210 of the separation insulating pattern 200 may have a pillar shape extending in the third direction D3. The bottom surface 210L of the lower pattern 210 may be in contact with the top surface 110U of the device isolation layer 110, and the top surface 210U of the lower pattern 210 may be in contact with the bottom surface 220L of the upper pattern 220. Each of the lower pattern 210 and the upper pattern 220 may have a width along the first direction D1. According to some implementations, a width 210W of the top surface 210U of the lower pattern 210 may be less than a width 220W of the bottom surface 220L of the upper pattern 220. The width 210W of the lower pattern 210 along the first direction D1 may increase from its top to its bottom.

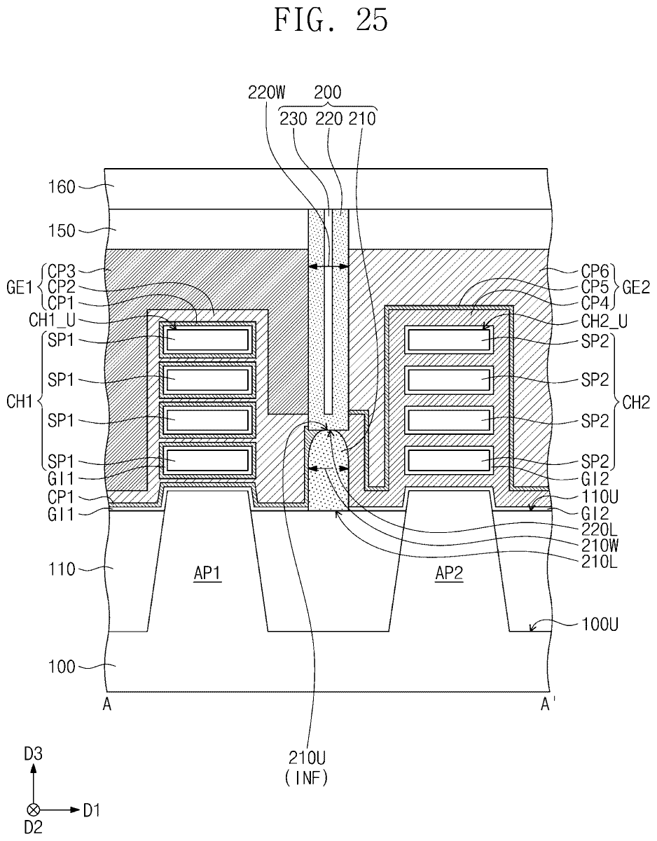

FIG. 25 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 25, the lower pattern 210 of the separation insulating pattern 200 may have a pillar shape extending in the third direction D3. The bottom surface 210L of the lower pattern 210 may be in contact with the top surface 110U of the device isolation layer 110, and the top surface 210U of the lower pattern 210 may be in contact with the bottom surface 220L of the upper pattern 220. According to some implementations, the top surface 210U of the lower pattern 210 may have a curved shape protruding toward the upper pattern 220. Accordingly, the top surface 210U of the lower pattern 210 may contact a portion of the bottom surface 220L of the upper pattern 220.

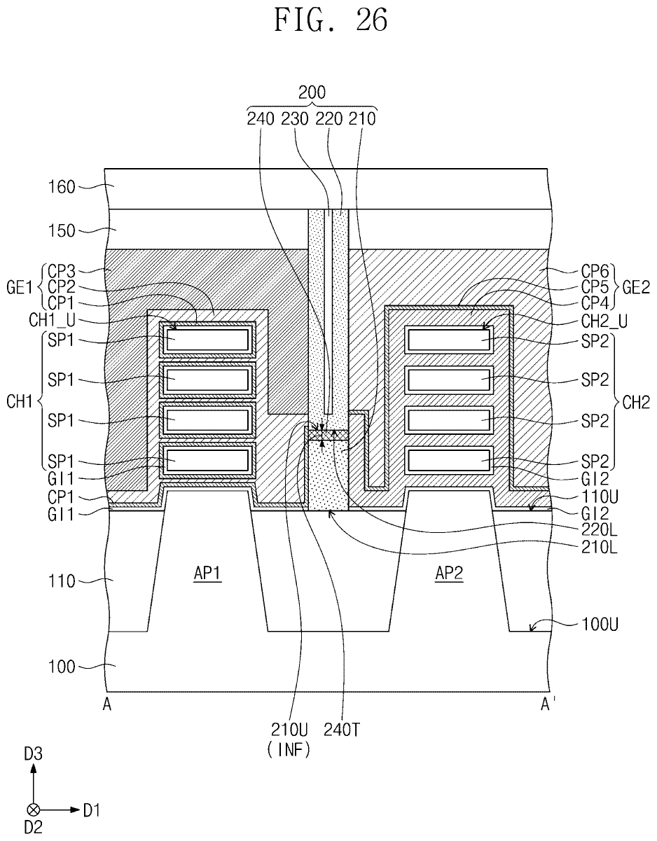

FIG. 26 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 26, the lower pattern 210 of the separation insulating pattern 200 may have a pillar shape extending in the third direction D3. The top surface 210U of the lower pattern 210 may be in contact with the bottom surface 220L of the upper pattern 220. According to some implementations, the lower pattern 210 may include a first portion and a second portion having an impurity layer 240 adjacent to the top surface 210U of the lower pattern 210. The first portion of the lower pattern 210 does not include the impurity layer 240. The impurity layer 240 may include the same material or the same element as the first portion of the lower pattern 210. The impurity layer 240 may further include an element different from the first portion of the lower pattern 210. A thickness 240T of the impurity layer 240 in the third direction D3 may be less than 5 nm, for example.

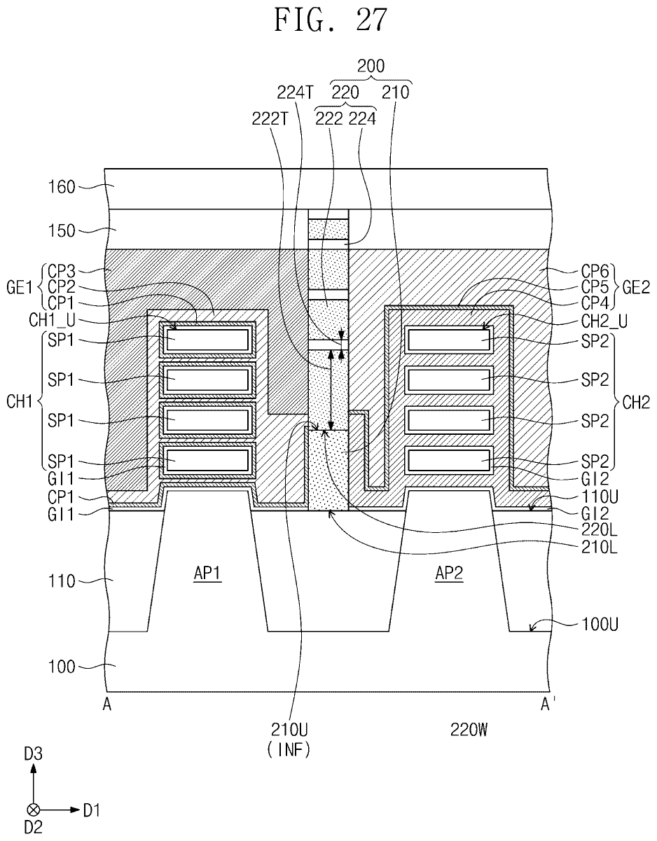

FIG. 27 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 27, according to some implementations, the upper pattern 220 of the separation insulating pattern 200 may include at least one first sublayer 222 and at least one second sublayer 224 alternately and repeatedly stacked along the third direction D3 on the top surface 210U of the lower pattern 210. The bottom surface 220L of the upper pattern 220 may be in contact with the top surface 210U of the lower pattern 210. The bottom surface 220L of the upper pattern 220 may correspond to a bottom surface of a lowermost first sublayer 222 of a plurality of first sublayers 222.

Each of the first sublayer 222 and the second sublayer 224 may have a thickness along the third direction D3. A thickness 222T of the first sublayer 222 may be greater than a thickness 224T of the second sublayer 224. The thickness 224T of the second sublayer 224 may be less than 5 nm, for example.

The first sublayer 222 may be formed by performing a filling process using a flowable insulating material, and the second sublayer 224 may be formed by performing a surface treatment process on a top surface of the first sublayers 222. The first sublayer 222 may include, for example, at least one of SiCN, SiN, and SiCON, and the second sublayer 224 may include, for example, at least one of SiN, SiON, SiCO, SiCON, SiO₂, and SiCOH.

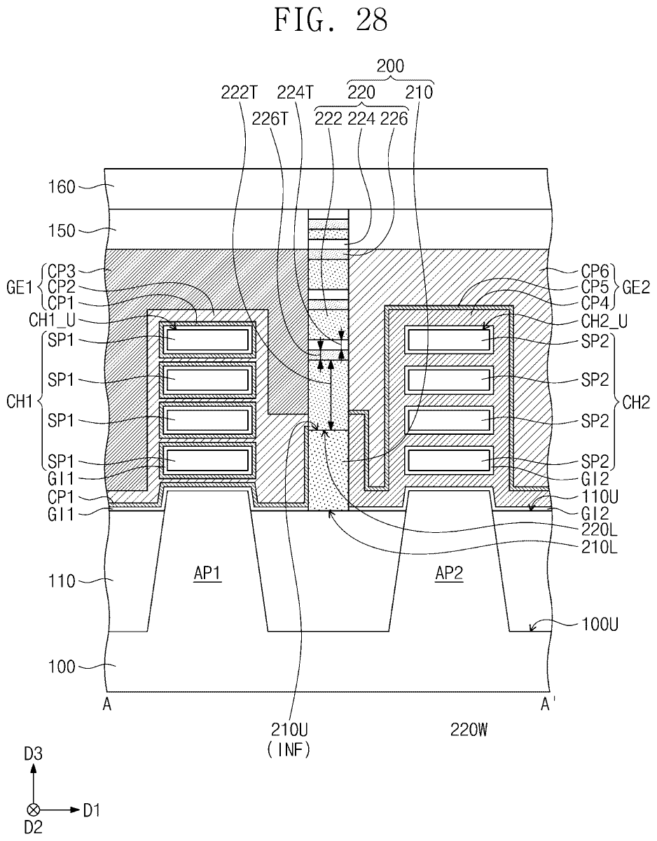

FIG. 28 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 28, according to some implementations, the upper pattern 220 of the separation insulating pattern 200 may include at least one first sublayer 222 and at least one second sublayer 224 alternately and repeatedly stacked along the third direction D3 on the top surface 210U of the lower pattern 210, and may further include an inter-mixing layer 226 between the first sublayer 222 and the second sublayer 224. The first sublayer 222 and the second sublayer 224 are respectively the same as the first sublayer 222 and the second sublayer 224 described with reference to FIGS. 1 and 27.

Each of the first sublayer 222, the second sublayer 224, and the inter-mixing layer 226 may have a thickness in the third direction D3. A thickness 222T of the first sublayer 222 may be greater than a thickness 224T of the second sublayer 224 and a thickness 226T of the inter-mixing layer 226. The thickness 224T of the second sublayer 224 may be less than 5 nm, for example, and the thickness 226T of the inter-mixing layer 226 may be less than 5 nm, for example. The inter-mixing layer 226 may include the same material or the same element as the first sublayer 222 and the second sublayer 224.

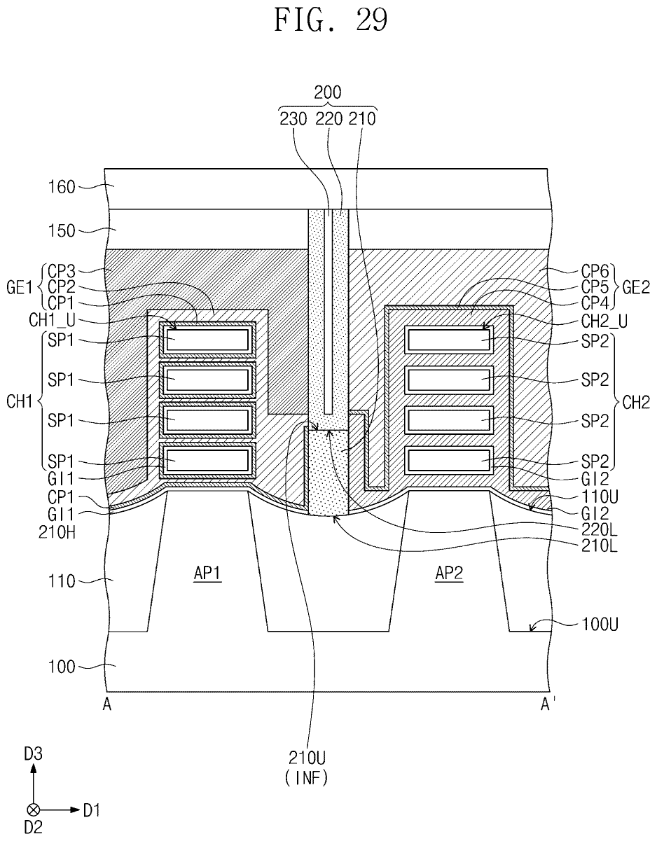

FIG. 29 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 29, according to some implementations, the top surface 110U of the device isolation layer 110 may be recessed toward the inside of the device isolation layer 110. The bottom surface 210L of the lower pattern 210 may be in contact with the recessed top surface 110U of the device isolation layer 110, and thus the bottom surface 210L of the lower pattern 210 may include a curved surface that is convex toward the inside of the device isolation layer 110.

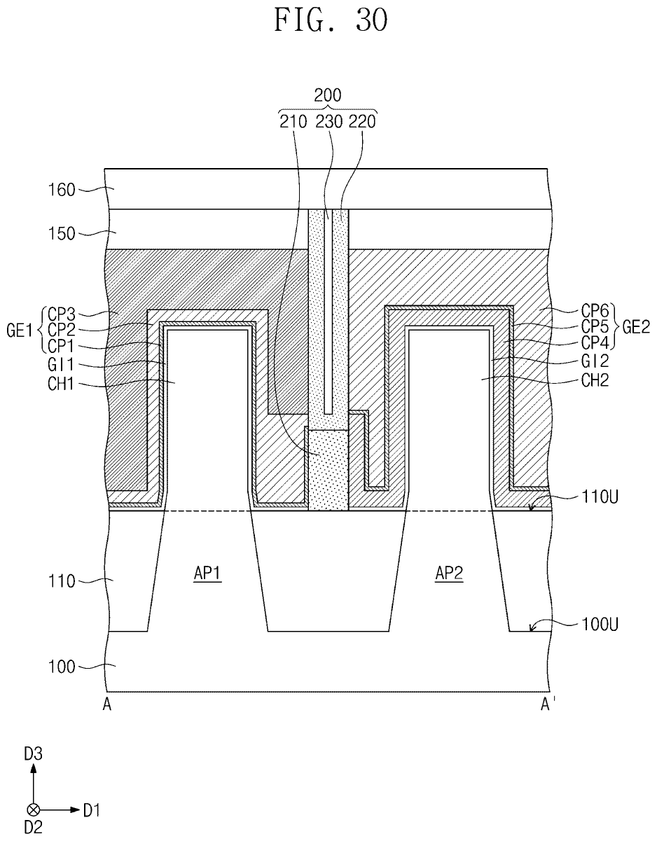

FIG. 30 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 30, according to some implementations, the first channel pattern CH1 may be an upper portion of the first active pattern AP1, which are protrudes from the first active pattern API. The device isolation layer 110 may be disposed on both sides of the first active pattern AP1, and may expose the first channel pattern CH1. The first gate electrode GE1 may cover a top surface and side surfaces of the first channel pattern CH1, and may extend on the device isolation layer 110 in the first direction D1. The first gate insulating pattern GI1 may be interposed between the first channel pattern CH1 and the first gate electrode GE1, and may extend between the device isolation layer 110 and the first gate electrode GE1. The first gate electrode GE1, the first channel pattern CH1, and the first source/drain patterns SD1 may constitute a Fin Field Effect Transistor (FINFET).

The second channel pattern CH2 may be an upper portion of the second active pattern AP2, which are protrudes from the second active pattern AP2. The device isolation layer 110 may be disposed on both sides of the second active pattern AP2, and may expose the second channel pattern CH2. The second gate electrode GE2 may cover a top surface and side surfaces of the second channel pattern CH2, and may extend on the device isolation layer 110 in the first direction D1. The second gate insulating pattern GI2 may be interposed between the second channel pattern CH2 and the second gate electrode GE2, and may extend between the device isolation layer 110 and the second gate electrode GE2. The second gate electrode GE2, the second channel pattern CH2, and the second source/drain patterns SD2 may constitute a Fin Field Effect Transisor (FINFET).

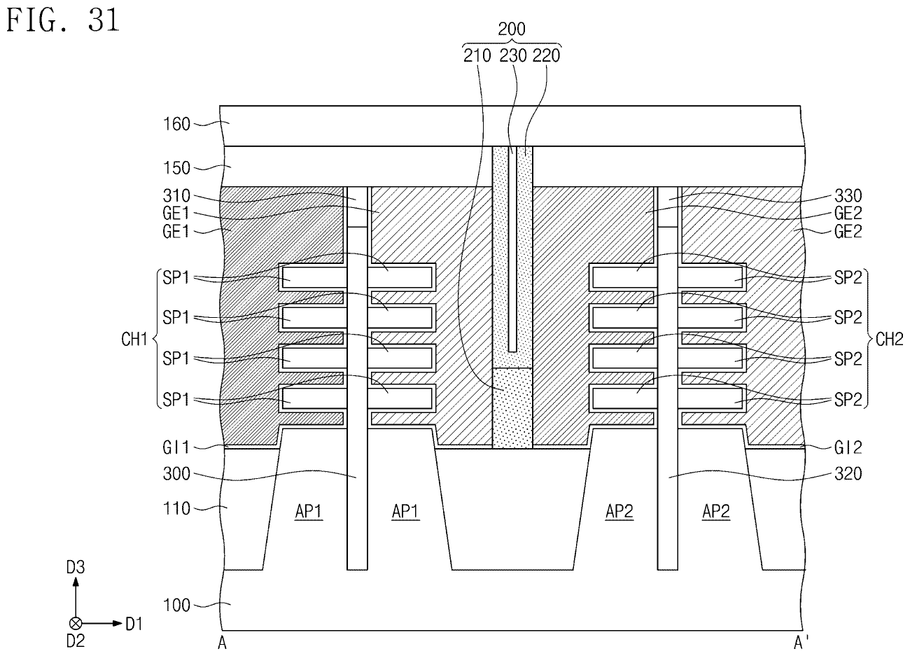

FIG. 31 is a cross-sectional view corresponding to the line A-A′ of FIG. 1, illustrating a semiconductor device according to some implementations of the present disclosure. For simplicity of description, features different from the semiconductor device described with reference to FIGS. 1 and 2A to 2D will be mainly described below.

Referring to FIGS. 1 and 31, according to some implementations, a first channel isolation pattern 300 may extend in the third direction D3 to penetrate through the first active pattern AP1 and the first channel pattern CH1. The first active pattern AP1 may be separated into a pair of first active patterns AP1 by the first channel isolation pattern 300, and the first channel pattern CH1 may be separated into a pair of first channel patterns CH1 by the first channel isolation pattern 300. Each of the pair of first channel patterns CH1 may include the first semiconductor patterns SP1 spaced apart from each other in the third direction D3.

A pair of first gate electrodes GE1 may be respectively disposed on the pair of first channel patterns CH1. The pair of first gate electrodes GE1 may include different materials from each other. A first gate isolation pattern 310 may be disposed on the first channel isolation pattern 300 and may be interposed between the pair of first gate electrodes GE1. First source/drain patterns may be disposed on both sides of each of the pair of first gate electrodes GE1, and may be connected to each of the pair of first channel patterns CH1. The pair of first gate electrodes GE1, the pair of first channel patterns CH1 and the first source/drain patterns may constitute a field effect transistor having a Forksheet structure.

A second channel isolation pattern 320 may extend in the third direction D3 to penetrate through the second active pattern AP2 and the second channel pattern CH2. The second active pattern AP2 may be separated into a pair of second active patterns AP2 by the second channel isolation pattern 320, and the second channel pattern CH2 may be separated into a pair of second channel patterns CH2 by the second channel isolation pattern 320. Each of the pair of second channel patterns CH2 may include the second semiconductor patterns SP2 spaced apart from each other in the third direction D3.

A pair of second gate electrodes GE2 may be respectively disposed on the pair of second channel patterns CH2. The pair of second gate electrodes GE2 may include different materials from each other. A second gate isolation pattern 330 may be disposed on the second channel isolation pattern 320 and may be interposed between the pair of second gate electrodes GE2. Second source/drain patterns may be disposed on both sides of each of the pair of second gate electrodes GE2 and may be connected to each of the pair of second channel patterns CH2. The pair of second gate electrodes GE2, the pair of second channel patterns CH2 and the second source/drain patterns may constitute a field effect transistor having a Forksheet structure.

The separation insulating pattern 200 may be disposed between the pair of first gate electrodes GE1 and the pair of second gate electrodes GE2, and on the device isolation layer 110. The separation insulating pattern 200 may be interposed between one of the pair of first gate electrodes GE1 and one of the pair of second gate electrodes GE2. The pair of second gate electrodes GE2 may be spaced apart (or separated) from the pair of first gate electrodes GE1 by the separation insulating pattern 200.

According to the present disclosure, the separation insulating pattern may include the lower pattern and the upper pattern stacked in the vertical direction(e.g., in the third direction) between the first gate electrode and the second gate electrode. The lower pattern may be formed before formation of the first and second gate electrodes, and the upper pattern may be formed to penetrate through the first and second gate electrodes after the formation of the first and second gate electrodes. In this case, as the lower pattern is provided between the device isolation layer and the upper pattern, loss of the device isolation layer during formation of the upper pattern may be minimized. Further, as the upper pattern is formed on the lower pattern, the vertical length of the upper pattern may be reduced, thereby facilitating the formation of the upper pattern.

In addition, the interface between the lower pattern and the upper pattern may be located at a lower height than the uppermost surfaces of the first channel pattern and the second channel pattern that are disposed below the first gate electrode and the second gate electrode, respectively. That is, the top surface of the lower pattern may be positioned at a lower height than the uppermost surfaces of the first channel pattern and the second channel pattern, and thus, layers formed between the first channel pattern and the lower pattern, and between the second channel pattern and the lower pattern may be easily removed during a manufacturing process of the semiconductor device.

Accordingly, a semiconductor device that can minimize manufacturing defects, is easy to manufacture, and has excellent reliability and a method of fabricating the same may be provided.

According to some implementations of the present disclosure, a method of fabricating a semiconductor device may comprise: forming a first active pattern and a second active pattern on a substrate, the first active pattern and the second active pattern being spaced apart from each other in a first direction and extending in a second direction, the first direction and the second direction being parallel to a top surface of the substrate and intersecting with each other; forming a device isolation layer between the first and second active patterns; forming a first channel pattern and a second channel pattern on the first active pattern and the second active pattern, respectively; forming a first lower mask layer covering the first channel pattern, the second channel pattern and the device isolation layer therebetween; forming a first separation hole penetrating through the first lower mask layer between the first channel pattern and the second channel pattern and exposing a top surface of the device isolation layer; forming a lower pattern in the first separation hole, a top surface of the lower pattern being located at a lower height than an uppermost surface of the first channel pattern and an uppermost surface of the second channel pattern; removing the first lower mask layer; forming a first gate electrode extending in the first direction and crossing the first active pattern and the first channel pattern to cover a portion of the lower pattern; forming a second gate electrode extending in the first direction and crossing the second active pattern and the second channels pattern to cover a remainder of the lower pattern, forming a second separation hole penetrating through a portion of the first gate electrode and a portion of the second gate electrode and exposing the top surface of the lower pattern; and forming an upper pattern in the second separation hole.

According to some implementations, the lower pattern may be formed using a bottom-up filling process.

According to some implementations, forming the upper pattern may comprise depositing the upper pattern to conformally cover a side surface of the first gate electrode, the top surface of the lower pattern, and a side surface of the second gate electrode, which are exposed by the second separation hole, and the upper pattern may comprise an empty region therein.

According to some implementations, forming the upper pattern may comprise: forming a first sublayer by filling a portion of the second separation hole with a flowable insulating material; and forming a second sublayer by performing a surface treatment process on an upper surface of the first sublayer.

According to some implementations, the upper pattern may include an inter-mixing layer formed between the first sublayer and the second sublayer.

According to some implementations, the lower pattern may include an impurity layer adjacent to the top surface of the lower pattern. The impurity layer may include an element different from the lower pattern.

According to some implementations, the method may further comprise: forming first source/drain patterns spaced apart from each other in the second direction with the first channel pattern interposed therebetween, on the first active pattern; and forming second source/drain patterns spaced apart from each other in the second direction with the second channel pattern interposed therebetween, on the second active pattern. The first source/drain patterns may have a different conductivity type than the second source/drain patterns.

According to some implementations, the method may further comprise: forming a first interlayer insulating layer covering the first and second source/drain patterns; and forming a gap region extending in the first direction within the first interlayer insulating layer and exposing the first channel pattern, the second channel pattern and the device isolation layer therebetween. The first lower mask layer may fill the gap region, and the first separation hole may penetrate through the first lower mask layer in the gap region to expose the top surface of the device isolation layer.

According to some implementations, the second gate electrode may comprise a different material than the first gate electrode.

According to some implementations, each of the first channel pattern and the second channel pattern may include a plurality of semiconductor patterns spaced apart from each other in a third direction perpendicular to the top surface of the substrate.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

As used herein, “about,” “approximately,” “generally,” and “substantially” are understood to refer to numbers in a range of numerals, for example the range of −10% to +10% of the referenced number, preferably-5% to +5% of the referenced number, more preferably −1% to +1% of the referenced number, most preferably −0.1% to +0.1% of the referenced number. Moreover, any numerical ranges disclosed herein should be interpreted as providing support for any specific value or sub-range within the stated range. For example, a disclosure of a range from 1 to 10 supports sub-ranges such as 1 to 5, 3 to 6, 1 to 9, 2.5 to 4.7, 2.2 to 9.9, and so on.

While implementations are described above, a person skilled in the art may understand that many modifications and variations are made without departing from the spirit and scope of the present disclosure defined in the following claims. Accordingly, the example implementations of the present disclosure should be considered in all respects as illustrative and not restrictive, with the spirit and scope of the present disclosure being indicated by the appended claims.

What is claimed is:

1. A semiconductor device comprising:
a first channel pattern and a second channel pattern spaced apart from each other in a first direction on a substrate having a top surface and a bottom surface opposite the top surface;
a first gate electrode on the first channel pattern and extending in the first direction;
a second gate electrode on the second channel pattern and extending in the first direction; and
a separation insulating pattern between the first gate electrode and the second gate electrode,
wherein the first gate electrode and the second gate electrode are aligned with each other in the first direction,
wherein the separation insulating pattern includes a lower pattern and an upper pattern stacked in a vertical direction perpendicular to the top surface of the substrate, and
wherein an interface between the lower pattern and the upper pattern is positioned at a lower height than an uppermost surface of the first channel pattern and an uppermost surface of the second channel pattern.

2. The semiconductor device of claim 1, wherein the lower pattern has a pillar shape extending in the vertical direction.

3. The semiconductor device of claim 1, wherein the upper pattern covers a side surface of the first gate electrode, a top surface of the lower pattern, and a side surface of the second gate electrode, and the upper pattern includes an empty region.

4. The semiconductor device of claim 1, wherein:
a top surface of the lower pattern is in contact with a bottom surface of the upper pattern,
each of the lower pattern and the upper pattern defines a respective width along the first direction, and
a width of the top surface of the lower pattern is equal to a width of the bottom surface of the upper pattern.

5. The semiconductor device of claim 4, wherein a width of the lower pattern decreases from the top surface of the lower pattern to a bottom surface of the lower pattern.

6. The semiconductor device of claim 1, wherein:
a top surface of the lower pattern is in contact with a bottom surface of the upper pattern,
each of the lower pattern and the upper pattern defines a respective width along the first direction, and
a width of the top surface of the lower pattern is smaller than a width of the bottom surface of the upper pattern.

7. The semiconductor device of claim 6, wherein a width of the lower pattern increases from the top surface of the lower pattern to the bottom surface of the lower pattern.

8. The semiconductor device of claim 1, wherein:
a top surface of the lower pattern is in contact with a bottom surface of the upper pattern,
each of the lower pattern and the upper pattern defines a respective width along the first direction, and
a width of the top surface of the lower pattern is greater than a width of the bottom surface of the upper pattern.

9. The semiconductor device of claim 1, wherein:
the upper pattern includes a first sublayer and a second sublayer stacked in the vertical direction on a top surface of the lower pattern,
each of the first sublayer and the second sublayer defines a respective thickness along the vertical direction, and
a thickness of the second sublayer is smaller than a thickness of the first sublayer.

10. The semiconductor device of claim 9, wherein the upper pattern includes an inter-mixing layer between the first sublayer and the second sublayer.

11. The semiconductor device of claim 1, wherein:
the lower pattern includes a first portion and a second portion, wherein the second portion of the lower pattern includes an impurity layer adjacent to the interface between the lower pattern and the upper pattern, and
the impurity layer includes an element different from the first portion of the lower pattern.

12. The semiconductor device of claim 1, wherein the second gate electrode includes a different material than the first gate electrode.

13. The semiconductor device of claim 1, comprising:
first source/drain patterns disposed on opposite sides of the first gate electrode; and
second source/drain patterns disposed on opposite sides of the second gate electrode,
wherein the first source/drain patterns are spaced apart from each other in a second direction intersecting the first direction and connected to the first channel pattern,
wherein the second source/drain patterns are spaced apart from each other in the second direction and connected to the second channel pattern, and
wherein the first source/drain patterns have a different conductivity type than the second source/drain patterns.

14. A semiconductor device comprising:
a first active pattern and a second active pattern spaced apart from each other in a first direction and extending in a second direction on a substrate having a top surface and a bottom surface opposite the top surface, the first direction and the second direction being parallel to the top surface of the substrate and intersecting each other;
a device isolation layer between the first active pattern and the second active pattern;
a first channel pattern on the first active pattern;
a second channel pattern on the second active pattern;
a first gate electrode extending in the first direction and crossing the first active pattern and the first channel pattern;
a second gate electrode extending in the first direction and crossing the second active pattern and the second channel pattern; and
a separation insulating pattern interposed between the first gate electrode and the second gate electrode and disposed on the device isolation layer,
wherein the first gate electrode and the second gate electrode are aligned with each other in the first direction,
wherein the separation insulating pattern includes a lower pattern and an upper pattern stacked in a third direction perpendicular to the top surface of the substrate, and
wherein a top surface of the lower pattern is positioned at a lower height than an uppermost surface of the first channel pattern and an uppermost surface of the second channel pattern.

15. The semiconductor device of claim 14, wherein the upper pattern covers a side surface of the first gate electrode, the top surface of the lower pattern, and a side surface of the second gate electrode, and the upper pattern includes an empty region.

16. The semiconductor device of claim 14, wherein:
the upper pattern includes at least one first sublayer and at least one second sublayer stacked in the third direction on the top surface of the lower pattern,
each of the at least one first sublayer and the at least one second sublayer defines a respective thickness along the third direction, and
a thickness of the at least one second sublayer is smaller than a thickness of the at least one first sublayer.

17. The semiconductor device of claim 16, wherein:
the upper pattern further includes an inter-mixing layer between the at least one first sublayer and the at least one second sublayer, and
a thickness of the inter-mixing layer in the third direction is smaller than the thickness of the at least one first sublayer.

18. The semiconductor device of claim 14, wherein:
the lower pattern includes a first portion and a second portion, wherein the second portion of the lower pattern includes an impurity layer adjacent to the top surface of the lower pattern, and
the impurity layer includes an element different from the first portion of the lower pattern.

19. The semiconductor device of claim 14, wherein:
the lower pattern defines a respective width along the first direction, and
the width of the lower pattern decreases or increases from the top surface of the lower pattern to a bottom surface of the lower pattern.

20. A semiconductor device comprising:
a first active pattern and a second active pattern spaced apart from each other in a first direction and extending in a second direction on a substrate having a top surface and a bottom surface opposite the top surface, the first direction and the second direction being parallel to the top surface of the substrate and intersecting each other;
a first channel pattern on the first active pattern;
first source/drain patterns on the first active pattern and spaced apart from each other in the second direction across the first channel pattern;
a second channel pattern on the second active pattern;
second source/drain patterns on the second active pattern and spaced apart from each other in the second direction across the second channel pattern;
a first gate electrode extending in the first direction and crossing the first active pattern and the first channel pattern;
a second gate electrode extending in the first direction and crossing the second active pattern and the second channel pattern; and
a separation insulating pattern interposed between the first gate electrode and the second gate electrode,
wherein the first gate electrode and the second gate electrode are aligned with each other in the first direction,
wherein the separation insulating pattern includes a lower pattern and an upper pattern stacked in a third direction perpendicular to the top surface of the substrate,
wherein an interface between the lower pattern and the upper pattern is located at a lower height than an uppermost surface of the first channel pattern and an uppermost surface of the second channel pattern, and
wherein the first source/drain patterns have a different conductivity type than the second source/drain patterns.
